(19) United States
(12) Patent Application Publication
(10) Pub. No.: US 2021/0301133 A1
(43) Pub. Date: Sep. 30, 2021

(54) CURABLE POLYIMIDES

(71) Applicant: Designer Molecules, Inc., San Diego, CA (US)

(72) Inventor: Farhad G Mizori, San Diego, CA (US)

(21) Appl. No.: 16/626,317

(22) PCT Filed: Jun. 25, 2018
(86) PCT No.: PCT/US18/39232

§ 371 Date: Dec. 23, 2019

Related U.S. Application Data
(60) Provisional application No. 62/525,279, filed on Jun. 27, 2017.
(60) Provisional application No. 62/524,584, filed on Jun. 25, 2017.
(60) Provisional application No. 62/524,581, filed on Jun. 25, 2017.
(60) Provisional application No. 62/524,517, filed on Jun. 24, 2017.

(51) Int. Cl. C08L 79/08; C08G 73/10; C08K 5/13; C08J 5/24; H01L 23/00

(52) U.S. Cl. CPC C08L 79/085; C08G 73/1082; C08G 73/1042; C08G 73/1021; C08G 73/105; C08K 5/13; H01L 2924/07025; H01L 24/02; C08L 2312/06; C08G 2150/00; C08G 2170/00; C08L 2203/20; H01L 2224/024; C08J 5/24

(57) ABSTRACT

The present invention provides curable, high molecular weight (>20,000 Daltons) polyimide compounds. The polyimides, once cured, possess a wide range of glass transition temperatures, have high tensile strength and high elongation. Furthermore, the cured polyimides are hydrophobic, have high glass transition temperatures, low coefficient of thermal expansion, very low dielectric constant and very low dielectric dissipation factor.

### RELATED APPLICATIONS

This application claims the benefit of priority under 35 USC § 119 of U.S. Provisional Patent Application Ser. Nos.: 62/524,517 (filed Jun. 24, 2017); 62/524,581 (filed Jun. 25, 2017); 62/524,584 (filed Jun. 25, 2017); and 62/525,279 (filed Jun. 27, 2017), the entire disclosures of which are incorporated herein by reference.

### FIELD OF INVENTION

The present invention relates to thermosetting polymers, adhesive and coating compositions and methods of use, specifically, high molecular weight, flexible polyimide resins functionalized with curable moieties that heat-, UV- and self-cure. Specifically, the invention also relates to hydrophobic, photoimagable polymeric compounds and compositions that can be used for redistribution layers, temporary adhesives, shape memory plastics and in the production of prepregs, copper-clad laminates and printed wiring boards.

### BACKGROUND OF INVENTION

Adhesive compositions are used for a variety of purposes in the fabrication and assembly of semiconductor packages and microelectronic devices. Prominent uses include bonding of electronic elements such as integrated circuit chips to lead frames and other substrates, and bonding of circuit packages or assemblies to printed wire boards.

### Temporary Adhesives

Temporary adhesive tapes and other temporary adhesive compositions are extensively used in wafer backgrinding, wafer dicing and many other processes in electronics fabrication. For temporary applications, adhesives must be fully removable after serving its purpose. However, many of the new processes that are encountered require high temperature stability over 250° C. and for these applications the traditional materials are inadequate because they are unstable at very high temperature and can cause voids and delamination.

### Coatings and Packaging

Curable monomers used in adhesive compositions for electronics packaging must be hydrophobic, have low ionic content, high thermal stability, and good mechanical strength. They must also be thermally stable for extended periods of time at temperatures in excess of 250° C., with little or no weight loss that would cause delamination, and as well as being resistant to many solvents.

Often in electronics applications, a clear, non-filled conformal coating is an appropriate way to protect or encapsulate an electronic component. In this type of application, the coating protects delicate wiring that can easily be damaged (e.g. by shock), and/or circuitry that is susceptible to mechanical damage and/or corrosion.

During certain stages in the assembly of electronics components, such as solder reflow, high temperatures are encountered. Similarly, during operation, electronics components generate heat and thus, adhesives and coatings used must be resistant to high temperatures encountered during assembly and operation. Coatings and adhesives used in electronics must also be very hydrophobic to resist and protect against moisture, which can be very destructive.

In certain applications, such as underfilling, materials are required that have a very high glass transition temperature (T_{g}) along with a very low coefficient of thermal expansion (CTE). In other applications, softer materials are required (i.e., with a low T_{g}). Softer materials are generally more useful as conformal coatings because they can withstand shock and remain flexible even at very cold temperatures.

### Polyimides

Aliphatic, low modulus maleimide-terminated polyimides have high temperature stability (based on dynamic TGA measurements performed in air). These polyimide materials perform well in very short duration (a few seconds) high temperature excursions, such as solder reflow at 260° C. Yet even these short duration exposures, temperatures greater than 200° C. can cause maleimide-terminated polyimides materials to lose flexibility, while prolonged exposure leads to thermo-oxidative degradation causing the material to turn black and become brittle. Adding antioxidants can remedy some of these problems, however, a large quantity of antioxidant is required to prevent the effect of thermal degradation and aging and antioxidant leaching can occur.

Maleimide oligomers UV-cure much slower than acrylics. In order to aid the UV-curing without adding large amounts of initiator, it would be useful a UV sensitizer built into the system. A potential solution to the problem of leaching would be to make the antioxidant a part of the polymer itself, that way it could be self-healing without the addition of materials that could be depleted over time or affect neighboring materials and structures.

Polyimides are frequently used in photolithography and photoresists, wafer passivation. Polyimide passivation layers of 4-6 microns in thickness protect delicate thin films of metals and oxides on the chip surface from damage during handling and from induced stress after encapsulation in plastic molding compound. Patterning is simple and straightforward. Because of the low defect density and robust plasma etch resistance inherent with polyimide films, a single mask process can be implemented, which permits the polyimide layer to function both as a stress buffer and as a dry etch mask for an underlying silicon nitride layer. In addition, polyimide layers are readily used for flip-chip bonding applications, including both C-4 and dual-layer bond pad redistribution (BPR) applications. Polyimide layers can also be patterned to form the structural components in microelectromechanical systems (MEMS).

Polyimides may also serve as an interlayer dielectric in both semiconductors and thin film multichip modules (MCM-Ds). The low dielectric constant, low stress, high modulus, and inherent ductility of polyimide films make them well suited for these multiple layer applications. Other uses for polyimides include alignment and/or dielectric layers for displays, and as a structural layers in micro machining. In lithium-ion battery technology, polyimide films can be used as protective layers for PTC thermistor (positive temperature coefficient) controllers.

However, polyimides are difficult to process. They are typically applied as a solution of the corresponding polyamic acid precursors onto a substrate, and then thermally cured to smooth, rigid, intractable films and structural layers. The film can be patterned using a lithographic (photographic) process in conjunction with liquid photoresists. Polyimides formed in situ by imidization through cyclodehydration of the polyamic acid precursors require the evaporation of high boiling point, polar aprotic solvents, which can be difficult to remove. Removal typically requires temperature of >300° C., is sometimes referred to as the “hard bake” step. This process is important, because if the polyimide is not fully imidized the material will absorb a great deal of moisture.

Polyimides have been used as interlayer dielectric materials in microelectronic devices such as integrated circuits (ICs) due dielectric constants lower than that of silicon dioxide. Also, such polyimide materials can serve as planarization layers for ICs as they are generally applied in a liquid form, allowed to level, and subsequently cured. However, thermally cured polyimides, can generate stress, which can lead to delamination and can warp thin wafers.

Existing polyimide materials are generally hydrophilic and usually require tedious multi-step processes to form vias required for electrical interconnects. Moreover, polyimides readily absorb moisture even after curing which can result in device failure when the moisture combined with ionic impurities, causes corrosion. Accordingly, there is a need for hydrophobic, polyimides that are compatible with very thin silicon wafers and will not cause warping of thin silicon wafers.

A need also exists for polyimide films that can be developed easily in photolithography. Generally, photoresists are classified as two types: negative and positive tone. A “Positive resist” photoresist becomes soluble in a photoresist developer when exposed to light, while unexposed areas remain insoluble. A “negative resist” photoresist becomes insoluble to developer when exposed to light. Negative photoresists are more widely used in electronic due to lower cost, superior adhesion to silicon, and much better chemical resistance. However, negative photoresists are inferior to positive resists in development of fine feature definition.

### Shape Memory Polymers

Many of the same challenges that are encountered in the electronics field are encountered in shape memory polymers or SMPs. SMPs or smart plastics, are high molecular weight materials that have the ability to change from a temporary or deformed shape, back to an original or permanent shape when an external stimulus such as heat is applied. Shape memory polymers are generally characterized as phase-segregated linear block co-polymers having hard segments and soft segments. The hard segments are typically crystalline, with a defined melting point (MP), and the soft segments are typically amorphous, with a defined glass transition temperature (T_{g}). When an SMP is heated above the MP or T_{g} of the hard segment, the material can be shaped, and the shape “memorized” by cooling. When cooled below the MP or T_{g} of the soft segments while the shape is deformed, that (temporary) shape becomes fixed. The original shape is recovered by heating above the MP or T_{g} of the soft segments, but below that of the hard segments. A temporary shape can also set by deforming at a temperature lower than the soft segment MP or T_{g}, which absorbs the stress and strain forces. Reheated above the soft segment MP or T_{g}, but below that of the hard segments, relieves the stress and strain and the material returns to its original shape. The temperature-dependent recovery of original shape is called the “thermal shape memory effect”. Properties that describe the shape memory capabilities of a material are the shape recovery of the original shape and the shape fixity of the temporary shape. SMPs can readily recover an original molded shape following numerous thermal cycles and can be heated above the MP of the hard segment and reshaped/cooled to fix a new shape.

Other physical properties of SMPs are significantly altered in response to external changes in temperature and stress, particularly at the MP or T_{g} of the soft segments. These properties include the elastic modulus, hardness, flexibility, vapor permeability, damping, index of refraction, and Dk. The elastic modulus (the ratio of the stress in a body to the corresponding strain) of an SMP can change by a factor of up to 200 when heated above the MP or T_{g} of the soft segment. The hardness of the material changes dramatically when the soft segment is at or above its MP or T_{g} and damping ability can be up to five times higher than a conventional rubber product.

Although many SM polymers have been found they are very weak and have very low tensile strength, as well as low T_{g} and very high CTE. Thus. a need exists for very thermally stable, strong, tough shape memory polymers. The ideal material would have good tensile strength, high elongation, relatively high T_{g} and low CTE, with either thermal or UV curing. Preferably, the material would be a hydrophobic, with low Dk and low Df.

### SUMMARY OF THE INVENTION

The present invention provides a curable polyimide having a structure according to any one of Formulae IA, IB, IC and 1D:

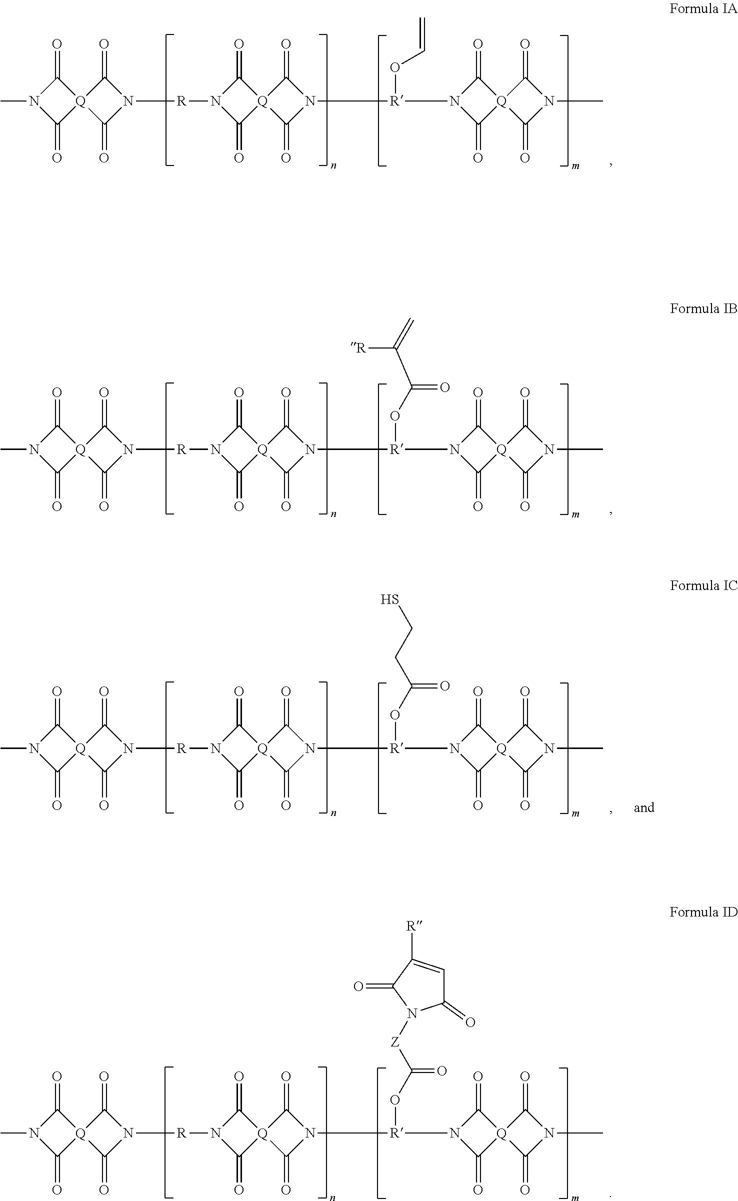

where R is independently a substituted and unsubstituted aliphatic, cycloaliphatic, alkenyl, polyether, polyester, polyamide, aromatic, heteroaromatic, or siloxane moieties; R′ is an alcohol functionalized diamine; each Q is independently a substituted or unsubstituted aliphatic, cycloaliphatic, alkenyl, polyether, polyester, polyamide, aromatic, heteroaromatic, or siloxane moiety; each R″ is H or methyl; z is independently a substituted or unsubstituted aliphatic or aromatic moiety; and n and m are integers having a value from 10 to about 100, with the proviso the average molecular weight of curable polyimide is greater than 20,000 Daltons. The curable polyimides of formulae IA, IB, IC and ID are the product of a condensation of diamine(s) with dianhydride(s) followed by functionalizing of the pendant alcohol group.

The present invention also provides method for synthesizing a high molecular weight polyimide, comprising the steps of dissolving at least one diamine in a solvent at room temperature; adding at least one dianhydride, wherein the total amount of the at least one dianhydride amount is approximately one molar equivalent of the total amount of the at least one diamine; slowly heating the mixture to reflux over 1-hour, refluxing the mixture while removing the water for about one to about two hours, or until all the water produced has been removed, wherein the average molecular weight of the polyimide is greater than 20,000 Daltons. In certain embodiments, the solvent is an aromatic solvent, such as anisole.

The alcohol pendant polyimides can be functionalized by reacting the pendant alcohol groups to produce a functionalized polyimide, which can involve catalyzing the reaction with a polymer-bound acid catalyst and removing the polymer-bound catalyst by filtration.

Diamines contemplated for use in the methods of the invention include but are not limited to dimer diamine; 1,10-diaminodecane; 1,12-diaminododecane; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomenthane; 1,8-diaminooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4′-diamino-2,2′-bistrifluoromethylbiphenyl; bis(amino-3-chlorophenyl)ethane; bis(4-amino-3,5-dimethylphenyl)methane; bis(4-amino-3,5-diisopropylphenyl)methane; bis(4-amino-3,5-methyl-isopropylphenyl)methane; bis(4-amino-3,5-diethylphenyl)methane; bis(4-amino-3-ethylphenyl)methane; diaminofluorene; 4,4′-(9-Fluorenylidene)dianiline; diaminobenzoic acid; 2,3-diaminonaphthalene; 2,3-diaminophenol; 3,5-diaminobenzyl alcohol; bis(4-amino-3-methylphenyl)methane; bis(4-amino-3-ethylphenyl)methane; 4,4′-diaminophenylsulfone; 3,3′-diaminophenylsulfone; 2,2-bis(4,-(4-aminophenoxy)phenyl)sulfone; 2,2-bis(4-(3-aminophenoxy)phenyl)sulfone; 4,4′-oxydianiline; 4,4′-diaminodiphenyl sulfide; 3,4′-oxydianiline; 2,2-bis(4-(4-aminophenoxy)phenyl)propane; 1,3-bis(4-aminophenoxy)benzene; 4,4′-bis(4-aminophenoxy)biphenyl; 4,4′-diamino-3,3′-dihydroxybiphenyl; 4,4′-diamino-3,3′-dimethylbiphenyl; 4,4′-diamino-3,3′-dimethoxybiphenyl; Bisaniline M (4-[2-[3-[2-(4-aminophenyl)propan-2-yl]phenyl]propan-2-yl]aniline)]Bisaniline); Bisaniline P (4-[2-[4-[2-(4-aminophenyl)propan-2-yl]phenyl]propan-2-yl]aniline); 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3′,5,5′-tetramehylbenzidine; 4,4′-diaminobenzanilide; 2,2-bis(4-aminophenyl) hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; 3(4),8(9)-bis(aminomethyl)tricyclo(5.2.1.0^{2,6})decane; ethanolamine; 1,3-cyclohexanebis(methylamine); 1,3-diamino-2-propanol; 1,4-diaminobutane, 1,5-diaminopentane; 1,6-diaminohexane; 2,2-bis[4-(3-aminophenoxy)phenyl]propane; 2,3,5′-tetramethylbenzidine; 2,3-diamononaphtalene; and polyalkylenediamines.

Dianhydrides contemplated for use in the methods of the invention include but are not limited to 4,4′-Bisphenol A dianhydride; pyromellitic dianhydride; 1,2,3,4-cyclobutanetetracarboxylic dianhydride; 1,4,5,8-naphthalenetetracarboxylic dianhydride; 3,4,9,10-perylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3′,4,4′-benzophenone tetracarboxylic dianhydride; 3,3′,4,4′-biphenyl tetracarboxylic dianhydride; 4,4′-oxydiphthalic anhydride; 3,3′,4,4′-diphenylsulfone tetracarboxylic dianhydride; 2,2′-bis(3,4-dicarboxyphenyl)hexafluoropropane dianhydride; 4,4′-bisphenol A diphthalic anhydride; 5-(2,5-dioxytetrahydro)-3-methyl-3-cyclohexene-1,2-dicarboxylic anhydride; ethylene glycol bis(trimellitic anhydride); hydroquinone diphthalic anhydride;

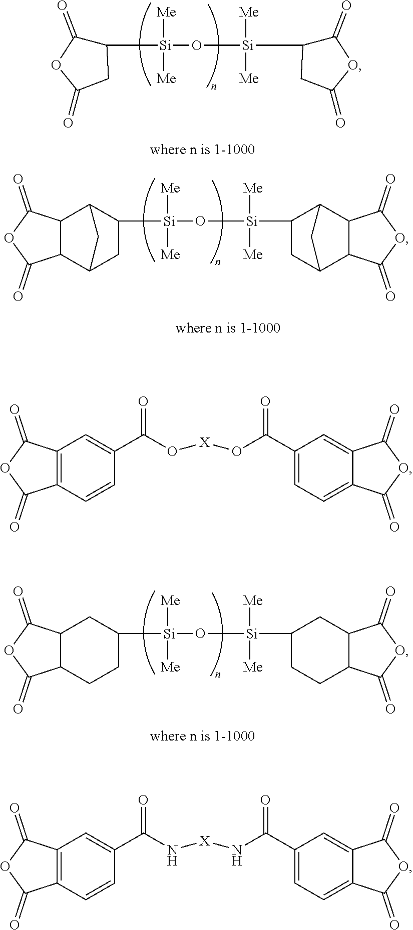

where X is saturated, unsaturated, strait or branched alkyl, polyester, polyamide, polyether, polysiloxane or polyurethane;

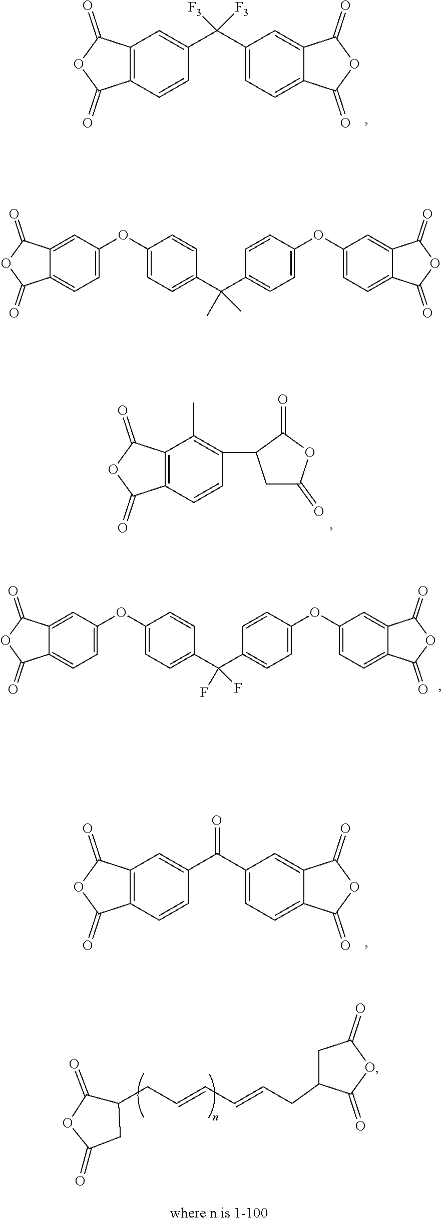

Also provided by the invention are adhesive formulations including comprising a polyimide of the invention, which can be a removable or temporary adhesive.

The temporary adhesives of the invention can be removed by applying an air jet to the temporary adhesive; and peeling the adhesive from the article. In some aspects the removal process may require soaking in a chemical solvent that removes residual adhesive such as cyclopentanone, cyclohexanone or a combination thereof.

The invention also provides articles, such as thinned or unthinned wafers, patterned or unpatterned chips, and electronics packages comprising a coating of a formulation of the invention.

Formulations provided by the invention comprise at least one curable, functionalized polyimide described herein, at least one reactive diluent or co-curable compound; and a solvent in which the functionalized polyimide is soluble. Such formulations can also include at least one adhesion promoters; at least one or more coupling agents; and/or at least one or more UV initiators; or free-radical initiators.

The formulations can be, for example, coatings, passivation layers, or redistribution layers.

For example, redistribution layers provided by the invention can include metallization between two layers of a formulation described herein. Also provided are articles coated on at least a part of a surface with a formulation of the invention, which can be a coating, passivation layer or redistribution layer.

The invention also provides prepregs that include comprising a fiber support impregnated with the formulation of the invention, as well as copper clad laminates in which copper foil is laminated to one surface or both surfaces of a prepreg of the invention. Also provided are printed wiring boards utilizing the copper-clad laminates of the invention.

The invention further provides flexible copper clad laminates comprising copper foil laminated to one surface or both surfaces of a cured layer of a polyimide formulation described herein.

Also provided are methods for backgrinding a wafer, including the steps of: applying a removable adhesive described herein to the top of a wafer; adhering the wafer to a support; grinding and polishing the wafer; removing the wafer from the support; and removing the adhesive from the wafer. Applying can be by spin-coating a liquid formulation onto the wafer, or the formulation can be applied to a tape backing. The formulation can be pressure-sensitive or curable.

In another embodiment, the invention provides methods for dicing a wafer, comprising the steps of: applying a removable adhesive described herein to the top or bottom side of a wafer; securing the wafer to a frame; cutting the wafer to singulate individual die; removing the die from the wafer; and removing the adhesive from the die. The applying step can be by spin-coating or application of a pressure sensitive or curable tap.

Also provided are methods for redistributing an I/O pad of a chip, comprising the steps of: applying a first redistribution layer formulation to the surface of the chip that covers at least a line from the I/O pad a new I/O pad location, or can cover the entire chip; metallizing the line; applying a second redistribution layer to the cover at least the metallization; removing redistribution layer formulation covering the metallization of the new I/O pad, which can be done by covering the pad before applying the second redistribution layer or by masking/photolithography; and curing the first redistribution layer formulation and the second redistribution layer formulation. Alternatively, the first redistribution layer can be cured prior to metallizing. Excess redistribution layer can be removed at the end of the process, e.g. by photolithography. In certain embodiments, the redistribution layer is on a single silicon chip. In other embodiments, the chip is part of a fan-out package and the redistribution layer originates on the silicon chip and ends in the fan-out area.

### BRIEF DESCRIPTION OF THE DRAWINGS

FIG. 1. is a schematic flow diagram illustrating the process of backgrinding according to an embodiment of the invention. Solid arrows indicate direction according to an embodiment of the invention. Broken arrows A-H indicate steps in the process.

FIGS. 2A and 2B are consecutive parts of a schematic flow diagram illustrating the process of wafer dicing according to an embodiment of the invention. They are intended to be viewed together as a single diagram. Arrows A-F indicate steps in the process

FIG. 3A is a cross-sectional view through the structures at plane I of FIG. 2A.

FIG. 3B is a cross-sectional view through the structures at plane II of FIG. 2B.

FIG. 3C is a cross-sectional view through the structures at plane III of FIG. 2A.

FIG. 3D is a cross-sectional view through the structures at plane IV of FIG. 2A.

FIG. 3E is a cross-sectional view through the structures at plane V of FIG. 2A.

FIG. 3F is a cross-sectional view through the structures at plane VI of FIG. 2A.

FIG. 3G is a cross-sectional view through the structures at plane VII of FIG. 2B.

FIG. 3H is a cross-sectional view through the structures at plane VII of FIG. 2B.

FIG. 3I is a cross-sectional view through the structures at plane IX of FIG. 2B.

FIG. 3J is a cross-sectional view through the structures at plane X of FIG. 2B.

FIG. 4 is a schematic flow diagram illustrating the process of redistributing an I/O pad using Redistribution Layer (RDL) according to an embodiment of the invention. Arrows A-D indicate steps in the process.

FIG. 5A is a cross-sectional view through the structures at plane XI of FIG. 4.

FIG. 5B is a cross-sectional view through the structures at plane XII of FIG. 4.

FIG. 5C is a cross-sectional view through the structures at plane XIII of FIG. 4.

FIG. 5D is a cross-sectional view through the structures at plane XIV of FIG. 4.

FIG. 5E is a cross-sectional view through the structures at plane XV of FIG. 4.

FIG. 6 is a perspective view of fan-out IC package including RDL according to one embodiment of the invention.

FIG. 7 is a cross-sectional view through the structures at plane XVI of FIG. 6.

FIG. 8 is a schematic flow diagram illustrating the process of making a printed circuit board including preparing a prepreg, laminating copper onto the prepreg, and etching a circuit pattern on the copper-cladding. Arrows A-E indicate steps in the process.

FIG. 9 is a cross-sectional view through the structures at plane XVII of FIG. 8.

FIG. 10A is a schematic flow diagram illustrating the process of producing a one-sided flexible copper-clad laminate (FCCL) according to one embodiment of the invention that includes an adhesive layer. Arrows A and B indicate steps in the process.

FIG. 10B is a schematic flow diagram illustrating the process of producing a one-sided flexible copper-clad laminate (FCCL) according an embodiment of the invention that includes layers of adhesive. Arrows A and B indicate steps in the process.

FIG. 11A is a schematic flow diagram illustrating the process of producing a one-sided flexible copper-clad laminate (FCCL) according to one embodiment of the invention that omits an adhesive layer. Arrows A and B indicate steps in the process.

FIG. 11B is a schematic flow diagram illustrating the process of producing a one-sided flexible copper-clad laminate (FCCL) according an embodiment of the invention that excludes layers of adhesive. Arrows A and B indicate steps in the process.

FIG. 12 is a graph showing the thermogravimetric analysis of Compound 1-E.

FIG. 13 is a graph showing the thermogravimetric analysis of Compound 4A.

FIG. 14 is a graph showing the elution profile of Compound 1-B from a gel permeation column for the estimation of molecular weight.

FIG. 15 is a graph showing the elution profile of Compound 1-D from a gel permeation column for the estimation of molecular weight.

FIG. 16 is a graph showing the elution profile of Compound 1-E from a gel permeation column for the estimation of molecular weight.

FIG. 17 is a graph showing the elution profile of Compound 1-H from a gel permeation column for the estimation of molecular weight.

FIG. 18 is a graph showing the elution profile of Compound 2-A from a gel permeation column for the estimation of molecular weight.

FIG. 19 is a graph showing the elution profile of Compound 3-A from a gel permeation column for the estimation of molecular weight.

FIG. 20 is a graph showing the elution profile of Compound 4-A from a gel permeation column for the estimation of molecular weight.

FIG. 21 is gel permeation column standard curve for the estimation of molecular weight.

FIG. 22 is scanning electron micrograph of copper oxide diffusion through a redistribution layer according to an embodiment of the invention (panel B) and a through a control redistribution layer (panel A).

### DETAILED DESCRIPTION

It is to be understood that both the foregoing general description and the following detailed description are exemplary and explanatory only and are not restrictive of the invention claimed. As used herein, the use of the singular includes the plural unless specifically stated otherwise. As used herein, “or” means “and/or” unless stated otherwise. Furthermore, use of the term “including” as well as other forms, such as “includes,” and “included,” is not limiting.

The section headings used herein are for organizational purposes only and are not to be construed as limiting the subject matter described.

Unless specific definitions are provided, the nomenclatures utilized in connection with, and the laboratory procedures and techniques of analytical chemistry, synthetic organic and inorganic chemistry described herein are those known in the art, such as those set forth in “IUPAC Compendium of Chemical Terminology: IUPAC Recommendations (The Gold Book)” (McNaught ed.; International Union of Pure and Applied Chemistry, 2^{nd} Ed., 1997) and “Compendium of Polymer Terminology and Nomenclature: IUPAC Recommendations 2008” (Jones et al., eds; International Union of Pure and Applied Chemistry, 2009). Standard chemical symbols are used interchangeably with the full names represented by such symbols. Thus, for example, the terms “hydrogen” and “H” are understood to have identical meaning. Standard techniques may be used for chemical syntheses, chemical analyses, and formulation.

### Definitions

“About” as used herein means that a number referred to as “about” comprises the recited number plus or minus 1-10% of that recited number. For example, “about 100 degrees” can mean 95-105 degrees or as few as 99-101 degrees depending on the situation. Whenever it appears herein, a numerical range such as “1 to 20” refers to each integer in the given range; e.g., “1 to 20 carbon atoms” means that an alkyl group can contain only 1 carbon atom, 2 carbon atoms, 3 carbon atoms, etc., up to and including 20 carbon atoms (although the term “alkyl” also includes instances where no numerical range of carbon atoms is designated). Where a range described herein includes decimal values, such as “1.2% to 10.5%”, the range refers to each decimal value of the smallest increment indicated in the given range; e.g. “1.2% to 10.5%” means that the percentage can be 1.2%, 1.3%, 1.4%, 1.5%, etc. up to and including 10.5%; while “1.20% to 10.50%” means that the percentage can be 1.20%, 1.21%, 1.22%, 1.23%, etc. up to and including 10.50%.

As used herein, the term “substantially” refers to a great extent or degree. For example, “substantially all” typically refers to at least about 90%, frequently at least about 95%, often at least 99%, and more often at least about 99.9%.

“Effective amount”, as used herein, refers to the amount of a compound or other substance that is sufficient in the presence of the remaining components to effect the desired result, such as reduction in photo-degradation and thermo-oxidative degradation by at least about 50%, usually at least about 70%, typically at least about 90%, frequently at least about 95% and most often, at least about 99%. In other aspects of the invention, an “effective amount” of a compound can refer to that concentration of the compound that is sufficient in the presence of the remaining components to effect the desired result. The effective amount of a compound or other substance is readily determined by one of ordinary skill in the art.

“Adhesive”, “adhesive compound”, “adhesive composition”, and “adhesive formulation” as used herein, refer to any substance that can adhere or bond two items together. Implicit in the definition of an “adhesive composition” and “adhesive formulation” is that these are combinations or mixtures of more than one species, component or compound, which can include adhesive monomers, oligomers, and/or polymers along with other materials, whereas an “adhesive compound” refers to a single species, such as an adhesive polymer or oligomer.

More specifically, the terms “adhesive”, “adhesive composition”, and “adhesive formulation” refer to un-cured mixtures in which the individual components in the mixture retains the chemical and physical characteristics of the original components of which the mixture is made. Adhesive compositions are typically malleable and may be liquids, paste, gel or another form that can be applied to an item so that the item can be bonded to another item.

“Cured adhesive”, “cured adhesive compound”, and “cured adhesive composition”, refer to adhesive components and mixtures obtained from reactive, curable original compounds or mixtures of compounds that have undergone a chemical and/or physical change such that the original compound or mixture of compounds is transformed into a solid, substantially non-flowing material. A typical curing process may involve cross-linking.

“Curable” means that an original compound or composition can be transformed into a solid, substantially non-flowing material by means of chemical reaction, cross-linking, radiation cross-linking, or the like. Thus, adhesive compounds and compositions of the invention are curable, but unless otherwise specified, adhesive compounds and compositions are not cured.

“Thermoplastic,” as used herein, refers to the ability of a compound, composition or other material (e.g. a plastic) to dissolve in a suitable solvent or to melt to a liquid when heated and freeze to a solid, often brittle and glassy, state when cooled sufficiently.

“Thermoset,” as used herein, refers to the ability of a compound, composition or other material to irreversibly “cure” resulting in a single three-dimensional network that has greater strength and less solubility compared to the un-cured compound, composition or other material.

Thermoset materials are typically polymers that may be cured, for example, through heat (e.g. above 200° C.), via a chemical reaction (e.g. epoxy ring-opening, free-radical polymerization, etc.) or through irradiation (e.g. visible light, UV light, electron beam radiation, ion-beam radiation, or X-ray irradiation).

Thermoset materials, such as thermoset polymers or resins, are typically liquid or malleable forms prior to curing, and therefore may be molded or shaped into their final form, and/or used as adhesives. Curing transforms the thermoset resin into a rigid infusible and insoluble solid or rubber by a cross-linking process. Thus, energy and/or catalysts are typically added that cause the molecular chains of the polymers to react at chemically active sites (e.g., unsaturated or epoxy sites), linking the polymer chains into a rigid, 3D structure. The cross-linking process forms molecules with a higher molecular weight and resultant higher melting point. During the reaction, when the molecular weight of the polymer has increased to a point such that the melting point is higher than the surrounding ambient temperature, the polymer becomes a solid material.

“Cross-linking,” as used herein, refers to the bonding, typically covalent bonding, of two or more oligomer or longer, polymer chains by bridges of an element, a molecular group, a compound, or another oligomer or polymer. Cross-linking may take place upon heating; some cross-linking processes may also occur at room temperature or a lower temperature. As cross-linking density is increased, the properties of a material can be changed from thermoplastic to thermosetting

As used herein, “B-stageable” refers to the properties of an adhesive having a first solid phase followed by a tacky rubbery stage at elevated temperature, followed by yet another solid phase at an even higher temperature. The transition from the tacky rubbery stage to the second solid phase is thermosetting. However, prior to thermosetting, the material behaves similarly to a thermoplastic material. Thus, such adhesives allow for low lamination temperatures while providing high thermal stability.

A “die” or “semiconductor die” as used herein, refers to a small block of semiconducting material, on which a functional circuit is fabricated.

“Chip” as used herein, refers to die fabricated with a functional circuit, (e.g., a set of electronic circuits or an integrated circuit).

A “flip-chip” semiconductor device is one in which a semiconductor die is directly mounted to a wiring substrate, such as a ceramic or an organic printed circuit board. Conductive terminals on the semiconductor die, usually in the form of solder bumps, are directly physically and electrically connected to the wiring pattern on the substrate without use of wire bonds, tape-automated bonding (TAB), or the like. Because the conductive solder bumps making connections to the substrate are on the active surface of the die or chip, the die is mounted in a facedown manner, thus the name “flip-chip.”

The term “photoimageable”, as used herein, refers to the ability of a compound or composition to be selectively cured only in areas exposed to light. The exposed areas of the compound are thereby rendered cured and insoluble, while the unexposed area of the compound or composition remains un-cured and therefore soluble in a developer solvent. Typically, this operation is conducted using ultraviolet light as the light source and a photomask as the means to define where the exposure occurs. The selective patterning of dielectric layers on a silicon wafer can be carried out in accordance with various photolithographic techniques known in the art. In one method, a photosensitive polymer film is applied over the desired substrate surface and dried. A photomask containing the desired patterning information is then placed in close proximity to the photoresist film. The photoresist is irradiated through the overlying photomask by one of several types of imaging radiation including UV light, e-beam electrons, x-rays, or ion beam. Upon exposure to the radiation, the polymer film undergoes a chemical change (cross-links) with concomitant changes in solubility. After irradiation, the substrate is soaked in a developer solution that selectively removes the non-cross-linked or unexposed areas of the film.

The term “passivation” as used herein, refers to the process of making a material “passive” in relation to another material or condition. The term “passivation layers” (PLs) refers to layers that are commonly used to encapsulate semiconductor devices, such as semiconductor wafers, to isolate the device from its immediate environment and, thereby, to protect the device from oxygen, water, etc., as well airborne or space-borne contaminants, particulates, humidity and the like. Passivation layers are typically formed from inert materials that are used to coat the device. This encapsulation process also passivates semiconductor devices by terminating dangling bonds created during manufacturing processes and by adjusting the surface potential to either reduce or increase the surface leakage current associated with these devices. In certain embodiments of the invention, passivation layers contain dielectric material that is disposed over a microelectronic device. Such PLs are typically patterned to form openings therein that provide for making electrical contact to the microelectronic device. Often a passivation layer is the last dielectric material disposed over a device and serves as a protective layer.

The term “Interlayer Dielectric Layer” (ILD) refers to a layer of dielectric material disposed over a first pattern of conductive traces and between such first pattern and a second pattern of conductive traces. Such ILD layer is typically patterned to form openings therein (generally referred to as “vias”) to provide for electrical contact between the first and second patterns of conductive traces in specific regions. Other regions of such ILD layer are devoid of vias and thus prevent electrical contact between the conductive traces of the first and second patterns in such other regions.

A “redistribution layer” or “RDL” as used herein, refers to an extra metal layer on a chip that makes the I/O (input-output) pads of an integrated circuit available in other locations.

“Fan-out package” as used herein, refers to a I/O circuit package in which a silicon chip is extended by molding the chip in a dielectric material (e.g., an epoxy resin) to extend the size of the chip. I/O pads of the silicon chip can be made available to the fan-out region using RDL.

“Underfill,” “underfill composition” and “underfill material” are used interchangeably to refer to material, typically polymeric compositions, used to fill gaps between semiconductor components, such as between or under a semiconductor die and a substrate. “Underfilling” refers to the process of applying an underfill composition to a semiconductor component-substrate interface, thereby filling the gaps between the component and the substrate.

The term “conformal coating” as used herein, refers to a material applied to circuit boards, particularly electronic circuitry, to act as protection against that moisture, dust, chemicals, and temperature extremes that, if uncoated, could result in damage or failure of the electronics to function properly. Typically, the electronics assemblies are coated by brushing, spraying or dipping, with a protective coating layer that conforms to the electronics and isolates it from harsh environmental conditions. The conformal coating can be transparent to permit inspection of underlying circuitry. Furthermore, a suitably chosen material coating can reduce the effects of mechanical stress and vibration on the circuit and its ability to operate in extreme temperatures. For example, in a chip-on-board assembly process, a silicon die is mounted on the board with adhesive or a soldering process, and then electrically connected by wire bonding. To protect the very delicate package, the entire assembly is encapsulated in a conformal coating called a “glob top”.

The term “monomer” refers to a molecule that can undergo polymerization or co-polymerization, thereby contributing constitutional units to the essential structure of a macromolecule (a polymer).

The term “pre-polymer” refers to a monomer or combination of monomers that have been reacted to a molecular mass state intermediate between that of the monomer and higher molecular weight polymers. Pre-polymers are capable of further polymerization via reactive groups they contain, to a fully cured high molecular weight state. Mixtures of reactive polymers with un-reacted monomers may also be referred to a “resin”. The term “resin”, as used herein, refers to a substance containing pre-polymers, typically with reactive groups. In general, resins are pre-polymers of a single type or class, such as epoxy resins and bismaleimide resins.

“Polymer” and “polymer compound” are used interchangeably herein, to refer generally to the combined products of a single chemical polymerization reaction. Combining monomer subunits into a covalently bonded chain produces polymers. Polymers that contain only a single type of monomer are known as “homopolymers,” while polymers containing a mixture of monomers are known as “copolymers.”

The term “copolymers” is inclusive of products that are obtained by copolymersization of two monomer species, those obtained from three monomers species (terpolymers), those obtained from four monomers species (quaterpolymers), etc. It is well known in the art that copolymers synthesized by chemical methods include, but are not limited to, molecules with the following types of monomer arrangements:

alternating copolymers, which contain regularly alternating monomer residues; periodic copolymers, which have monomer residue types arranged in a repeating sequence;

random copolymers, which have a random sequence of monomer residue types;

statistical copolymers, which have monomer residues arranged according to a known statistical rule;

block copolymers, which have two or more homopolymer subunits linked by covalent bonds. The blocks of homopolymer within block copolymers, for example, can be of any length and can be blocks of uniform or variable length. Block copolymers with two or three distinct blocks are called diblock copolymers and triblock copolymers, respectively; and

star copolymers, which have chains of monomer residues having different constitutional or configurational features that are linked through a central moiety.

Furthermore, the length of a polymer chain according to the present invention will typically vary over a range or average size produced by a particular reaction. The skilled artisan will be aware, for example, of methods for controlling the average length of a polymer chain produced in a given reaction and also of methods for size-selecting polymers after they have been synthesized.

Unless a more restrictive term is used, the term “polymer” is intended to encompass homopolymers and co-polymers having any arrangement of monomer subunits as well as co-polymers containing individual molecules having more than one arrangement. With respect to length, unless otherwise indicated, any length limitations recited for the polymers described herein are to be considered averages of the lengths of the individual molecules in polymer.

As used herein, oligomer” or “oligomeric”, refers to a polymer having a finite and moderate number of repeating monomers structural units. Oligomers of the invention typically have 2 to about 100 repeating monomer units; frequently 2 to about 30 repeating monomer units; and often 2 to about 10 repeating monomer units; and usually have a molecular weight up to about 3,000.

The skilled artisan will appreciate that oligomers and polymers may be incorporated as monomers in further polymerization or cross-linking reactions, depending on the availability of polymerizable groups or side chains.

“Thermoplastic elastomer” or “TPE”, as used herein refers to a class of co-polymers that consist of materials with both thermoplastic and elastomeric properties.

“Hard blocks” or “hard segments” as used herein refer to a block of a copolymers (typically a thermoplastic elastomer) that is hard at room temperature by virtue of a high melting point (Tₘ) or T_{g}. By contrast, “soft blocks” or “soft segments” have a T_{g} below room temperature.

As used herein, “reactive diluent” refers to low-viscosity, mono-, bi- or polyfunctional monomers or oligomers or solutions thereof. Exemplary reactive diluents include acrylates, methacrylates, vinyl ethers, thiols, and epoxies.

As used herein, the term “vinyl ether” refers to a compound bearing at least one moiety having the structure:

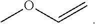

As used herein, the term “vinyl ester” refers to a compound bearing at least one moiety having the structure:

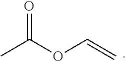

As used herein, “aliphatic” (i.e., non-aromatic) refers to any alkyl, alkenyl, cycloalkyl, or cycloalkenyl moiety.

“Aromatic hydrocarbon” or “aromatic”, as used herein, refers to compounds having one or more benzene rings.

“Alkane,” as used herein, refers to saturated straight chain, branched or cyclic hydrocarbons having only single bonds. Alkanes have general formula CₙH₂ₙ₊₂, where n is any integer.

“Cycloalkane,” refers to an alkane having one or more rings in its structure.

As used herein, “alkyl” refers to straight or branched chain hydrocarbyl groups having from 1 to about 500 carbon atoms. “Lower alkyl” refers generally to alkyl groups having 1 to 6 carbon atoms. The terms “alkyl” and “substituted alkyl” include, respectively, unsubstituted and substituted (as set forth below) C₁-C₅₀₀ straight chain saturated aliphatic hydrocarbon groups, unsubstituted and substituted C₂-C₂₀₀ straight chain unsaturated aliphatic hydrocarbon groups, unsubstituted and substituted C₄-C₁₀₀ branched saturated aliphatic hydrocarbon groups, unsubstituted and substituted C₁-C₅₀₀ branched unsaturated aliphatic hydrocarbon groups.

For example “alkyl” includes but is not limited to: methyl (Me), ethyl (Et), propyl (Pr), butyl (Bu), pentyl, hexyl, heptyl, octyl, nonyl, decyl, undecyl, ethenyl, propenyl, butenyl, penentyl, hexenyl, heptenyl, octenyl, nonenyl, decenyl, undecenyl, isopropyl (i-Pr), isobutyl (i-Bu), tert-butyl (t-Bu), sec-butyl (s-Bu), isopentyl, neopentyl, cyclopropyl, cyclobutyl, cyclopentyl, cyclohexyl, cycloheptyl, cyclooctyl, cyclopentenyl, cyclohexenyl, cycloheptenyl, cyclooctenyl, methylcyclopropyl, ethylcyclohexenyl, butenylcyclopentyl, tricyclodecyl, adamantyl, norbornyl and the like.

In addition, as used herein “C₃₆” and “C₃₆ moiety” refer to all possible structural isomers of a 36 carbon aliphatic moiety, including branched isomers and cyclic isomers with up to three carbon-carbon double bonds in the backbone. One non-limiting example of a C₃₆ moiety is the moiety comprising a cyclohexane-based core and four long “arms” attached to the core, as demonstrated by the following structure:

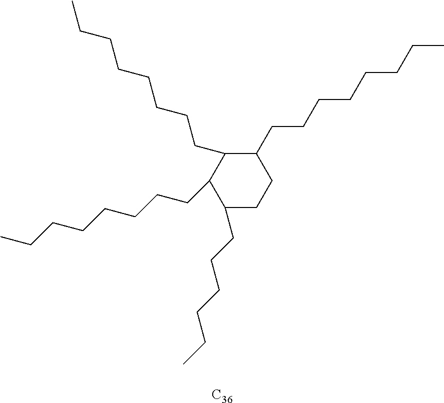 [SMILES: CCCCCCCCC1CCC(CCCCCC)C(CCCCCCCC)C1CCCCCCCC ; "C36"]

As used herein, “cycloalkyl” refers to cyclic ring-containing groups containing in the range of 3 to about 20 carbon atoms, typically 3 to about 15 carbon atoms. In certain embodiments, cycloalkyl groups have in the range of about 4 to about 12 carbon atoms, and in yet further embodiments, cycloalkyl groups have in the range of about 5 to about 8 carbon atoms. “Substituted cycloalkyl” refers to cycloalkyl groups further bearing one or more substituents as set forth below.

As used herein, the term “aryl” refers to unsubstituted, mono-, di- or trisubstituted monocyclic, polycyclic, biaryl aromatic groups covalently attached at any ring position capable of forming a stable covalent bond, certain preferred points of attachment being apparent to those skilled in the art (e.g., 3-phenyl, 4-naphtyl and the like). The aryl substituents are independently selected from the group consisting of halo, —OH, —SH, —CN, —NO₂, trihalomethyl, hydroxypyronyl, C₁₋₁₀ alkyl, aryl C₁₋₁₀ alkyl, C₁₋₁₀ alkyloxy C₁₋₁₀ alkyl, aryl C₁₋₁₀ alkyloxy C₁₋₁₀ alkyl, C₁₋₁₀ alkylthio C₁₋₁₀ alkyl, aryl C₁₋₁₀ alkylthio C₁₋₁₀ alkyl, C₁₋₁₀ alkylamino C₁₋₁₀ alkyl, aryl C₁₋₁₀ alkylamino C₁₋₁₀ alkyl, N-aryl-N—C₁₋₁₀ alkylamino C₁₋₁₀ alkyl, C₁₋₁₀ alkylcarbonyl C₁₋₁₀ alkyl, aryl C₁₋₁₀ alkylcarbonyl C₁₋₁₀ alkyl, C₁₋₁₀ alkylcarboxy C₁₋₁₀ alkyl, aryl C₁₋₁₀ alkylcarboxy C₁₋₁₀ alkyl, C₁₋₁₀ alkylcarbonylamino C₁₋₁₀ alkyl, and aryl C₁₋₁₀ alkylcarbonylamino C₁₋₁₀ alkyl.

As used herein, “arylene” refers to a divalent aryl moiety. “Substituted arylene” refers to arylene moieties bearing one or more substituents as set forth above.

As used herein, “alkylaryl” refers to alkyl-substituted aryl groups and “substituted alkylaryl” refers to alkylaryl groups further bearing one or more substituents as set forth below.

As used herein, “arylalkyl” refers to aryl-substituted alkyl groups and “substituted arylalkyl” refers to arylalkyl groups further bearing one or more substituents as set forth below. Examples of arylalkyl and substituted arylalkyl include but are not limited to (4-hydroxyphenyl)ethyl and or (2-aminonaphthyl) hexenyl, respectively.

As used herein, “arylalkenyl” refers to aryl-substituted alkenyl groups and “substituted arylalkenyl” refers to arylalkenyl groups further bearing one or more substituents as set forth below.

As used herein, “arylalkynyl” refers to aryl-substituted alkynyl groups and “substituted arylalkynyl” refers to arylalkynyl groups further bearing one or more substituents as set forth below.

As used herein, “aroyl” refers to aryl-carbonyl species such as benzoyl and “substituted aroyl” refers to aroyl groups further bearing one or more substituents as set forth below.

“Substituted” refers to compounds or moieties bearing substituents that include, but are not limited to, alkyl, alkenyl, alkynyl, hydroxy, oxo, alkoxy, mercapto, cycloalkyl, substituted cycloalkyl, heterocyclic, substituted heterocyclic, aryl, substituted aryl (e.g., aryl C₁₋₁₀ alkyl or aryl C₁₋₁₀ alkyloxy), heteroaryl, substituted heteroaryl (e.g., heteroaryl C₁₋₁₀ alkyl), aryloxy, substituted aryloxy, halogen, haloalkyl (e.g., trihalomethyl), cyano, nitro, nitrone, amino, amido, carbamoyl, ═O, ═CH—, —C(O)H—, —C(O)O—, —C(O)—, —S—, —S(O)₂—, —OC(O)—O—, —NR—C(O), —NRC—(O)—NR—, —OC(O)—NR—, where R is H or lower alkyl, acyl, oxyacyl, carboxyl, carbamate, sulfonyl, sulfonamide, sulfuryl, C₁₋₁₀ alkylthio, aryl C₁₋₁₀ alkylthio, C₁₋₁₀ alkylamino, aryl C₁₋₁₀ alkylamino, N aryl N C₁₋₁₀ alkylamino, C₁₋₁₀ alkyl carbonyl, aryl C₁₋₁₀ alkylcarbonyl, C₁₋₁₀ alkylcarboxy, aryl C₁₋₁₀ alkylcarboxy, C₁₋₁₀ alkyl carbonylamino, aryl C₁₋₁₀ alkylcarbonylamino, tetrahydrofuryl, morpholinyl, piperazinyl, and hydroxypyronyl.

As used herein, “hetero” refers to groups or moieties containing one or more hetero (i.e., non-carbon) atoms such as N, O, Si and S. Thus, for example “heterocyclic” refers to cyclic (i.e., ring-containing) groups having e.g. N, O, Si or S as part of the ring structure, and having in the range of 3 up to 14 carbon atoms. “Heteroaryl” and “heteroalkyl” moieties are aryl and alkyl groups, respectively, containing e.g. N, O, Si or S as part of their structure. The terms “heteroaryl”, “heterocycle” or “heterocyclic” refer to a monovalent unsaturated group having a single ring or multiple condensed rings, from 1 to 8 carbon atoms and from 1 to 4 hetero atoms selected from nitrogen, sulfur or oxygen within the ring.

“Heteroaryl” includes but is not limited to thienyl, benzothienyl, isobenzothienyl, 2,3-dihydrobenzothienyl, furyl, pyranyl, benzofuranyl, isobenzofuranyl, 2,3-dihydrobenzofuranyl, pyrrolyl, pyrrolyl-2,5-dione, 3-pyrrolinyl, indolyl, isoindolyl, 3H-indolyl, indolinyl, indolizinyl, indazolyl, phthalimidyl (or isoindoly-1,3-dione), imidazolyl. 2H-imidazolinyl, benzimidazolyl, pyridyl, pyrazinyl, pyridazinyl, pyrimidinyl, triazinyl, quinolyl, isoquinolyl, 4H-quinolizinyl, cinnolinyl, phthalazinyl, quinazolinyl, quinoxalinyl, 1,8-naphthyridinyl, pteridinyl, carbazolyl, acridinyl, phenazinyl, phenothiazinyl, phenoxazinyl, chromanyl, benzodioxolyl, piperonyl, purinyl, pyrazolyl, triazolyl, tetrazolyl, thiazolyl, isothiazolyl, benzthiazolyl, oxazolyl, isoxazolyl, benzoxazolyl, oxadiazolyl, thiadiazolyl, pyrrolidinyl-2,5-dione, imidazolidinyl-2,4-dione, 2-thioxo-imidazolidinyl-4-one, imidazolidinyl-2,4-dithione, thiazolidinyl-2,4-dione, 4-thioxo-thiazolidinyl-2-one, piperazinyl-2,5-dione, tetrahydro-pyridazinyl-3,6-dione, 1,2-dihydro-[1,2,4,5]tetrazinyl-3,6-dione, [1,2,4,5]tetrazinanyl-3,6-dione, dihydro-pyrimidinyl-2,4-dione, pyrimidinyl-2,4,6-trione, 1H-pyrimidinyl-2,4-dione, 5-iodo-1H-pyrimidinyl-2,4-dione, 5-chloro-1H-pyrimidinyl-2,4-dione, 5-methyl-1H-pyrimidinyl-2,4-dione, 5-isopropyl-1H-pyrimidinyl-2,4-dione, 5-propynyl-1H-pyrimidinyl-2,4-dione, 5-trifluoromethyl-1H-pyrimidinyl-2,4-dione, 6-amino-9H-purinyl, 2-amino-9H-purinyl, 4-amino-1H-pyrimidinyl-2-one, 4-amino-5-fluoro-1H-pyrimidinyl-2-one, 4-amino-5-methyl-1H-pyrimidinyl-2-one, 2-amino-1,9-dihydro-purinyl-6-one, 1,9-dihydro-purinyl-6-one, 1H-[1,2,4]triazolyl-3-carboxylic acid amide, 2,6-diamino-N.sub.6-cyclopropyl-9H-purinyl, 2-amino-6-(4-methoxyphenylsulfanyl)-9H-purinyl, 5,6-dichloro-1H-benzoimidazolyl, 2-isopropylamino-5,6-dichloro-1H-benzoimidazolyl, 2-bromo-5,6-dichloro-1H-benzoimidazolyl, and the like. Furthermore, the term “saturated heterocyclic” refers to an unsubstituted, mono-, di- or trisubstituted monocyclic, polycyclic saturated heterocyclic group covalently attached at any ring position capable of forming a stable covalent bond, certain preferred points of attachment being apparent to those skilled in the art (e.g., 1-piperidinyl, 4-piperazinyl and the like).

Hetero-containing groups may also be substituted. For example, “substituted heterocyclic” refers to a ring-containing group having in the range of 3 to about 14 carbon atoms that contains one or more heteroatoms and also bears one or more substituents, as set forth above.

As used herein, the term “phenol” includes compounds having one or more phenolic groups having a structure:

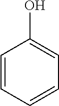

per molecule. The terms aliphatic, cycloaliphatic and aromatic, when used to describe phenols, refers to phenols to which aliphatic, cycloaliphatic and aromatic residues, direct bonding or ring fusion generates combinations of these backbones with phenols.

As used herein, “alkenyl,” “alkene” or “olefin” refers to straight or branched chain unsaturated hydrocarbyl groups having at least one carbon-carbon double bond, and typically having in the range of about 2 to about 500 carbon atoms. In certain embodiments, alkenyl groups have in the range of about 5 to about 250 carbon atoms, about 5 to about 100 carbon atoms, about 5 to about 50 carbon atoms or 5 to about 25 carbon atoms. In other embodiments, alkenyl groups have in the range of about 6 to about 500 carbon atoms, about 8 to about 500 carbon atoms, about 10 to about 500 carbon atoms, about 20 to about 500 carbon atoms, or about 50 to about 500 carbon atoms. In yet further embodiments, alkenyl groups have in the range of about 6 to about 100 carbon atoms, about 10 to about 100 carbon atoms, about 20 to about 100 carbon atoms, or about 50 to about 100 carbon atoms, while in other embodiments, alkenyl groups have in the range of about 6 to about 50 carbon atoms, about 6 to about 25 carbon atoms, about 10 to about 50 carbon atoms, or about 10 to about 25 carbon atoms. “Substituted alkenyl” refers to alkenyl groups further bearing one or more substituents as set forth above.

As used herein, “alkylene” refers to a divalent alkyl moiety, and “oxyalkylene” refers to an alkylene moiety containing at least one oxygen atom instead of a methylene (CH₂) unit. “Substituted alkylene” and “substituted oxyalkylene” refer to alkylene and oxyalkylene groups further bearing one or more substituents as set forth above.

As used herein, “alkynyl” refers to straight or branched chain hydrocarbyl groups having at least one carbon-carbon triple bond, and having in the range of 2 to about 100 carbon atoms, typically about 4 to about 50 carbon atoms, and frequently about 8 to about 25 carbon atoms. “Substituted alkynyl” refers to alkynyl groups further bearing one or more substituents as set forth below.

“Allyl” as used herein, refers to refers to a compound bearing at least one moiety having the structure:

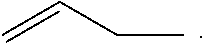

“Imide” as used herein, refers to a functional group having two carbonyl groups bound to a primary amine or ammonia. The general formula of an imide of the invention is:

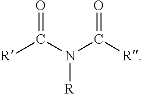

“Polyimide” refers to polymers of imide-containing monomers. Polyimides are typically linear or cyclic. Non-limiting examples of linear and cyclic (e.g. an aromatic heterocyclic polyimide) polyimides are shown below for illustrative purposes.

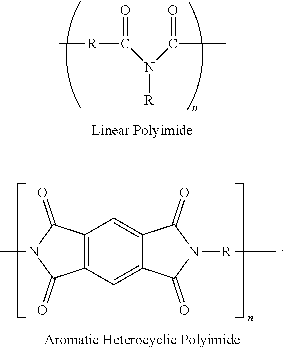

“Maleimide,” as used herein, refers to an N-substituted maleimide having the formula shown below:

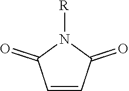

where R is an aromatic, heteroaromatic, aliphatic, or polymeric moiety.

“Bismaleimide” or “BMI”, as used herein, refers to compound in which two imide moieties are linked by a bridge, i.e. a polyimide compound having the general structure shown below:

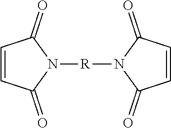

where R is an aromatic, heteroaromatic, aliphatic, or polymeric moiety. BMIs can cure through addition rather than condensation reactions, thus avoiding the formation of volatiles. BMIs can also be cured by a vinyl-type polymerization of a pre-polymer terminated with two maleimide groups.

As used herein, “acyl” refers to alkyl-carbonyl species.

As used herein, the term “acrylate” refers to a compound bearing at least one moiety having the structure:

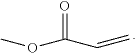

As used herein, the term “methacrylate” refers to a compound bearing at least one moiety having the structure:

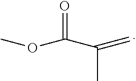

As used herein, “maleate” refers to a compound bearing at least one moiety having the structure:

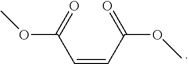

As used herein, “styrene” or “styrenic” refers to a compound bearing at least one moiety having the structure:

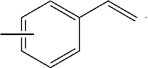

“Benzoxazine” as used herein, refers to a compound bearing at least one moiety having the structure:

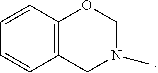

“Fumarate” as used herein, refers to a compound bearing at least one moiety having the structure:

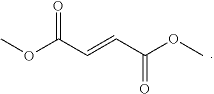

“Cyanate ester” as used herein, refers to a compound bearing at least one moiety having the structure:

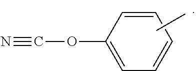

“Cyanoacrylate” as used herein, refers to a compound bearing at least one moiety having the structure:

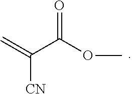

“Propargyl” as used herein, refers to a compound bearing at least one moiety having the structure:

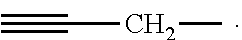

As used herein, “norbornyl” refers to a compound bearing at least one moiety having the structure:

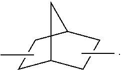

As used herein, the term “acyloxy benzoate” or “phenyl ester” refers to a compound bearing at least one moiety having the structure:

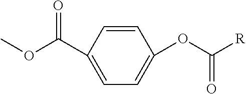

where R═H, lower alkyl, or aryl.

As used herein, a “primary amine terminated difunctional siloxane bridging group” refers to a moiety having the structural formula:

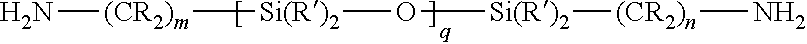

where each R is H or Me, each R′ is independently H, lower alkyl, or aryl; each of m and n is an integer having the value between 1 to about 10, and q is an integer having the value between 1 and 100.

“Diamine,” as used herein, refers generally to a compound or mixture of compounds, where each species has 2 amine groups.

The term “solvent,” as used herein, refers to a liquid that dissolves a solid, liquid, or gaseous solute, resulting in a solution. “Co-solvent” refers to a second, third, etc. solvent used with a primary solvent.

As used herein, “polar protic solvents” are ones that contain an O—H or N—H bond, while “polar aprotic solvents” do not contain an O—H or N—H bond.

As used herein, the term “citraconimide” refers to a compound bearing at least one moiety having the structure:

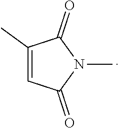

“Itaconate”, as used herein refers to a compound bearing at least one moiety having the structure:

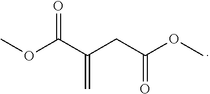

As used herein, the terms “halogen,” “halide,” or “halo” include fluorine, chlorine, bromine, and iodine.

As used herein, “siloxane” refers to any compound containing a Si—O moiety. Siloxanes may be either linear or cyclic. In certain embodiments, siloxanes of the invention include 2 or more repeating units of Si—O. Exemplary cyclic siloxanes include hexamethylcyclotrisiloxane, octamethylcyclotetrasiloxane, decamethylcyclopentasiloxane, dodecamethylcyclohexasiloxane and the like.

As used herein, “oxirane” or “epoxy” refers to divalent moieties having the structure:

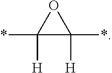

The asterisks denote a site of attachment of the oxirane group to another group. If the oxirane group is at the terminal position of an epoxy resin, the oxirane group is typically bonded to a hydrogen atom:

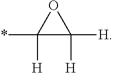

The terminal oxirane group is often part of a glycidyl group:

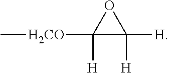

The term “epoxy” also refers to thermosetting epoxide polymers that cure by polymerization and cross-linking when mixed with a catalyzing agent or “hardener,” also referred to as a “curing agent” or “curative.” Epoxies of the present invention include, but are not limited to aliphatic, cycloaliphatic, glycidyl ether, glycidyl ester, glycidyl amine epoxies, and the like, and combinations thereof.

The term “epoxy” also refers to thermosetting epoxide polymers that cure by polymerization and cross-linking when mixed with a catalyzing agent or “hardener,” also referred to as a “curing agent” or “curative.” Epoxies of the present invention include, but are not limited to aliphatic, cycloaliphatic, glycidyl ether, glycidyl ester, glycidyl amine epoxies, and combinations thereof.

As used herein, the term “oxetane” refers to a compound bearing at least one moiety having the structure:

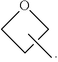

As used herein, “benzophenone” refers the moiety:

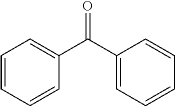 [SMILES: O=C(c1ccccc1)c1ccccc1]

or a compound bearing a benzophenone moiety, including but not limited to benzophenone-containing anhydrides such as benzophenone tetracarboxylic dianhydride:

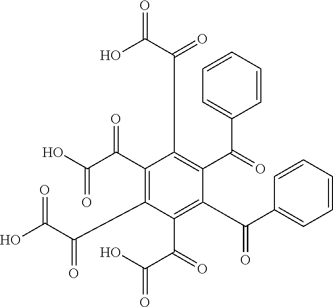 [SMILES: O=C(O)C(=O)c1c(C(=O)C(=O)O)c(C(=O)C(=O)O)c(C(=O)c2ccccc2)c(C(=O)c2ccccc2)c1C(=O)C(=O)O]

As used herein, the term “free radical initiator” refers to any chemical species that upon exposure to sufficient energy (e.g., light, heat, or the like) decomposes into parts (“radicals”), which are uncharged, but every one of such parts possesses at least one unpaired electron.

“Photoinitiation” as used herein, refers to polymerization initiated by light. In most cases, photoinduced polymerization, utilizes initiators to generate radicals, which can be one of two types: “Type I Photoinitiators” (unimolecular photoinitiators), which undergo homolytic bond cleavage upon absorption of light; and “Type II Photoinitiators” (bimolecular photoinitiators), consisting of a photoinitiator such as benzophenone or thioxanthone and a coinitiator such as alcohol or amine.

As used herein, the term “coupling agent” refers to chemical species that are capable of bonding to a mineral surface and that also contain polymerizably reactive functional group(s) so as to enable interaction with a polymer composition, such as a compound or composition of the invention. Coupling agents thus facilitate linkage of e.g. an adhesive, die-attach paste, passivation layer, film, or coating to the substrate to which it is applied.

As used herein, “breakdown voltage” of an dielectric insulator is the minimum voltage that causes a portion of an insulator to become electrically conductive.

“Glass transition temperature” or “T_{g}” is used herein to refer to the temperature at which an amorphous solid, such as a polymer, becomes brittle on cooling, or soft on heating. More specifically, it defines a pseudo second order phase transition in which a supercooled melt yields, on cooling, a glassy structure and properties similar to those of crystalline materials e.g. of an isotropic solid material.

“Low glass transition temperature” or “Low T_{g}” as used herein, refers to a T_{g} at or below about 50° C. “High glass transition temperature” or “High T_{g}” as used herein, refers to a T_{g} of at least about 60° C., at least about 70° C., at least about 80° C., at least about 100° C. “Very high glass transition temperature” and “very high T_{g}” as used herein, refers to a T_{g} of at least about 150° C., at least about 175° C., at least about 200° C., at least about 220° C. or higher. High glass transition temperature compounds and compositions of the invention typically have a T_{g} in the range of about 70° C. to about 300° C.

“Modulus” or “Young's modulus” as used herein, is a measure of the stiffness of a material. Within the limits of elasticity, modulus is the ratio of the linear stress to the linear strain, which can be determined from the slope of a stress-strain curve created during tensile testing.

The “Coefficient of Thermal Expansion” or “CTE” is a term of art describing a thermodynamic property of a substance. The CTE relates a change in temperature to the change in a material's linear dimensions. As used herein “α1 CTE” or “α1” refers to the CTE before the T_{g}, while “α2 CTE” refers to the CTE after the T_{g}. Most polymers have CTEs between about 50 and 200.

“Low Coefficient of Thermal Expansion” or “Low CTE” as used herein, refers to an CTE of less than about 50 ppm/° C., typically less than about 30 ppm/° C. or less than about 10 ppm/° C.

“Viscosity” refers to resistance to gradual deformation by shear stress or tensile stress. Viscosity of liquids can be understood informally as the “thickness”. “Low viscosity” as used herein, is exemplified by water (0.894 centipoise (cP)) and typically refers to a viscosity at 25° C. less than about 10,000 cP, often less than about 1,000 cP, typically less than about 100 cP and often less than about 10 cP. “High viscosity” fluids have a viscosity at 25° C. greater than about 20,000 cP, typically greater than about 50,000 cP and often greater than about 100,000 cP. Generally, for easy handling and processing, the viscosity of a composition of the present invention should be in the range of about 10 to about 12,000 cP, typically about 10 to about 2,000 cP, and often about 10 to about 1,000 cP.

“Thermogravimetric analysis” or “TGA” refers to a method of testing and analyzing a material to determine changes in weight of a sample that is being heated in relation to change in temperature. “Decomposition onset” refers to a temperature when the loss of weight in response to the increase of the temperature indicates that the sample is beginning to degrade.

As used herein the term “85/85” is used to describe a highly accelerated stress test (HAST) performed on electronics components. In this test, the electronics parts are exposed to 85° C. and 85% relative humidity for hundreds to thousands of hours. The parts are then checked for adhesion and/or electrical performance.

As used herein the term “PCT” or “pressure-cook test” is used to describe a HAST test performed on electronics components. In this case the electronics parts are placed in a pressure cooker and exposed to 121° C. with 100% relative humidity for up to 96 hours. The parts are then checked for adhesion or electrical performance. This is typically the highest reliability test performed on electronics components.

As used herein the term “dielectric constant” or “relative permittivity” (Dk) is the ratio of the permittivity (a measure of electrical resistance) of a substance to the permittivity of free space (which is given a value of 1). In simple terms, the lower the Dk of a material, the better it will act as an insulator. As used herein, “low dielectric constant” or “low-x” refers to a material with a Dk less than that of silicon dioxide, which has Dk of 3.9. Thus, “low dielectric constant refers” to a Dk of less than 3.9, typically less than about 3.4, frequently less than about 3.2, and most often less than about 3.0. Most polyimides have a Dk of about 3.4.

As used herein the term “dissipation dielectric factor”, “dissipation dielectric factor”, and abbreviation “Df” are used herein to refer to a measure of loss-rate of energy in a thermodynamically open, dissipative system. In simple terms, Df is a measure of how inefficient the insulating material of a capacitor is. It typically measures the heat that is lost when an insulator such as a dielectric is exposed to an alternating field of electricity. The lower the Df of a material, the better its efficiency. “Low dissipation dielectric factor” typically refers to a Df of less than about 0.01 at 1-GHz frequency, frequently less than about 0.005 at 1-GHz frequency, and most often 0.001 or lower at 1-GHz frequency.

“Thixotropy” as used herein, refers to the property of a material which enables it to stiffen or thicken in a relatively short time upon standing, but upon agitation or manipulation to change to low-viscosity fluid; the longer the fluid undergoes shear stress, the lower its viscosity. Thixotropic materials are therefore gel-like at rest but fluid when agitated and have high static shear strength and low dynamic shear strength, at the same time.

### Temporary Adhesives

Temporary adhesives are used through the fabrication of electronics devices and components, at various steps where a removable attachment is required, or when permanent attachment is facilitated by temporarily holding two or more parts together. An exemplary use of temporary adhesive is in the process of backgrinding silicon wafers to a desired thickness.

Backgrinding is a semiconductor device fabrication process that reduces the thickness of semi-conductor wafers (e.g., crystalline silicon wafers), which allows stacking and high-density packaging of integrated circuits (IC), often referred to as “chips”. ICs are produced from semiconductor wafers that may undergo a multitude of processing steps under harsh conditions to produce a final package. Silicon wafers predominantly in use today have diameters of 200 mm and 300 mm from which hundreds of IC microchips can be made. Wafers can also be made of materials other than pure silicon and/or can be doped with metals such as B, Al, Ar, P, Li, Bi, Ga and combinations thereof. For the purposes of this disclosure, “wafer” refers to semiconductor wafers made from silicon, doped silicon and/or any other material.

Wafers are initially produced having a thickness of approximately 750 μm, which ensures mechanical stability and avoids warping during processing steps. These thick wafers are then ground down to application-specific thickness, typically 75 to 50 μm.

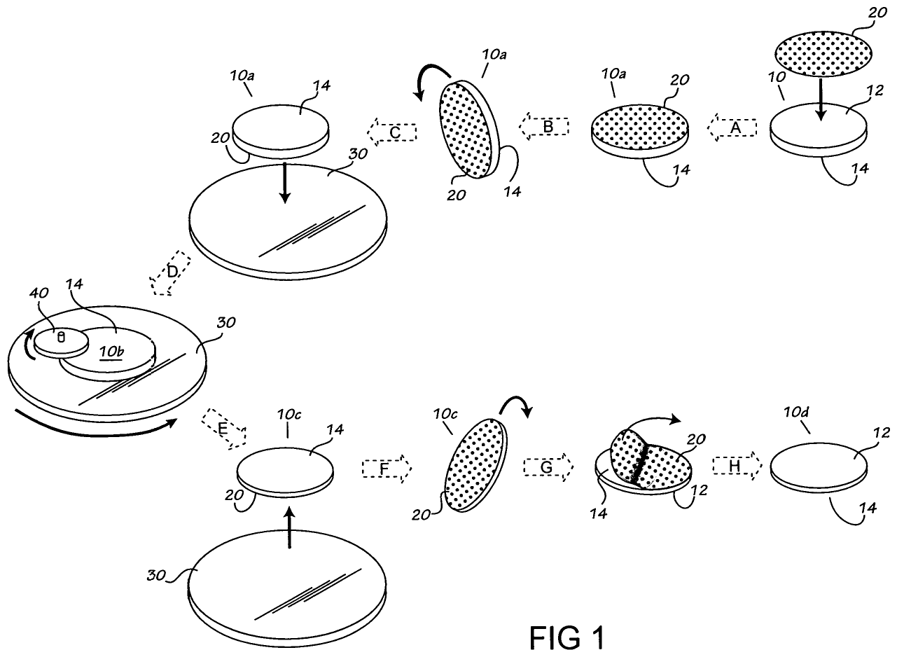

The process of thinning a wafer is referred to as “backgrinding” and is illustrated in FIG. 1 (where each of steps A-H is represented by a lettered arrow). A temporary adhesive 20 is applied to the top surface 12 of a wafer 10 (step A). In some embodiments, a release layer or compound (not shown) is also applied to wafer 10 and/or support 30 prior to applying temporary adhesive 20 to facilitate subsequent removal (described below). Backgrinding can generate significant heat. Thus, the temporary adhesive selected for this process should be very thermally stable for extended periods of time at temperatures in excess of 250° C., preferably in excess of 300° C. and often in excess of 350° C. with little or no weight loss that would cause delamination.

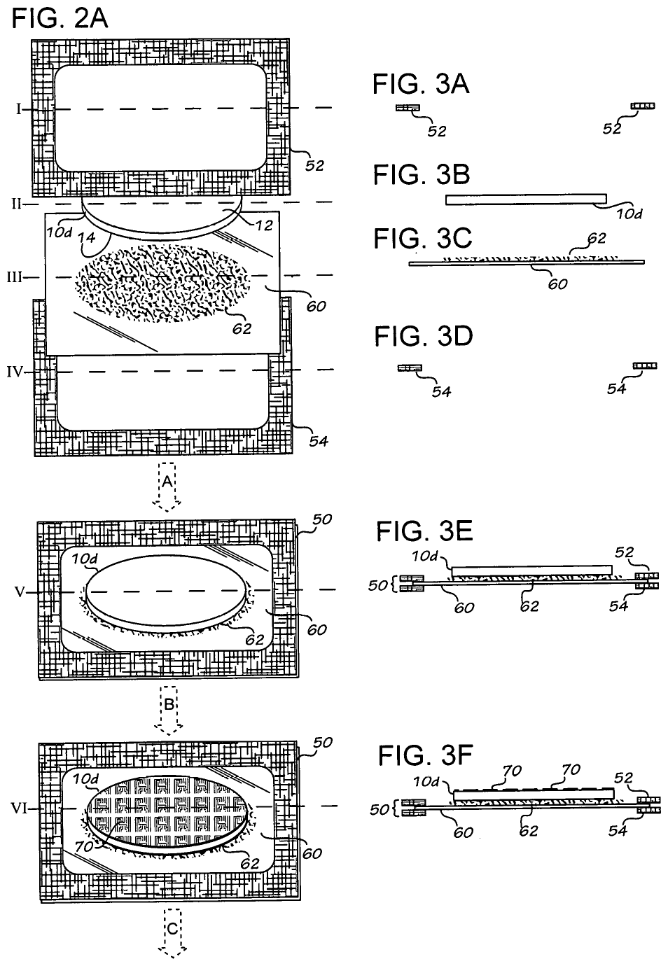

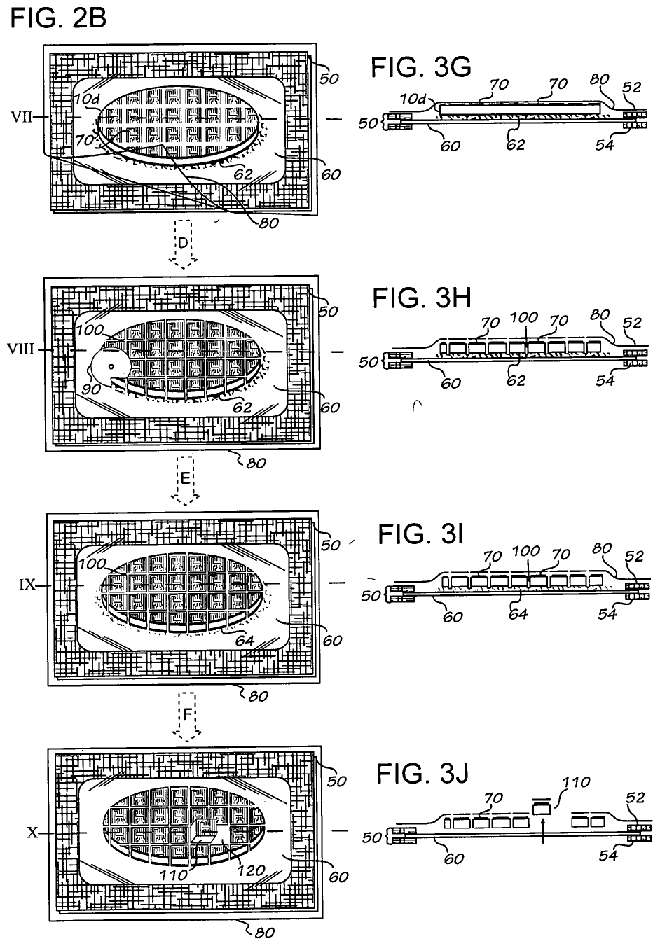

In some embodiments, the wafer 10 incudes a circuit pattern and/or other electronic elements (e.g. solder bumps) disposed on the top surface 12 prior to backgrinding. In other embodiments, these patterns and/or elements are applied following backgrinding as illustrated in FIG. 2.

In addition to securing the wafer in place, the temporary backgrinding adhesive 20 protects the wafer surface from surface damage and contamination. Thus, the adhesive materials must be tough enough to withstand physical assaults, as well as being resistant to many solvents used in the grinding and cleaning processes. Typically, the adhesive 20 is a UV-curable or is pressure-sensitive tape or film. In certain embodiments of the invention, the adhesive 20 is sprayed or spin-coated onto wafer 10. Advantageously, sprayed or spin-coated adhesive can be applied to a layer thickness that accommodates surface variabilities (e.g. solder bumps, vias, etc.).

Next (step B), the adhesive-coated wafer 10a is inverted to expose the back side of the wafer, and the adhesive side is bonded to a support 30 (step C), which support is frequently glass. In some embodiments, a release layer or compound (not shown) is also applied to wafer 10 and/or support 30 prior to applying temporary adhesive 20 to facilitate subsequent removal (described below. The resulting support-bound wafer 10b, is then ground with grinding and polishing means 40 to a desired thickness in step D. The grinding and polishing means 40 can include abrasive grinding tools that contact the wafer back side 14 as well as various grits of grinding and polishing compounds. Grinding is completed when the wafer thickness has been reduced, the back side 14 of the support-bound wafer 10b has been polished to the required smoothness, and the wafer thoroughly cleaned to remove all traces of grinding residue and contaminants.

The wafer is then removed from the support (step E), which in some embodiments of the invention, can be accomplished by further exposure to UV irradiation. In these embodiment, the adhesive composition is either pressure sensitive or is initially partially cured (e.g., with a controlled exposure to UV), producing a highly adhesive composition that effectively adheres to both the wafer top side 12 (step A) and backgrinding wafer support 30 (step C). To remove the adhesive from the support, further exposure to UV fully cures the adhesive to a glassy, high T_{g} composition which separates easily from support 30. In other embodiments of the invention, the adhesive is thermoplastic, and UV-curable such that it stiffens when cured and is easier to peel off In certain embodiments of the present invention, removal of thinned wafer 10b from support 30 is accomplished with the assistance of an air jet, which introduces voids and/or gaps between wafer 10b and support 30.

The thinned wafer 10c, once removed from the support (step F), can be inverted (step G) and the remaining adhesive removed by peeling with the assistance of an air jet (step H) and if needed, soaking in a dish of cyclopentanone or cyclohexanone (not shown) to dissolve the polymer leaving the adhesive-free, thinned wafer 10d.

Dicing is the process by which die are separated from a semiconductor wafer, typically following the processing of the wafer, as illustrated in FIGS. 2A and 2B, and in parallel FIGS. 3A-3J, which show cross-sections of the structures illustrated in FIGS. 2A and 2B. FIGS. 1, 2A, 2B and 3A-J, illustrate an exemplary work flow in which wafers are first thinned, then processed (e.g., “patterned” to form circuits on the wafer), and thereafter, cut into individual dies. Is should be noted that these steps can be performed in any order, such as circuit formation, followed by thinning, and thereafter dicing. Indeed, even packaging, typically a post-singulation process, can be performed at the wafer-level prior to dicing. This process, known as “fan-in” wafer-level packaging, yields packages that are die-sized instead of larger than die size. In some aspects, partial dicing can be performed prior to patterning and thinning. In this aspect, the final separation of individual dies occurs when the wafer is ground to meet the partial dicing cuts. Variations on these steps, including the order in which they are performed, are encompassed by the invention and within the ordinary level of skill in the art.

As illustrated in FIG. 2A, wafer dicing typically begins with mounting a thinned wafer 10d on dicing tape 60 that includes an adhesive 62. Dicing tape 60 typically has a PVC (polyvinylchloride), PO (polyoxymethylene), PE (polyethylene), PET (polyethylene terephthalate), or similar strong, high-temperature-resistant plastic backing, with an adhesive deposited thereon. In some embodiments, adhesive 62 covers the complete surface of the tape. In other embodiments, adhesive 62 covers a surface area corresponding to wafer size as illustrated in FIG. 2A. In some embodiments, the adhesive is pressure-sensitive, while in other embodiments, the adhesive is UV-cured. The tape, with mounted wafer is assembled with a support frame 50 (step A). Typically, support frame 50 is made of thin metal and may consist of a bottom frame 54 and a top frame 52. Alternatively, frame 50 may have only a bottom frame 54 with the top frame function supplied by securing the frame in a dicing device. In either case, the frame must elevate the wafer to permit access by subsequent processing equipment as shown in FIG. 3E.

The requirements for dicing tape 60, and particularly the adhesive 62, are that it withstand the conditions of temperature and pressure of dicing and any other processes that will be performed on the mounted wafer, yet easily release each individual “singulated” die 110. As the processes carried out on wafers prior to dicing vary, dicing tape 60 with a range of tack strengths are required. In some embodiments, low tack adhesive is used to facilitate easy release, while for other applications that require higher adhesion during processing, a UV-releasable adhesive is required. Such adhesives initially have high tack strength upon partial curing. After dicing, the adhesive is fully cured, which reduces adhesion and releases the die 110.

The mounted wafer can be processed by applying circuit tracings/patterns, and other pre-packaging features, which may be performed by plating, photolithography, drilling, or any other suitable method known in the art. Application of circuit patterns 70 is represented by step B. Advantages of performing such steps on a wafer rather than singulated die include efficient use of the wafer, the ability to inspect and analyze circuits en masse, and positioning of circuitry to allow a regularly spaced unpatterned scribe line or “saw street” matched to the dicing equipment.

After patterning, the wafer 10d is covered with a film 80, typically Mylar® (polyethylene terephthalate) (step C), to protect the delicate wiring 70 from sawdust and physical damage during dicing.

The wafer 10d is then cut with a dicing means 90, such as a saw (as illustrated) or a laser, along the saw street, forming a channel 100 between individual die (step D). If a UV release adhesive is used, the adhesive 62 is then exposed to UV light to release 64 the die from the dicing tape (step E). Finally, the individual die 110 are removed one at a time (step F) from wafer 10d, leaving a void 120. Removal can include picking the individual die from above (e.g. using a vacuum device), pushing the die from below (see arrow in FIG. 3J), or a combination thereof.

### Pendant Polyimides

The present invention provides compounds with pre-imidized backbones and photopolymerizable, pendant functional groups, according to the following structural formulae IA, IB, IC, and 1D:

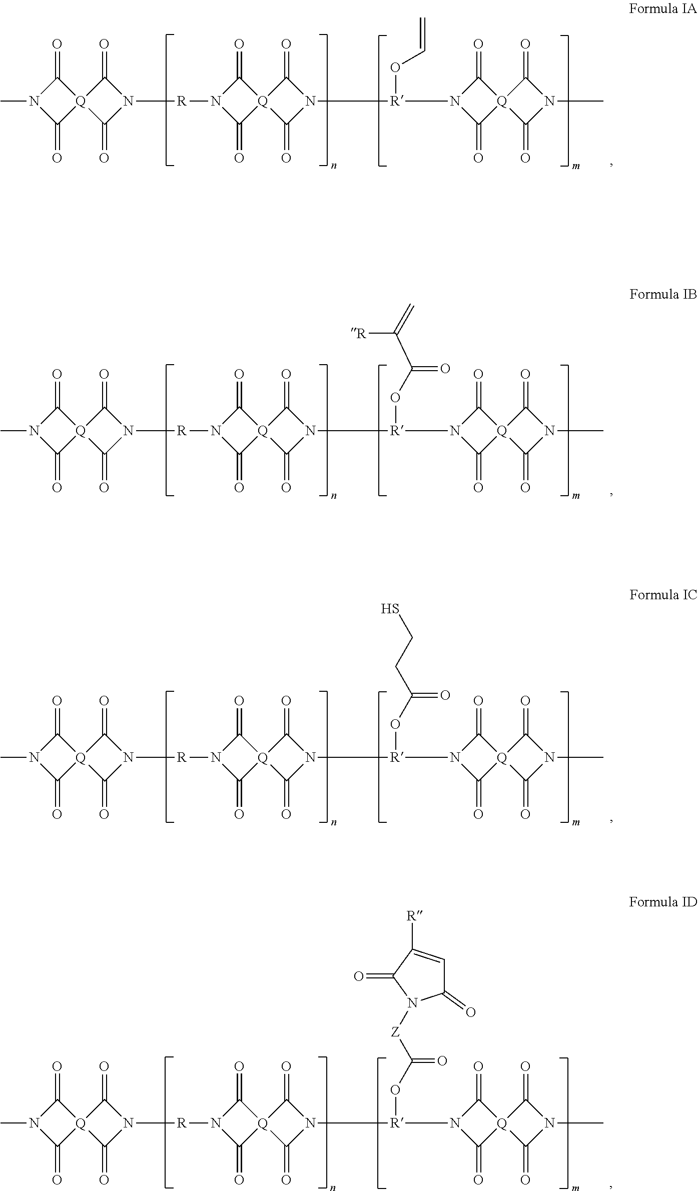

where R independently a substituted or unsubstituted aliphatic, cycloaliphatic, alkenyl, polyether, polyester, polyamide, aromatic, heteroaromatic, or siloxane moieties; R′ is independently a diamine with alcohol functionality, such as 1,3-diamino-2-propanol or 3,5-diaminobenzyl alcohol; Each Q is independently a substituted or unsubstituted aliphatic, cycloaliphatic, alkenyl, polyether, polyester, polyamide, aromatic, heteroaromatic, or siloxane moiety; R″ is hydrogen or methyl; z is independently a substituted or unsubstituted aliphatic or aromatic; and n and m are integers having a value from 10 to about 100.

The present invention provides temporary adhesive compositions suitable for backgrinding, dicing and other applications. The present invention is based in part on the observation that highly flexible, low surface energy temporary adhesives with high tensile strength are more easily removed than more rigid ones, coupled with the development of methods for synthesizing high molecular weight (>20,000 Daltons), flexible polyimides that are adhesive, but easily peeled off a surface to which they are applied.

The invention also provides methods for applying a temporary adhesive to an element, such as a wafer, the methods comprising spin-coating a temporary adhesive composition described herein on a side of an article (e.g. the top side of a wafer), thereby forming a layer of adhesive on the top of the article; and drying the layer of adhesive. Thus, the invention also provides articles coated on at least one side with a temporary adhesive described herein.

The invention further provides methods for adhering two articles together comprising the steps of coating one side or area of a first article with an adhesive composition of the invention; contacting the adhesive-coated side or area of the first article with a second article, thereby adhering the two articles together. In certain aspects of the invention, one side or area of both the first and second articles are coated with adhesive and the adhesive-coated sides of the two articles are contact with each other. The articles can be coated by any available method including spin-coating described above, spraying, film application and other methods known in the art. In certain aspects of the invention, the method further provides the step of curing the adhesive applied to the two articles, thereby forming a flexible, high temperature-resistant bond.

The invention also provides methods for removing the polyimide temporary adhesives described herein from an article, such as a wafer, to which it is adhered, comprising the steps of: applying an air jet to the temporary adhesive adhered to an article to initiate removal; and peeling the adhesive off of the article. In some aspects, the method further provides soaking and/or washing the article to facilitate removal of residual polymeric material.

Compounds of formula IA, IB, IC and ID are also useful in many other applications. Adhesive compositions of the invention that include the polyimide of Formula are suitable for use in backgrinding and dicing processes, which increasingly require high temperature stability because the grinding and singulation processes typically create temperatures in excess of 250° C. Thus, the temporary adhesives of the invention are typically stable to temperatures of at least about 250° C., frequently to temperatures of at least about 300° C., and can remain stable at temperatures of about 350° C. or higher during extended exposures to heat generated during backgrinding as well as other processes encountered during IC chip manufacturing. The high temperature stability of adhesives comprising polyimides of the invention is illustrated by the TGA diagrams, which show less than 2% weight loss at 350° C.

Moreover, temporary adhesive compositions of the invention experience little or no weight loss during curing or exposure to heating that would cause delamination from the wafer or support during high temperature processes. Furthermore, the temporary adhesive formulations of the invention are resistant to many common solvents that may be used in during electronic article manufacture yet are removable with other solvents. The temporary adhesive formulations of the invention are fully removable from wafers after the processes of backgrinding, patterning and dicing are complete.

### Preparation of Pendent Polyimides

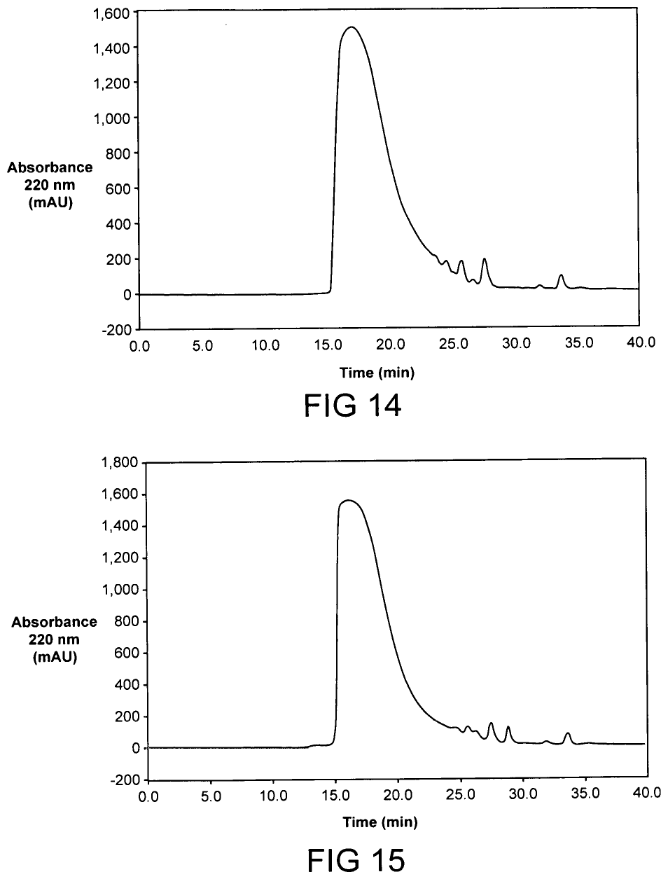

The polyimides of Formulae IA, IB, IC and ID are prepared by contacting at least two diamines with at least one dianhydride in a suitable solvent. The solvents used most often during polyimide synthesis are polar aprotic solvents such as N-Methyl-2-pyrrolidone (NMP), dimethylformamide (DMF), dimethylacetamide (DMAC), and dimethyl sulfoxide (DMSO). Very high molecular weight polyimides can be produced by adding the dianhydride to a diamine solution and stirring at room temperature for several hours. See FIGS. 14-21 (Compounds 1-B, 1-D, 1-E, 1-H, 2-A, 3-A and 4-A). The polyamic acid intermediate thus formed is very soluble in these polar aprotic solvents. An aromatic solvent such as toluene can be added to form an azeotrope with the water generated by thermal cyclodehydration during polyimide synthesis, thereby driving removal of the water. However, such solvents typically have very high boiling points and may need to be removed from the produced resin after the reaction is complete. Alternatively, the resin can be left in solution until needed; however, it may be difficult to remove all of the solvent from adhesive or other compositions or formulations without application of very high temperature, even when used as a thin film.

Alternative solvents for producing functionalized polyimides include aromatic solvents, particularly ether-functionalized aromatic solvents, such as anisole. Anisole is effective for dissolving polyimides as well the polyamic acid intermediate at high temperature. Anisole is relatively unreactive and produces polyimides with minimum color, whereas polar aprotic solvents produce polyimides that are very dark in color.

In one embodiment of the invention, functionalized polyimides are synthesized by adding diamines (one of which contains an alcohol moiety) to a reactor with anisole, followed by the addition of the dianhydride. Stirring nearly equivalent amount of diamine and dianhydride at room temperature produces the highest molecular weights. Although the polyamic acid intermediate may not be very soluble in ether solvents, as the mixture is slowly heated over 1 hour and as the temperature goes above 100° C., the components dissolve well, and the reaction is confirmed by the production of water. In certain cases, a small amount of polar aprotic solvent such as NMP, DMAC or DMF may also be added as a co-solvent to aid the solubility. After one to two hours of reflux, all the water is removed from the reaction and the fully imidized polymer is formed. A curable moiety can then be formed by converting the alcohol pendent group into a vinyl ether, a (meth)acrylate, a mercapto-ester or a maleimido-ester. The pendent ester moieties are formed via a reaction with the aid of an acid catalyst. In order to synthesize a product that is easily worked-up, a polymer bound sulfonic acid catalyst (Amberlyst® 36 resin; Dow Chemical, Midland, Mich.) can be used. The beads of catalyst can simply be filtered out of solution after the reaction is complete. The pendent vinyl ether groups are produced via the transetherification reaction with an excess of butyl vinyl ether in the presence of palladium acetate phenanthroline complex.

A wide variety of diamines are contemplated for use in the practice of the invention, such as for example: dimer diamine; 1,10-diaminodecane; 1,12-diaminododecane; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomenthane; 1,8-diaminooctane; 1,9-diaminononane; 3,3-diamino-N-methyldipropylamine; diaminomaleonitrile; 1,3-diaminopentane; 9,10-diaminophenanthrene; 4,4-diaminooctafluorobiphenyl; 3,5-diaminobenzoic acid; 3,7-diamino-2-methoxyfluorene; 4,4-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4-diamino-2,2-bistrifluoromethylbiphenyl; bis(amino-3-chlorophenyl)ethane; bis(4-amino-3,5-dimethylphenyl)methane; bis(4-amino-3,5-diisopropylphenyl)methane; bis(4-amino-3,5-methyl-isopropylphenyl)methane; bis(4-amino-3,5-diethylphenyl)methane; bis(4-amino-3-ethylphenyl)methane; diaminofluorene; 4,4-(9-Fluorenylidene)dianiline; diaminobenzoic acid; 2,3-diaminonaphthalene; 2,3-diaminophenol; 3,5-diaminobenzyl alcohol; bis(4-amino-3-methylphenyl)methane; bis(4-amino-3-ethylphenyl)methane; 4,4-diaminophenylsulfone; 3,3′-diaminophenylsulfone; 2,2-bis(4,-(4-aminophenoxy)phenyl)sulfone; 2,2-bis(4-(3-aminophenoxy)phenyl)sulfone; 4,4-oxydianiline; 4,4-diaminodiphenyl sulfide; 3,4-oxydianiline; 2,2-bis(4-(4-aminophenoxy)phenyl)propane; 1,3-bis(4-aminophenoxy)benzene; 4,4-bis(4-aminophenoxy)biphenyl; 4,4-diamino-3,3-dihydroxybiphenyl; 4,4-diamino-3,3-dimethylbiphenyl; 4,4-diamino-3,3-dimethoxybiphenyl; Bisaniline M (4-[2-[3-[2-(4-aminophenyl)propan-2-yl]phenyl]propan-2-yl]aniline)]Bisaniline); Bisaniline P (4-[2-[4-[-(4-aminophenyl)propan-2-yl]phenyl]propan-2-yl]aniline); 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3′,5,5′-tetramehylbenzidine; 4,4′-diaminobenzanilide; 2,2-bis(4-aminophenyl)hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; 3(4),8(9)-bis(aminomethyl)tricyclo(5.2.1.0^{2,6})decane; ethanolamine; 1,3-cyclohexanebis(methylamine); 1,3-diamino-2-propanol; 1,4-diaminobutane, 1,5-diaminopentane; 1,6-diaminohexane; 2,2-bis[4-(3-aminophenoxy)phenyl]propane; 2,3,5-tetramethylbenzidine; 2,3-diamononaphtalene; polyalkylenediamines (e.g. Huntsman's Jeffamine® D-230, D-400, D2000, and D-4000 products), and any other diamines or polyamines, especially if they contain an alcohol moiety.

A wide variety of dianhydrides are also contemplated for use in the practice of the invention, including: 4,4′-Bisphenol A dianhydride; pyromellitic dianhydride; 1,2,3,4-cyclobutanetetracarboxylic dianhydride; 1,4,5,8-naphthalenetetracarboxylic dianhydride; 3,4,9,10-perylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3′,4,4′-benzophenone tetracarboxylic dianhydride; 3,3′,4,4′-biphenyl tetracarboxylic dianhydride; 4,4′-oxydiphthalic anhydride; 3,3′,4,4′-diphenylsulfone tetracarboxylic dianhydride; 2,2′-bis(3,4-dicarboxyphenyl)hexafluoropropane dianhydride; 4,4′-bisphenol A diphthalic anhydride; 5-(2,5-dioxytetrahydro)-3-methyl-3-cyclohexene-1,2-dicarboxylic anhydride; ethylene glycol bis(trimellitic anhydride); hydroquinone diphthalic anhydride; 1,2,3,6-tetrahydrophthalic anhydride; 3,4,5,6-tetrahydrophthalic anhydride; 1,8-naphthalic anhydride; glutaric anhydride; dodecenylsuccinic anhydride; hexadecenylsuccinic anhydride; hexahydrophthalic anhydride; methylhexahydrophthalic anhydride; tetradecenylsuccinic anhydride; and the like. Use of mono-anhydrides terminates the polymer.

Additional dianhydrides contemplated for use include, but are not limited to:

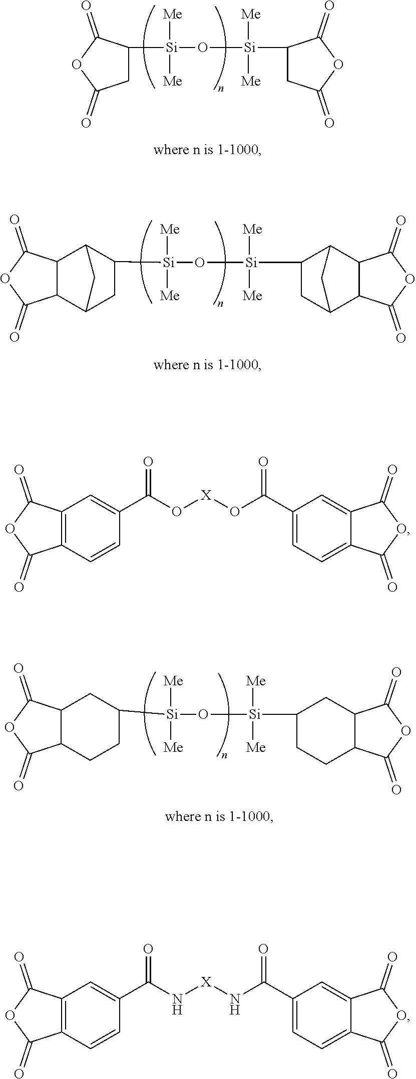

where X is saturated, unsaturated, strait or branched alkyl, polyester, polyamide, polyether, polysiloxane or polyurethane;

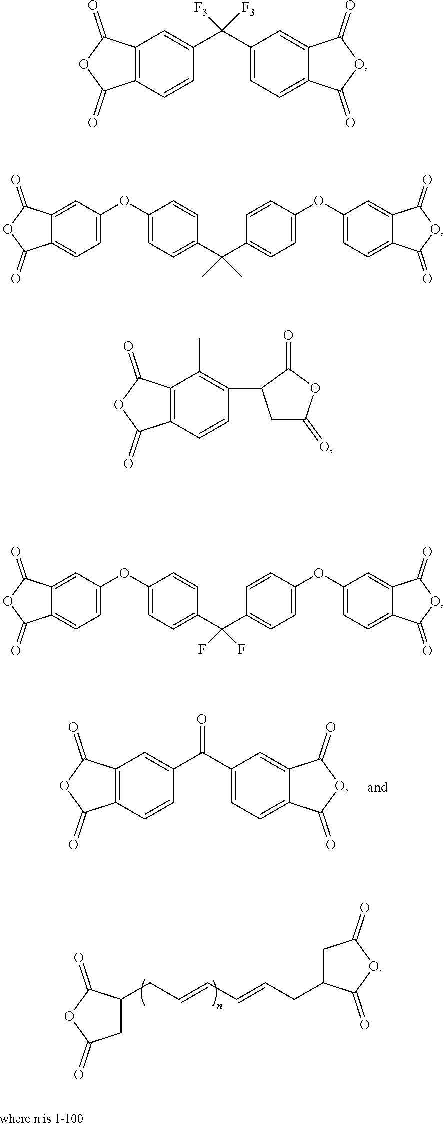

In another embodiment, the invention provides coating and passivation formulations comprising:

A. at least one curable, functionalized polyimide described here;

B. at least one reactive diluent; and

C. a solvent in which the functionalized polyimide is soluble.

In certain aspects, the formulation may also include:

D. one or more adhesion promoters;

E. one or more coupling agents; and

F. one or more UV initiators.

In certain embodiments, the present invention provides chain-propagated polyimide polymers having a flexible aliphatic backbone in place of the aromatic ether backbone found in conventional polyimide polymers, while having the same high temperature resistance due to their imide linkage. Polyimide polymers of the invention display lower shrinkage than conventional polyimide polymers due to the chain propagation mechanism, thereby reducing stress on wafers passivated with such polymers. Taken together, the methods and materials of the invention reduce the potential for delamination and warpage of semiconductor interconnection layers.

The polyimides are suitable for use in preparing redistribution layers, passivation layers and other chip coatings and are less subject to stress effects than prior polyimides. Therefore, the polyimides of the present invention and formulations thereof, are compatible with very thin silicon wafers.

In other embodiments, the curable functionalized polyimides may be combined with other monomers, such as thermoset monomers, and reactive diluents, fillers, and flame-retardants to make fully formulated curable compositions.

Co-monomers suitable for use in the polyimide containing composition include but are not limited to, acrylates methacrylates, acrylamides, methacrylamides, maleimides, vinyl ethers, vinyl esters, styrenic compounds, allyl functional compounds, epoxies, epoxy curatives, benzoxazines, cyanate esters, polyphenylene oxides (PPO), polyphenylene ethers (PPE), and olefins.

In certain embodiments of the invention the co-monomers used in compositions with the pendent curable polyimides are based on polyimides that contain a terminal curable moiety, such as the following generic example.

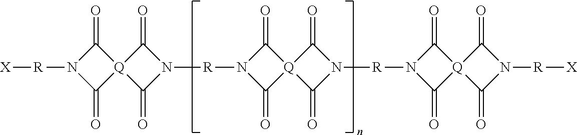

Wherein, R and Q are each independently a substituted or unsubstituted aliphatic, alkenyl, aromatic or siloxane; X is a curable moiety.

Various molecular weight compounds of the above example are commercially available from Designer Molecules, Inc., San Diego Calif. Examples of the compounds include the following trade names: BMI-689; BCI-737; BCI-1500; BMI-1500; BMI-1550; BMI-1700; BCI-3000; BMI-3000; BMI-2500; BMI-4100; BMI-6000; BMI-6100 and ILR-1363.

Free radical initiators also include photoinitiators. For compositions of the invention that contain a photoinitiator, the curing process can be initiated, for example, by UV radiation. In one embodiment, the photoinitiator is present at a concentration of 0.1 wt % to 10-wt %, based on the total weight of the composition (excluding any solvent).

Photoinitiators include benzoin derivatives, benzilketals, α,α-dialkoxyacetophenones, α-hydroxyalkylphenones, α-aminoalkylphenones, acylphosphine oxides, titanocene compounds, combinations of benzophenones and amines or Michler's ketone, and the like.

In some embodiments, both photoinitiation and thermal initiation may be desirable. For example, curing of a photoinitiator-containing composition can be started by UV irradiation, and in a later processing step, curing can be completed by the application of heat to accomplish a free-radical cure. Both UV and thermal initiators may therefore be added to the adhesive compositions of the invention.

Inhibitors for free-radical cure may also be added to the compositions described herein to extend the useful shelf life. Examples of free-radical inhibitors include hindered phenols such as 2,6-di-tert-butyl4-methylphenol; 2,6-di-tert-butyl-4-methoxyphenol; tert-butyl hydroquinone; tetrakis (methylene (3,5-di-tert-butyl-4-hydroxyhydrocinnamate)) benzene; 2,2′-methylenebis(6-tertbutyl-p-cresol); and 1,3,5-trimethyl-2,4,6-tris(3′,5′-di-tertbutyl-4-hydroxybenzyl) benzene. Other useful hydrogen donating antioxidants such as derivatives of p-phenylenediamine and diphenylamine. It is also well known in the art that hydrogen-donating antioxidants may be synergistically combined with quinones and metal deactivators to make a very efficient inhibitor package. Examples of suitable quinones include benzoquinone, 2-tert butyl-1,4-benzoquinone; 2-phenyl-1,4-benzoquinone; naphthoquinone, and 2,5-dichloro-1,4-benzoquinone. Examples of metal deactivators include N,N′-bis(3,5-di-tert-butyl-4-hydroxyhydrocinnamoyl)hydrazine; oxalyl bis(benzylidenehydrazide); and N-phenyl-N′-(4-toluenesulfonyl)-p-phenylenediamine amine.

Nitroxyl radical compounds such as TEMPO (2,2,6,6-tetramethyl-1-piperidnyloxy, free radical) are also effective as inhibitors at low concentrations. The total amount of antioxidant plus synergists typically falls in the range of 100 to 2000 ppm relative to the weight of total base resin. Other additives, such as adhesion promoters, in types and amounts known in the art, may also be added.

Fillers contemplated for use in the practice of the invention include but are not limited by materials such as: graphite; perfluorinated hydrocarbons (Teflon™); boron itride; carbon nanotubes; silica nano-particles; polyhedral oligomeric silsesquioxane (POSS™) nanoparticles and the like. The fillers contemplated for use will affect the dielectric properties of the compositions, they will affect the Tg and CTE, as well as the flammability rating of the composition.

Flame retardants contemplated for use in the practice of the invention include but are not limited to organophosphorous compounds.

### Redistribution Layers

Redistribution layers are a type of passivation material that provide a way to make the bond pads in one location on a chip available in other locations on a chip, or beyond (e.g., in the case of fan-out packages, described below). Using RDL, bond pads can be functionally moved around the face of the die for flip-chip applications, which can separate narrowly spaced, or high-density sites for solder balls, and thereby distribute the stress of mounting. In stacked die packages, RDL layers allow unique positions for address lines using identical generic chips. Furthermore, bond pads can be moved to more convenient locations based on the overall geometry of the chip and surrounding packages and connections.

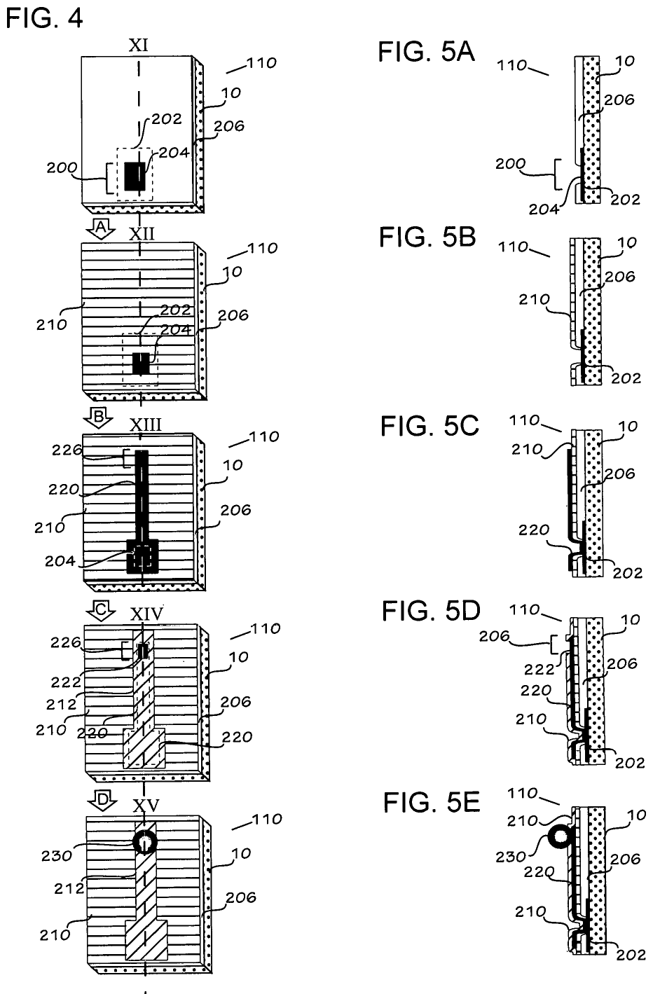

FIGS. 4 and 5 illustrate the process of RDL. A simplified chip 110, having a single bond pad 200 is shown. The chip 110 is fabricated from wafer material 10 with a conductive area of metallization 202, and a passivating layer partially covering the metallization except for a contact region 204. The dashed line indicates the extent of metallization 202 below the surface of the passivation layer 206. Redistribution of the pad involves establishing a conductive connection between the existing bond pad, and the new bond pad via with a line of surface metallization between the two points.

The redistribution line can be fabricated directly on the primary passivation 206 (not illustrated) or can be routed over a new layer of polymer passivation material 210 to ensure adequate protection of the metallization on all sides as illustrated in FIGS. 4 and 5B. In these illustration, the surface of the chip is coated with a first redistribution layer 110, excluding the contact of the existing pad (step A). In other aspects, this first polymer layer can be disposed over only the area that will receive metallization. In either case, photolithography can be used to remove excess polymer.

Metallization (e.g., copper foil, electroplating) is then applied to contact 204 (indicated by dashed line), the surrounding area, and along a continuous line to the new pad location using methods known in the art, thereby conductively connecting the original pad 200 with the new pad location 226 (FIG. 4, step B and FIG. 5B).

In step C, a second redistribution layer 212 is formed over the metallization 220, completely covering the existing original pad 200 and exposing only the new contact 222 of new pad 226. In this illustration, the second redistribution layer 212 is shown limited to the path of the metallization. However, the second redistribution layer 212 can cover the entire chip surface provided it doesn't interfere with any other functions of the chip.

Finally (step D), a solder bump 230 can be disposed over the relocated pad 226 for wire bonding or other connections.

### Fan-Out RDL

Redistribution layers have traditionally been used on the surface of single chips. However, the emerging technology of “fan-out” wafer level packaging (FOWLP) has significantly expanded the need and therefore the use of RDL. FOWLP (which is distinguished from “fan-in” WLP, described above), expands IC chip surface area by embedding a singulated chip in a molded package that is fabricated post-singulation. Multiple chips can be molded into the same package and the original I/O pads can then be redistributed to the fan-out regions of package. Redistribution layers make relatively inexpensive low CTE polymer (e.g., epoxy) molds suitable for carrying the delicate metallization lines from a silicon chip to a fan-out region, thereby redistributing the I/O pads across a substantially increased surface area.

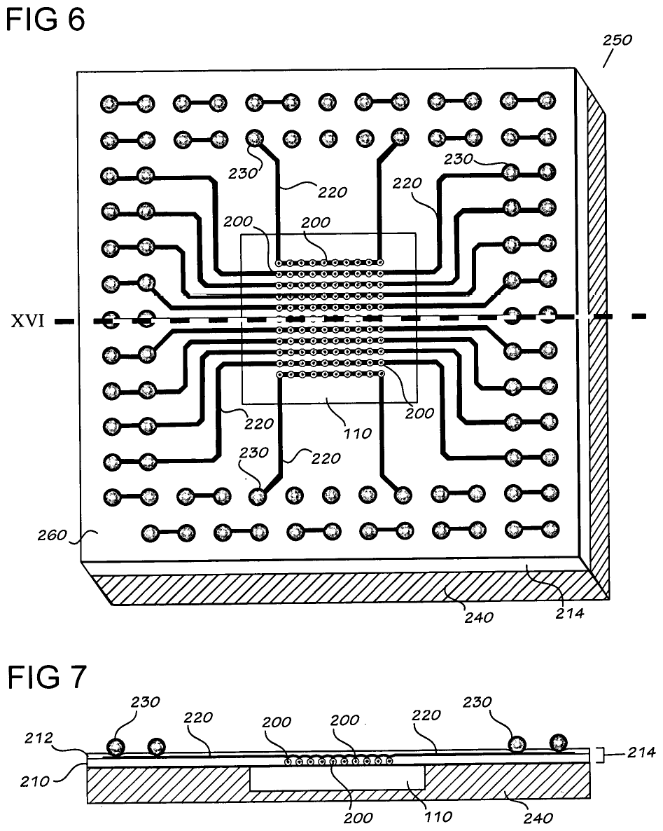

FIG. 6 is a top perspective view of a fan out package and FIG. 7 is a cross-sectional view of through the center of the package at plane XVI. For clarity, only a few of the repeated structure 200 (original pads), 220 (redistribution metallization lines) and 230 (solder balls) are numbered in the drawing. The original chip 110 (grey box in center) is located in the center of the package, surrounded by the molded polymer composition 214 (the “fan-out” area). High density original I/O pads 200 on chip 110 redistributed to the periphery of the “fan-out” 260 area using the process illustrated for a single redistributed pad in FIGS. 4 and 5A-E upon: a first layer of passivating redistribution polymer 210 is applied, followed by conductive metallization lines 220 from original to new pad, which are then covered with a second metallization layer 212, which layers collectively form an overall redistribution layer 214. Thick black lines represent the metallization lines 220 that follow a path from the original pads 200 to the redistributed pad upon which a solder ball 230 is disposed.

The present invention thus provides polymer formulations suitable for use in RDL. According to embodiments of the present invention, there is provided devices comprising a semiconductor wafer or other substrate and a redistribution layer disposed on the surface of the wafer, or substrate. The redistribution layer pre-imidized or partially imidized backbone with a photopolymerizable functional group, having a structure according to any of Formulae IA, IB, IC and ID.

The polyimides of this invention are fully imidized and are soluble in common organic solvents such as aromatic solvents or ketones required for the coating application. Furthermore, once UV cured, the polyimides of the invention are developable in common solvents such as cyclopentanone.

Advantageously, polyimides of the present invention are photoimagable, thereby allowing patterning of the redistribution layer. For example, a redistribution polymer formulation of the invention can be applied to the surface of an IC chip and/or fan-out package, and then photoimaged to remove areas designated for via holes or for UBM (Under Bump Metallization) sites, so as to allow subsequently sputtered and plated metallization to make contact with the bottom metallization layer to facilitate high density connections.

Another desirable feature of the polyimides of the invention is that they have much lower moisture uptake than traditional polyimide coatings. Therefore, the there is little risk that the RDL formulations will subject delicate metallization to corrosive conditions.

### Prepregs, Copper-Clad Laminates and Printed Circuit Boards

The present invention also provides compositions and methods for making prepregs (reinforcement fiber pre-impregnated with a resin), copper clad laminates and printed circuit boards. Also provided are prepregs, copper-clad laminates and printed circuit boards comprising polyimides of the invention.

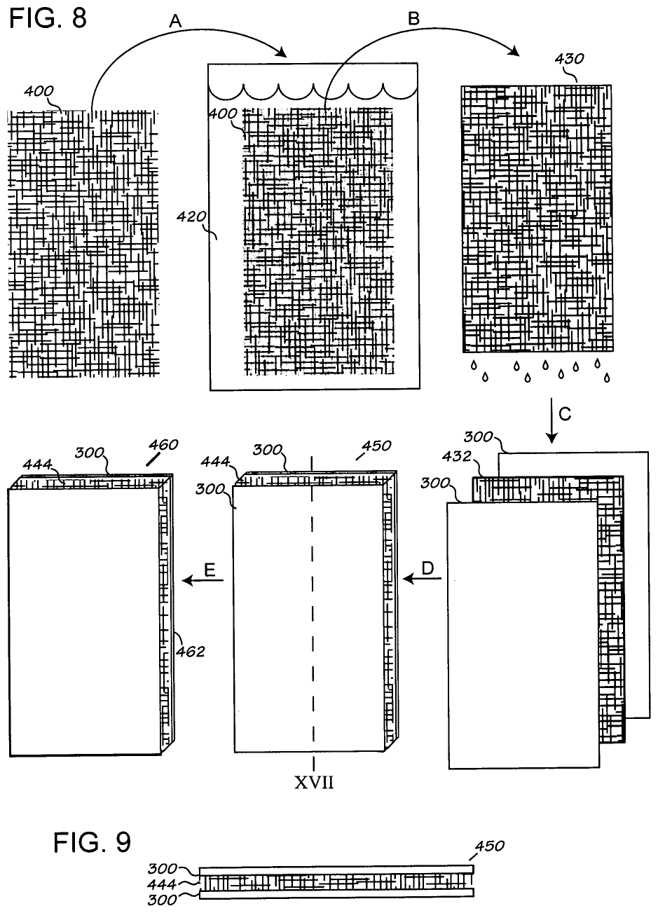

The process for preparing prepregs, copper clad laminates and printed circuit boards is illustrated in FIG. 8. Steps in the process are indicate by arrows. The process begins with a reinforcing fiber 400 such as, fiberglass or carbon fiber. The fiber can be in the form of a woven or unwoven fabric, or single strands of fiber that will be held together by the polymer. The fiber 400 is immersed in a liquid formulation 420 containing an uncured polyimide described herein (step A), thereby impregnating the fiber with the polyimide formulation to form a prepreg. The wet prepreg 430 is then dried to remove excess solvent (step B). Conveniently, the dried prepreg 432 can then be stored until needed.

The dried prepreg will typically be coated on one or both side with a layer of copper to form a copper-clad laminate (CCL). The copper can be applied by electroplating or by laminating thin copper foil to the prepreg. FIG. 8 illustrates preparation of a double-sided using copper foil 300. Thus. in step C, the dried prepreg 432 is assembled in a sandwich fashion with a sheet of copper foil 300 on either side. Optionally, layers of adhesive can be interleaved between the foil to increase adhesion (not shown). This is likely unnecessary because polyimides of the invention have strong adhesive properties. In some embodiments, adhesion promoters can be added to formulation 420 to increase bonding of the foil to the prepreg. In step D, the foil 300 is laminated to the prepreg 432 using heat and pressure. Advantageously, polyimides of the invention can be cured using heat. FIG. 9 shows a cross section of CCL 450 having a central core of fiber-reinforced, cured polyimide 444, laminated to copper foil 300 on each side.

Circuit patterns 462 can then be formed on either or both sides of the CCL 450 by photolithography to from a printed circuit board (PCB). 460. The resulting PCB exhibits the high structural strength and heat resistance necessary for contemporary electronics applications.

### Flexible Copper-Clad Laminates

The compounds and compositions of the invention are useful in any application that requires flexibility. In particular, flexible copper clad laminates (FCCLs) are increasingly used in electronics as they can provide the ultrathin thin profile demanded by increasing miniaturization. Moreover, circuitry is becoming prevalent in non-traditional situations, such as clothing, where the ability to conform to a three-dimensional shape other than a flat board is required.

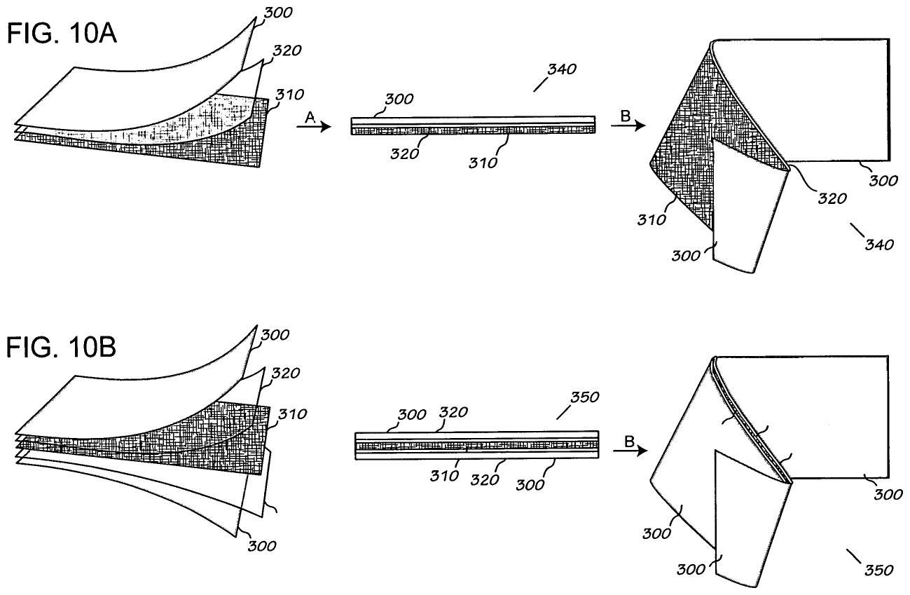

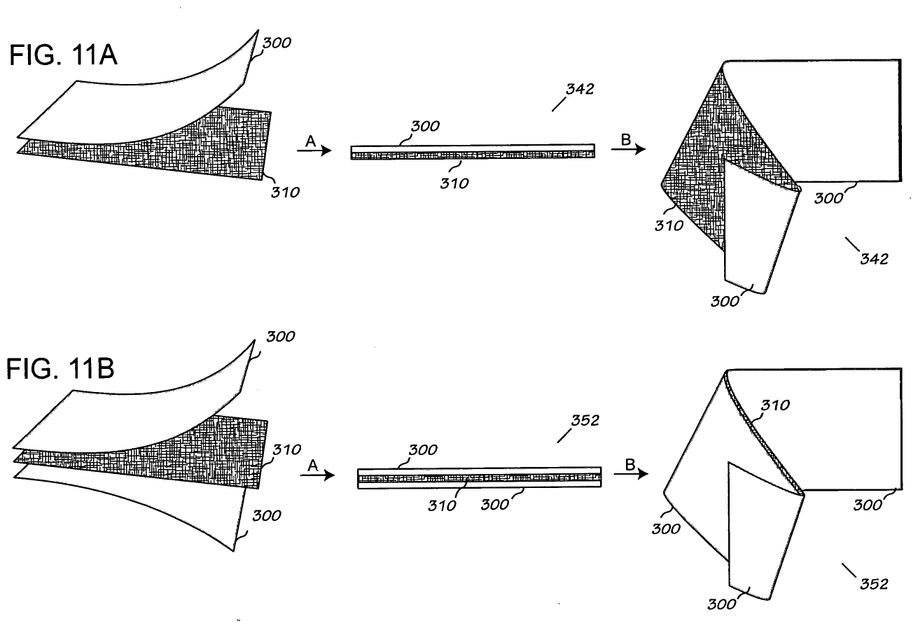

A process of forming FCCLs according to one embodiment of the invention is illustrated in FIGS. 10A and 10B for single- and double-sided FCCLs respectively. The process is similar to preparing a prepreg based CCL but is much thinner and lacks the rigidity of a prepreg. A thin and flexible film of polyimide polymer 310 prepared as described herein, is assembled with an adhesive layer 320 and copper foil 300 (FIG. 10A). The assembly is then laminated (step A) to form a single-sided copper clad laminate 340. The FCCL can then be rolled, bent or formed as needed (step B), while providing the basis for thin, flexible circuitry that can be used in consumer electronics, clothing and other goods.

Double-sided FCCL production according to one embodiment of the invention, is illustrated in FIG. 10B. This process is identical to that illustrated in FIG. 10A, except that the adhesive layer 320 and copper foil 300 are placed on both sides of polymer film 310 to form a 5-layer assembly, which is then laminated (step A) to form a double-sided FCCL 350.

In another embodiment of the invention, adhesiveless processes for producing FCCL are provided as shown in FIGS. 8A and 8B. Single-sided FCCL (FIG. 8A) is prepared by contacting copper foil 300 with one side of a polyimide film 310 prepared as described herein. The film is then heat-cured (step A), onto the foil to form an adhesiveless FCCL 342, which is thinner and more flexible than FCCL that includes an extra layer (i.e., the adhesive layer). The single-sided, adhesiveless FCCL 342 can be rolled, bent, or formed into a desired shape before (step B) or after patterning (not shown).

Double-sided, adhesiveless FCCL can be prepared (FIG. 10B) in the same manner as the single-sided product, except that both sides of film 310 are contacted with foil 300 prior to curing (step B). The double-sided adhesiveless FCCL 352 according to this embodiment of the invention can similarly be rolled, shaped, and formed (step B).

In yet another FCCL embodiment of the invention eliminates the step of forming a polymer film prior to assembly. Instead, a liquid formulation of the polymer is applied directly to the copper foil. Application can be by any method known in the art, such as by pouring, dropping, brushing, rolling or spraying, followed by drying and heat-curing. To prepare a double sided FCCL according to this embodiment of the invention, polymer-coated foil is prepared, dried and then a second foil is contacted on the polymer side of the foil prior to curing.

Application of circuit traces to FCCL can be performed using standard photolithography processes develop for patterning printed circuit boards.

In another embodiment of the invention the shape memory polyimides are claimed for use as: medical devices; in automotive applications; in marine applications; in aerospace applications; in sporting goods applications; for use as MEMs devices; for use as mechanical devices; for use as actuators; and so on.

### EXAMPLES

### Materials and Method

### Dynamic Mechanical Analysis (DMA)

Polymer formulations were prepared in a suitable solvent (e.g. anisole) with <5% dicumyl peroxide (Sigma-Aldrich, St. Louis Mo.), and 500 ppm inhibitor mix (Designer Molecules, Inc.; Cat. No. A619730; weight % p-Benzoquinone and 70 weight % 2,6-di-tert-butyl-4-methylphenol) and dispensed into a to 5 inch×5 inch stainless steel mold. The mixture was then vacuum degassing and the solvent (e.g. anisole) was allowed to slowly evaporate at 100° C. for ˜16 hours in an oven. The oven temperature was then ramped to 180° C. and hold for 1 hour for curing. Then the oven temperature was ramp to 200° C. and h1ld for 1 hour before cooling to room temperature. The resulting film (400-800 um) was then released from mold and cut into strips (≃2 inch×≃7.5 mm) for measurement.

The strips were analyzed on a Rheometrics Solids Analyzer (RSA ii) (Rheometric Scientific Inc.; Piscataway, N.J.) with a temperature ramp from 25 to 250° C. at a rate of 5° C./min under forced air using the Dynamic Temperature Ramp type test with a frequency of 6.28 rad/s. The autotension sensitivity was 1.0 g with max autotension displacement of 3.0 mm and max autotension rate of 0.01 mm/s. During the test, maximum allowed Force was 900.0×g and min allowed force is 3.0×g. Storage modulus and loss modulus temperature were plotted against and temperature. The maximum loss modulus value found was defined as the glass transition (T_{g}).

### Coefficient of Thermal Expansion (CTE)

Formulations were prepared as above for DMA. Samples sufficient to give a 0.2 mm to 10 mm thick film were dried at 100° C. for 2 hours to overnight and cured for 1-2 hours at ≃180° C. to ≃250° C.

Hitachi TMA7100 was used for CTE measurement. The film was placed on the top of a sample holder (disk type quartz) and move down quartz testing probe was lowered onto top of the sample to measure sample thickness. The temperature ramped from 25° C. to 250° C. at a 5° C./min, load 10 mN to measure expansion/compression. CTE was calculated as the slope of length change verses temperature change in ppm/° C. α1 CTE and α2 CTE are calculated based on T_{g}.

### Thermalgravimetric Analysis (TGA)

Thermalgravimetric analysis measurements were performed on an TGA-50 Analyzer (Shimadzu Corporation; Kyoto, Japan) under an air flow of 40 mL/min with heating rate of 5° C./min to or 10° C./min. The sample mass lost versus temperature change was recorded and the decomposition temperature was defined at the temperature at which the sample lost 5% of its original mass.

### Tensile Strength and Percent Elongation

Samples were dried to remove solvent at 100° C. for 2 hours to overnight and cured for 1-2 hours at 180° C.˜250° C. in a metal mold to obtain thin films. Test strip film dimension for test was 6 inch×0.5 inch×0.25 inch; measurement length 4.5 inches.

The tensile strength and percent elongation were measure using an Instron 4301 Compression Tension Tensile Tester. Tensile strength was calculated as the ratio of load verses sample cross-section area (width×thickness). Percent elongation was calculated as the ratio of original length of sample (4.5 inch) verses length at break point.

### Permittivity/Dielectric Constant (Dk) and Loss Tangent/Dielectric Dissipation Factor (Df)

Formulations were prepared as above for DMA, except that a 2 inch×2 inch film was cut for analysis.

Dk and Df measurements were carried out by National Technical Systems (Anaheim, Calif., USA) with IPC TM-650 2.5.5.9 as the test procedure. The samples were placed in a conditioning cabinet at 23 2° C. and 50±5% relative humidity for 24 hours prior to testing, which was performed at measured conditions of 22.2° C. and 49.7% relative humidity. One sweep of the impedance material analyzer was performed with an oscillatory voltage of 500 mV at 1.5 GHz and the sweep was performed between 99.5% and 100.5% of the desired value (1.4925 GHz and 1.5075 GHz).

### Gel Permeation Chromatography

Gel permeation chromatography analysis of polymer molecular weight was carried out on an Ultimate 3000 HPLC instrument (Thermo Scientific; Carlsbad, Calif.) using tetrahydrofuran (THF) as eluent solvent and polystyrene standards as reference for molecular weight (MW) calculation based on the retention time of the polymer samples. The standards used had MWs of: 96,000; 77,100; 58,900; 35,400; 25,700; 12,500; 9,880; 6,140; 1,920; 953; 725; 570; 360; and 162. UV-vis detecting mode was applied at wavelength 220 nm and 10 mg/mL polymer in THF solution were used for testing. The standard curve is given in FIG. 21.

### Spin Coating and Photolithography

A silicon wafer was secured on the middle of a spin coater and spun at low rpm (550 rpm) while dropping material on rotating wafer surface over approximately 5-10 seconds. The speed was increased to 1,150 rpm and spin for 15 seconds. The coated wafer was dried in an oven at 100° C. for 5-15 min

A photomask was placed on the coated wafer and exposed to UV (I-line, 365 nm) for 50 see to achieve 500 mJ to cure exposed area. Film thickness was measured post-UV-cure, using a surface profiler.

The film was developed in cyclopentanone or propylene glycol methyl ether acetate (PGMEA) and tetramethlyammonium hydroxide (TMAH) to remove uncured areas of film (negative type photolithography).

Films were air dried post development and film thickness measured to calculate film thickness loss due to development. Film thickness was again measured following curing at 100° C. for 1 hour.

### Chemicals

Unless another supplier is indicated, chemicals were purchased from TCI America, Portland Oreg.

### Polyimides with Vinyl Pendant Groups

### Example 1: Synthesis of Vinyl Pendent Polyimide (1-A)

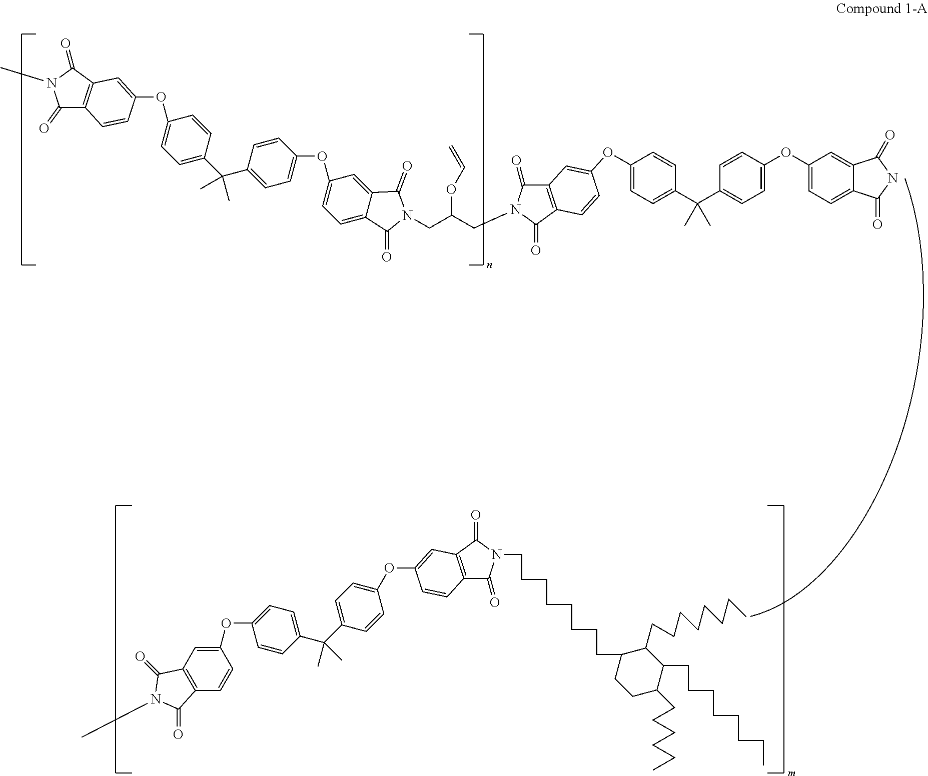

A 3 L reactor was charged with the following ingredients: 9.0 g (100 mmol) 1,3-diamino-2-propanol, 219.6 g (400 mmol) Priamine™ 1075 (C₃₆-dimer diamine; Croda, Edison, N.J.) and 1500 g of anisole (methoxybenzene). The solution was stirred while 261.0 g (500 mmol) 4,4′-Bisphenol A dianhydride (BPADA) was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by the recovery of (18.0 mL) the theoretical yield of water, producing an alcohol pendent polyimide.

The solution was cooled down to about 75° C. and a large excess (500.0 g, 5.0 mol) of butyl vinyl ether was added to the reactor along with 1.0 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product. ¹H NMR data were consistent with an aliphatic/aromatic polyimide. Infrared spectroscopy confirmed the presence of the imide carbonyl group and vinyl group. The FTIR spectrum of the sample showed major bands at 3065, 1712, 1615, 1232 and 734 wavenumbers.

### Example 2: Synthesis of Vinyl Pendent Polyimide 1-B

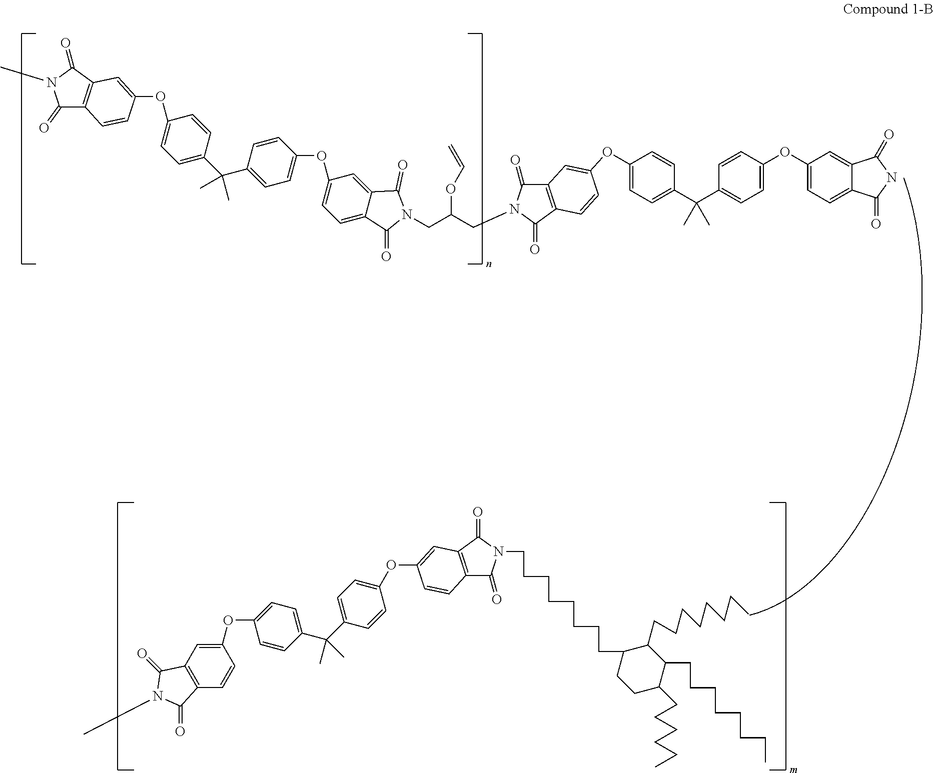

A 3 L reactor was charged with the following ingredients: 6.75 g (75 mmol) 1,3-diamino-2-propanol, 233.4 g (425 mmol) Priamine™ 1075, and 1500 g of anisole. The solution was stirred while 261.0 g (500-mmol) BPADA was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by the recovery of (18.0 mL) the theoretical yield of water, producing an alcohol pendent polyimide.

The solution was cooled down to about 75° C. and a large excess (3.75 mol, 375.0 g) of butyl vinyl ether was added to the reactor along with 0.75 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product.

Molecular Weight was analyzed as described above by gel permeation chromatography. See FIG. 14. The estimated molecular weight of Compound 1-B was calculated to be 55,000 Daltons.

¹H NMR data were consistent with an aliphatic/aromatic polyimide. Infrared spectroscopy confirmed the presence of the vinyl group and imide carbonyl group. The FTIR spectrum of the sample showed major bands at 3065, 1713, 1615, 1232, 839, and 747 wavenumbers.

### Example 3: Synthesis of Vinyl Pendent Polyimide 1-C

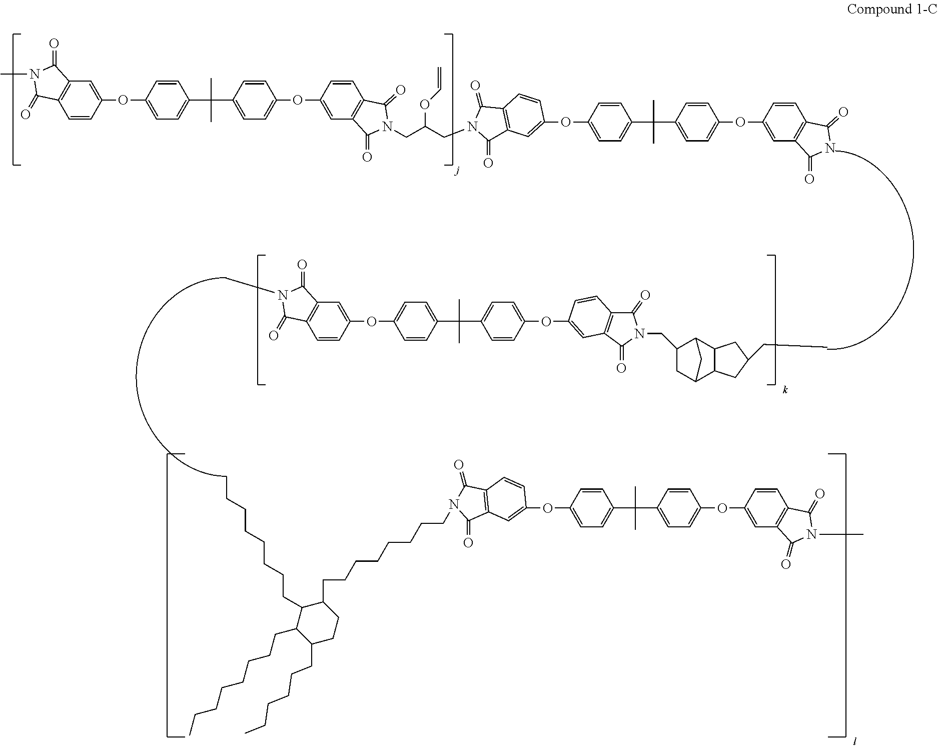

A 3 L reactor was charged with the following ingredients: 4.5 g 1,3-diamino-2-propanol (50 mmol), 9.7 g (50 mmol) tricyclodecanediamine (TCD-DA), 219.4 g (400 mmol) Priamine™ 1075, and 1500 g of anisole. The solution was stirred while 261.0 g (500-mmol) BPADA was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by recovery of (18.0 mL) the theoretical yield of water, producing an alcohol pendent polyimide.

The solution was cooled down to about 75° C. and a large excess (2.5 mol; 250.0 g) of butyl vinyl ether was added to the reactor along with 0.5 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product.

¹H NMR data were consistent with an aliphatic/aromatic polyimide. Infrared spectroscopy confirmed the presence of the vinyl group and the imide carbonyl. The FTIR spectrum of the sample showed major bands at 3065, 1713, 1615, 1599, 1238, 831, and 733 wavenumbers.

### Example 4: Synthesis of Vinyl Pendent Polyimide 1-D

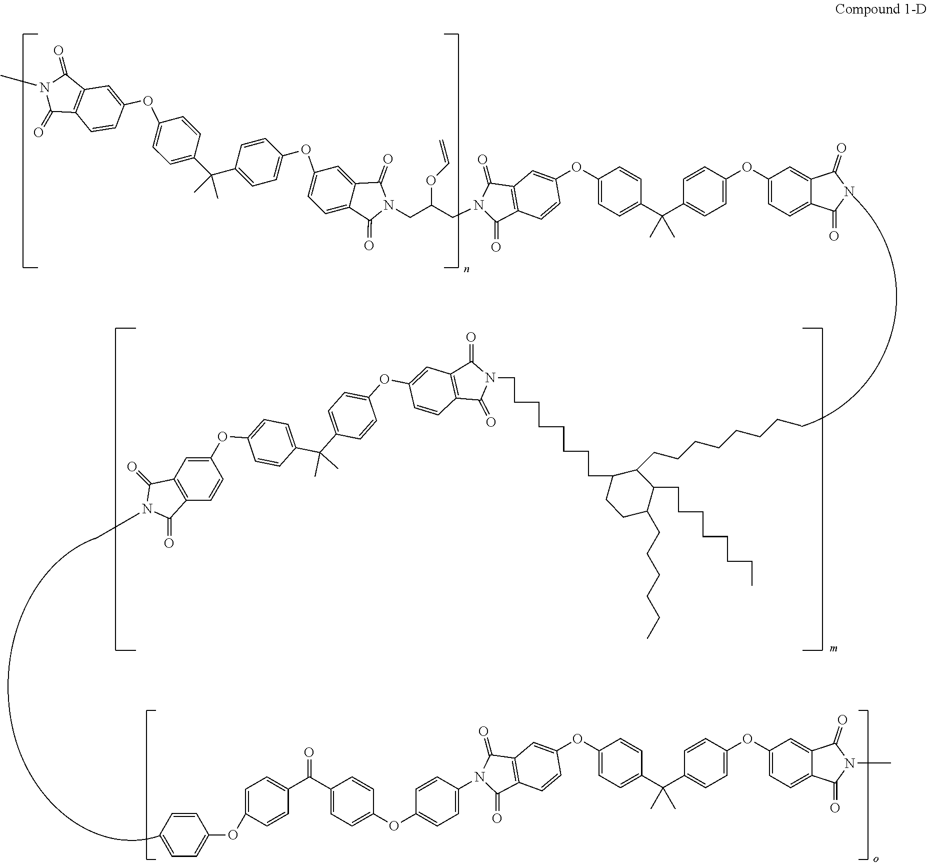

A 3 L reactor was charged with the following ingredients: 5.4 g (60 mmol) 1,3-diamino-2-propanol, 39.6 g (100 mmol) BAPB (4,4′-Bis (4-aminophenoxy) benzophenone), 86.7 g (340 mmol) Priamine™ 1075, and 1500 g of anisole. The solution was stirred while 261.0 g (500-mmol) BPADA was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by recovery of the (18.0 mL) theoretical yield of water, producing an alcohol pendent polyimide.

The solution was cooled down to about 75° C. and a large excess (3.0 mol, 300.0 g) of butyl vinyl ether was added to the reactor along with 0.6 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product.

Molecular Weight was analyzed as described above by gel permeation chromatography. See FIG. 15. The estimated molecular weight of Compound 1-D was calculated to be 75,000 Daltons.

¹H NMR data were consistent with aliphatic/aromatic polyimide. Infrared spectroscopy confirmed the presence of the vinyl group and imide carbonyl group. The FTIR spectrum of the sample showed major bands at 3055, 1711, 1612, 1599, 1233, 840, and 739 wavenumbers.

### Example 5: Synthesis of Vinyl Pendent Polyimide 1-E

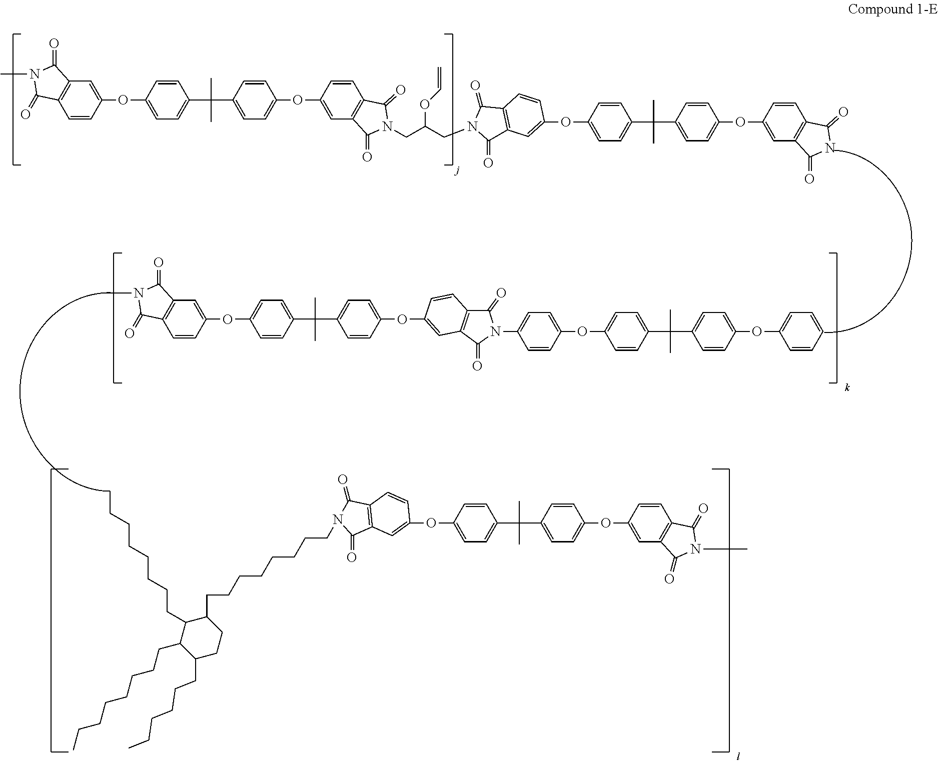

A 3 L reactor was charged with the following ingredients: 9.0 g (100 mmol) 1,3-diamino-2-propanol, 10.3 g (25 mmol) BAPPP (2,2-Bis[4-(4-aminophenoxy)phenyl]propane), 205.9 g (375 mmol) Priamine™ 1075, and 1500 g of anisole. The solution was stirred while 261.0 g (500 mmol) BPADA was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by recovery of the (18.0 mL) theoretical yield of water, producing an alcohol pendent polyimide.

The solution was cooled down to about 75° C. and a large excess (5.0 mol, 500.0 g) of butyl vinyl ether was added to the reactor along with 1.0 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product.

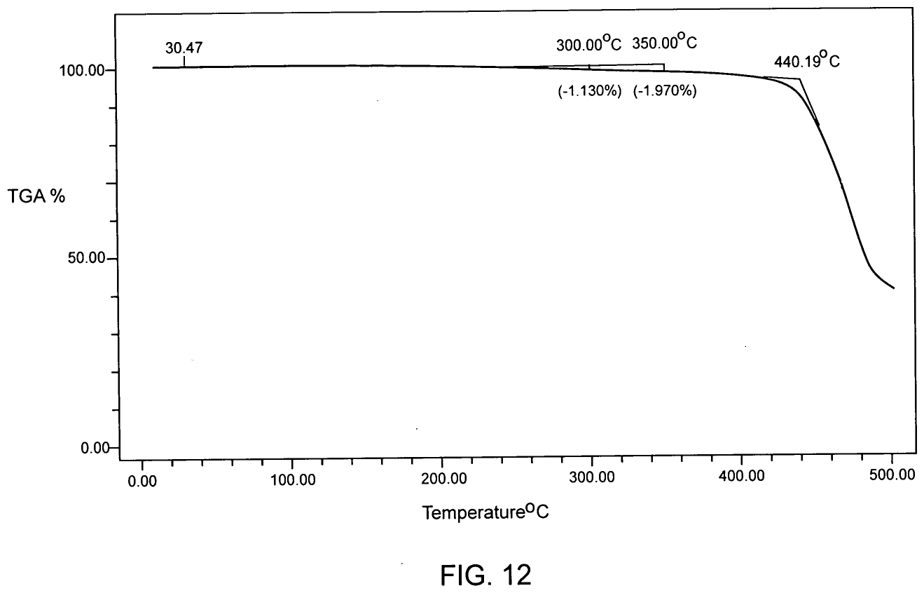

Thermal Stability. The thermal stability of this compound was demonstrated by TGA analysis (performed as described above). The compound had less than 2% weight loss at 350° C. and an onset of thermal degradation at 440.19° C. See FIG. 12.

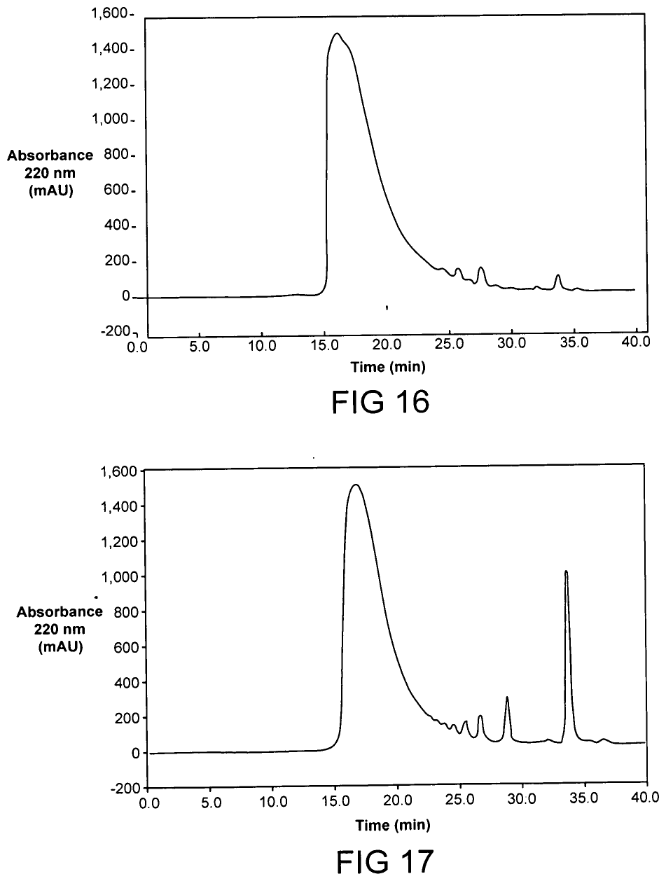

Molecular Weight was analyzed as described above by gel permeation chromatography. See FIG. 16. The estimated molecular weight of Compound 1-E was 75,000 Daltons.

¹H NMR data were consistent with an aliphatic/aromatic polyimide. Infrared spectroscopy confirmed the presence of the vinyl group and the imide carbonyl group. The FTIR spectrum of the sample showed major bands at 3056, 1712, 1613, 1601, 1237, 839, and 734 wavenumbers.

### Example 6: Synthesis of Vinyl Pendent Polyimide 1-F

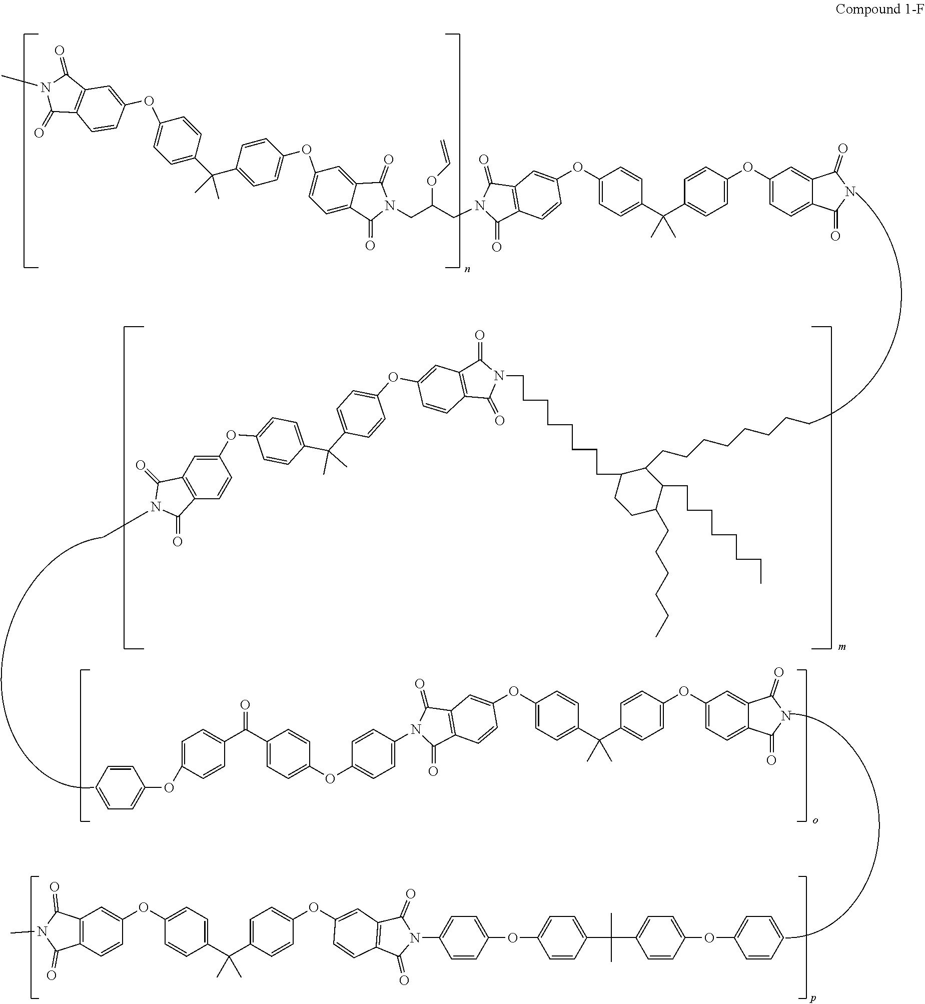

A 3 L reactor was charged with the following ingredients: 3.4 g (37.5 mmol) 1,3-diamino-2-propanol, BAPB (112.5 mmol, 44.6 g), 61.6 g (150.0 mmol) BAPPP, 109.6 g (200 mmol) Priamine™ 1075, and 1500 g of anisole. The solution was stirred while 261.0 g (500-mmol) bisphenol-A-dianhydride (BPADA) was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by recovery of the (18.0 mL) theoretical yield water, producing an alcohol pendent polyimide.

The solution was cooled down to about 75° C. and a large excess (1.88 mol, 188.0 g) of butyl vinyl ether was added to the reactor along with 0.4 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product.

Infrared spectroscopy confirmed the presence of the vinyl group and the imide carbonyl group. The FTIR spectrum of the sample showed major bands at 3055, 1712, 1615, 1601, 1238, 839, and 736 wavenumbers.

### Example 7: Synthesis of Vinyl Pendent Polyimide 1-G

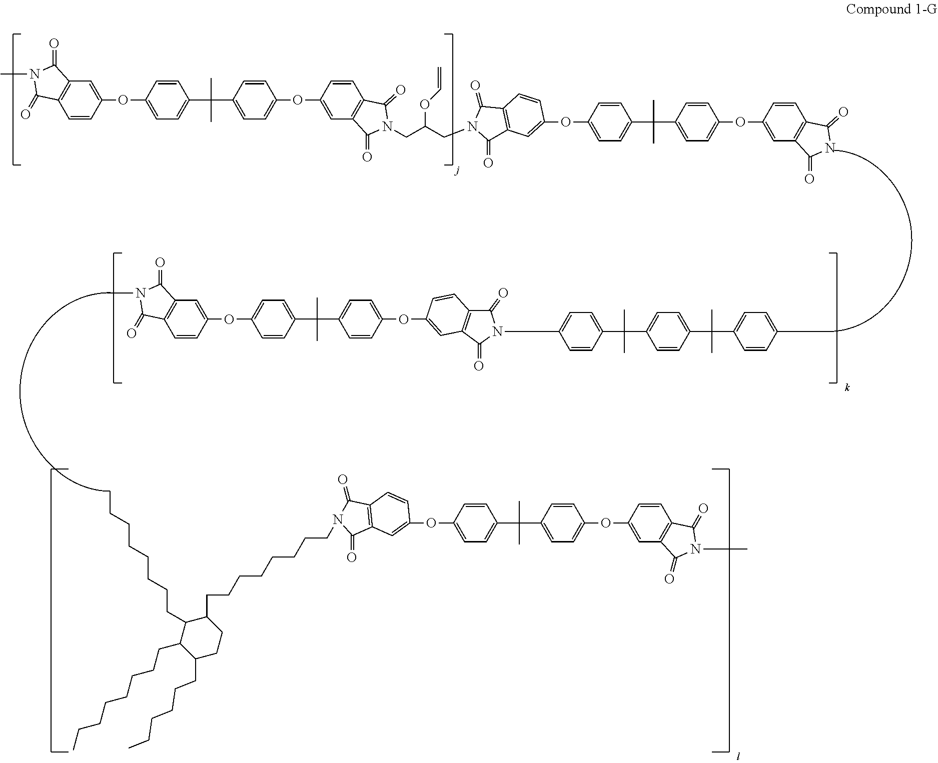

A 3 L reactor was charged with the following ingredients. 9.0 g (100 mmol) 1,3-diamino-2-propanol, 77.5 g (225.0 mmol) Bisaniline P, 96.1 g (175.0 mmol) Priamine™ 1075, and 1500 g of anisole. The solution was stirred while 261.0 g (500-mmol) BPADA was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by recovery of the (18.0 mL) theoretical yield of water, producing an alcohol pendent polyimide.

The solution was cooled down to about 75° C. and a large excess (5.0 mol, 500.0 g) of butyl vinyl ether was added to the reactor along with 1.0 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product.

¹H NMR data were consistent with an aliphatic/aromatic polyimide. Infrared spectroscopy confirmed the presence of the vinyl group and the imide carbonyl group. The FTIR spectrum of the sample showed major bands at 3055, 1713, 1613, 1600, 1232, and 734 wavenumbers.

### Example 8: Synthesis of Vinyl Pendent Polyimide 1-H

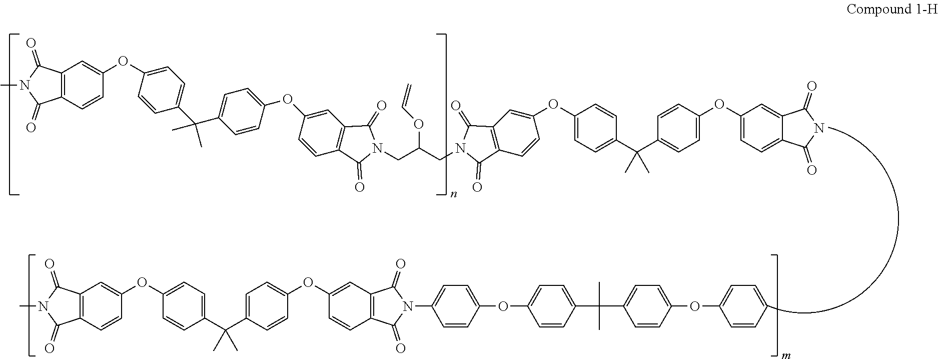

A 3 L reactor was charged with the following ingredients: 4.5 gl (50.0 mmol) 3-diamino-2-propanol, 184.7 g (450.0 mmol), BAPPP and 1500 g of anisole. The solution was stirred while 261.0 g (500-mmol) bisphenol-A-dianhydride (BPADA) was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by recovery of the (18.0 mL) theoretical yield of water, producing an alcohol pendent polyimide.

The solution was cooled down to about 75° C. and a large excess (2.5 mol, 250.0 g) of butyl vinyl ether was added to the reactor along with 0.5 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the p vinyl pendant polyimide product.

Molecular Weight was analyzed as described above by gel permeation chromatography. See FIG. 17. The estimated molecular weight of Compound 1-H was 65,000 Daltons.

¹H NMR data were consistent with an aromatic polyimide. Infrared spectroscopy confirmed the presence of the vinyl group and the imide carbonyl. The FTIR spectrum of the sample showed major bands at 3055, 1712, 1614, 1598, 1231, 830 and 741 wavenumbers.

### Example 9: Synthesis of Vinyl Pendent Polyimide 1-I

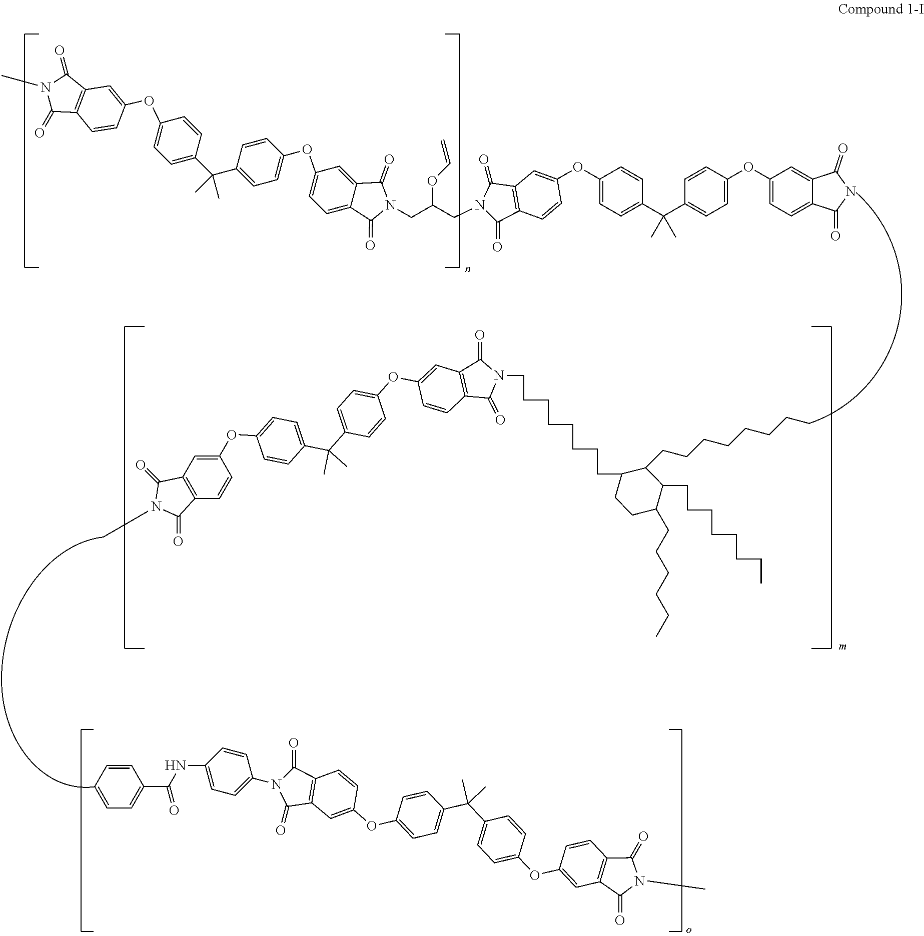

A 3 L reactor was charged with the following ingredients: 4.5 g (50.0 mmol) 1,3-diamino-2-propanol, 11.4 g (50.0 mmol) 4,4′-diaminobenzanilide), 109.6 g (200 mmol) Priamine™ 1075 and 1500 g of anisole. The solution was stirred while 82.1 g (200-mmol), BAPPP and 261.0 g (500.0-mmol) of BPADA was added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by recovery of the (18.0) theoretical yield of water, producing an alcohol pendent polyimide.

The solution was cooled down to about 75° C. and a large excess (2.5 mol, 250.0 g) of butyl vinyl ether was added to the reactor along with 0.5 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the p vinyl pendant polyimide product.

Infrared spectroscopy confirmed the presence of the amide carbonyl, the vinyl group and the imide carbonyl. The FTIR spectrum of the sample showed major bands at 3299, 3055, 1714, 1652. 1613, 1599, 1239, 734 wavenumbers.

### Example 10: Synthesis of Vinyl Pendent Polyimide 1-J

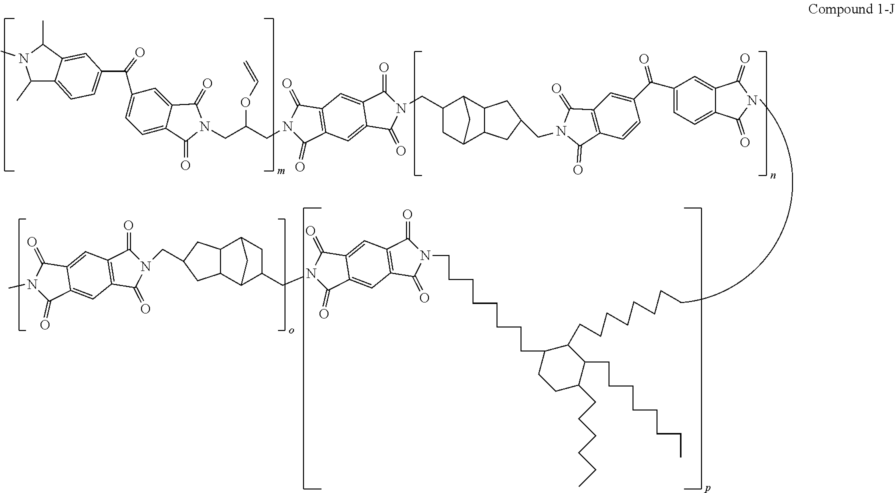

A 3 L reactor was charged with the following ingredients: 4.5 g (50.0 mmol) 1,3-diamino-2-propanol, 55.9 g (285.0 mmol) TCD-DA, 90.6 g (165.0 mmol) Priamine™ 1075 and 1500 g of 50:50 (wt:wt) anisole:dimethyl acetamide. The solution was stirred while 72.0 g (330.0 mmol) pyromellitic dianhydride and 54.8 g (170.0 mmol) benzophenone tetracarboxylic dianhydride were added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by recovery of about 30 mL of water and dimethylacetamide, producing an alcohol pendent polyimide.

The solution was cooled down to about 75° C. and a large excess (2.5 mol, 250.0 g) of butyl vinyl ether was added to the reactor along with 0.50 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product.

Infrared spectroscopy confirmed the presence of the vinyl group and the imide carbonyl group. The FTIR spectrum of the sample showed major bands at 3062, 1718, 1710, 1615, 1601, 1235, and 743 wavenumbers.

### Example 11: Synthesis of Vinyl Pendent Polyimide 1-K

A 3 L reactor was charged with the following ingredients: 6.75 g (75 mmol) 1,3-diamino-2-propanol, 79.6 g (145.0 mmol) Priamine™ 1075, 25.9 g (75.0 mmol) Bisaniline-M, 38.1 g (190.0 mmol) 3,4-oxydianiline, 6.16 g (15.0 mmol) of 2,2-Bis [4-(4-aminophenoxy)phenyl] propane and 1500 g of 50:50 (wt:wt) anisole:dimethyl acetamide. The solution was stirred while 16.1 g (50.0 mmol) benzophenone tetracarboxylic dianhydride, 77.6 g (250.0 mmol) oxydiphthalic anhydride; and 104.0 g (200.0 mmol) BPADA were added to the flask. The mixture was heated to reflux temperature of about 155° C. During the heating, the dianhydride slowly started to dissolve and produced a turbid solution. As the polyimide was generated, the water produced was condensed and collected in a Dean-Stark trap. After 1.5 hours, the reaction was complete as indicated by the recovery of about 30 mL of water and dimethylacetamide, producing an alcohol pendent polyimide.

The solution was cooled down to about 75° C. and a large excess (3.75 mol, 375.0 g) of butyl vinyl ether was added to the reactor along with 0.75 g of palladium acetate phenanthroline complex as a catalyst for the transetherification reaction. The solution was stirred for about 5 hours at 75° C. and then stirred overnight at room temperature. The product was vacuum distilled to remove the excess butyl vinyl ether and some of the excess anisole to produce about a 25% solids solution of the vinyl pendant polyimide product.

Infrared spectroscopy confirmed the presence of the vinyl group and the imide carbonyl group. The FTIR spectrum of the sample showed major bands at 3063, 1718, 1711, 1613, 1600, 1241, and 740 wavenumbers.

### Polyimides with Thiol Pendant Groups

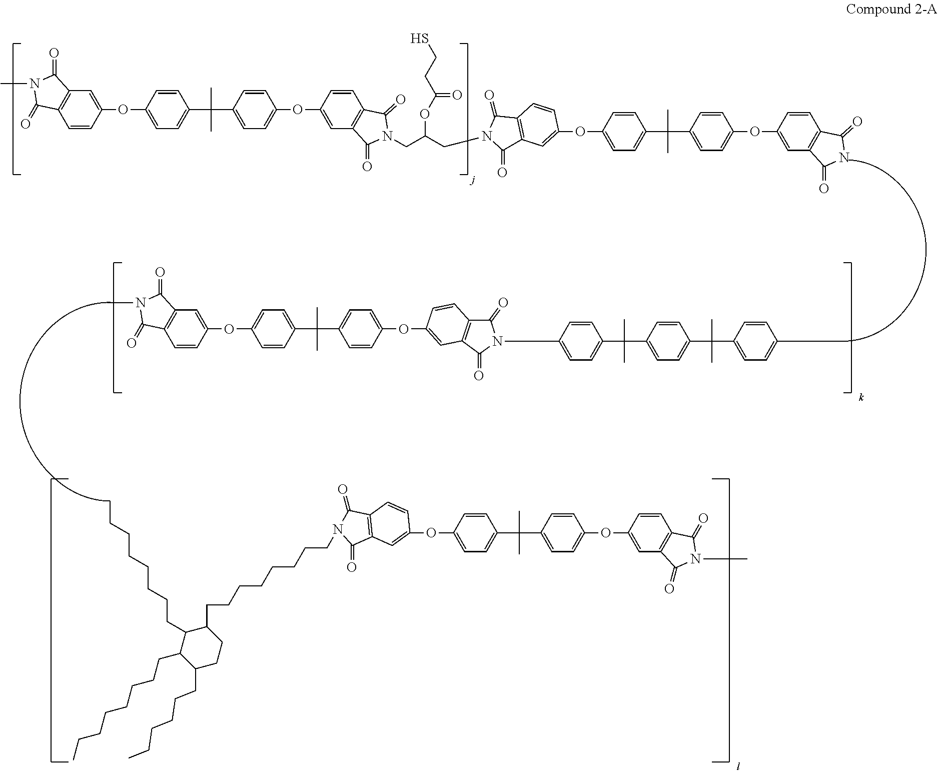

### Example 12: Synthesis of Thiol Pendent Polyimide 2-A

A 1 L reactor was charged with 0.90 g (10.0 mmol) of 1,3-diamino-2-propanol. To the reactor was also added 21.5 g (62.5 mmol) of Bisaniline P, 34.3 g (62.5 mmol) of Priamine™ 1075, and 500 g of anisole. To the stirred solution was added 70.2 g (135.0 mmol) of BPADA. The mixture was heated to reflux for 1.5 hours to produce the alcohol pendent polyimide. The solution was cooled and 1.06 g (10.0 mmol) of 3-mercaptopropionic acid and 2.0 g of Amberlyst® 36 acidic ion exchange resin was added. The mixture was refluxed for 1.0 hour to produce an ester. The Amberlyst® resin was filtered out to leave a clear yellow solution that was about 20% solids in anisole.

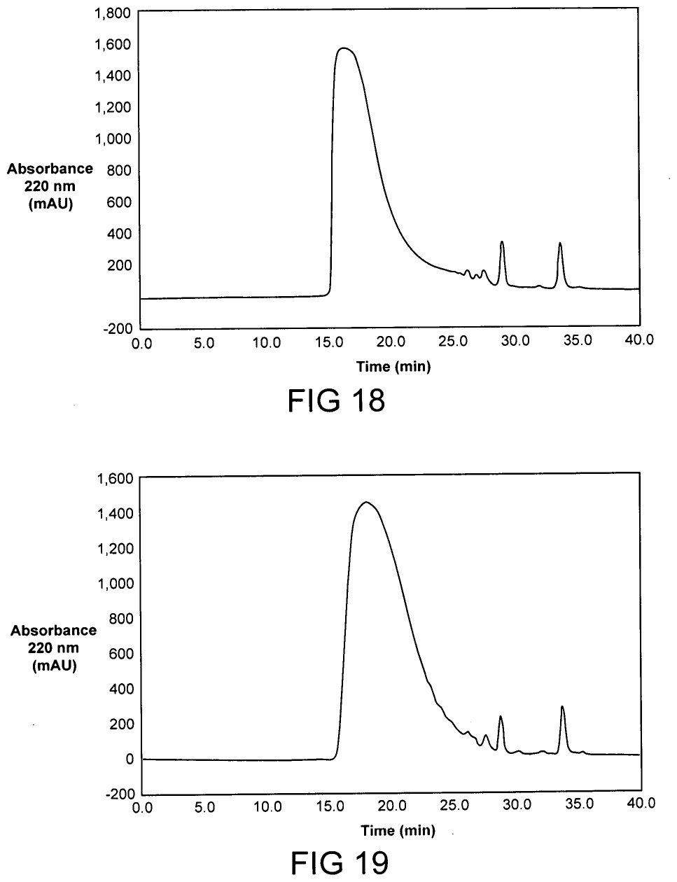

Molecular Weight was analyzed as described above by gel permeation chromatography. See FIG. 18. The estimated molecular weight of Compound 2-A was ‘calculated to be 65,000 Daltons.

¹H NMR data were consistent with an aliphatic/aromatic polyimide. Infrared spectroscopy confirmed the presence of the imide carbonyl. The FTIR spectrum of the sample showed major bands at 1710, 1600, 1231, 834 and 733 wavenumbers.

### Polyimides with Methacrylate Pendant Groups

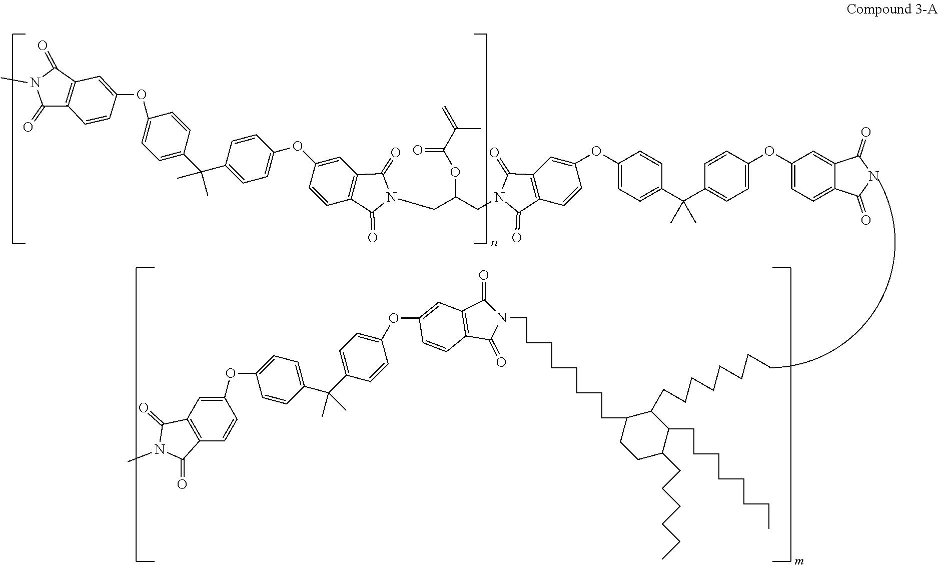

### Example 13: Synthesis of Methacrylate Pendent Polyimide 3-A

To a 1 L reactor were added 0.9 g (10.0 mmol) of 1,3-diamino-2-propanol, 54.9 g (100.0 mmol) of Priamine™ 1075, and 500 g of anisole. To the reactor was added 57.2 g (110.0 mmol) of BPADA and the mixture was heated to reflux for 1.5 hours to produce the alcohol pendent polyimide, with recovery of the 4 mL of the theoretical amount of water being removed. The solution was cooled to 60° C. and 1.55 g (10.0 mmol) of methacrylic anhydride was added to the reactor along with 0.1 g of dimethyl aminopyridine. The solution was stirred for 2 hours to assure the complete reaction.

Molecular Weight was analyzed as described above by gel permeation chromatography. See FIG. 19. The estimated molecular weight of Compound 3-A was calculated to be ˜50,000 Daltons.

¹H NMR data were consistent with an aliphatic/aromatic polyimide. Infrared spectroscopy confirmed the presence of the methacrylate group and the imide carbonyl. The FTIR spectrum of the sample showed major bands at 3056, 1713, 1599, 1238, 831 and 733 wavenumbers.

### Polyimides with Maleimide Pendant Groups

### Example 14: Synthesis of Maleimide Pendent Polyimide 4-A

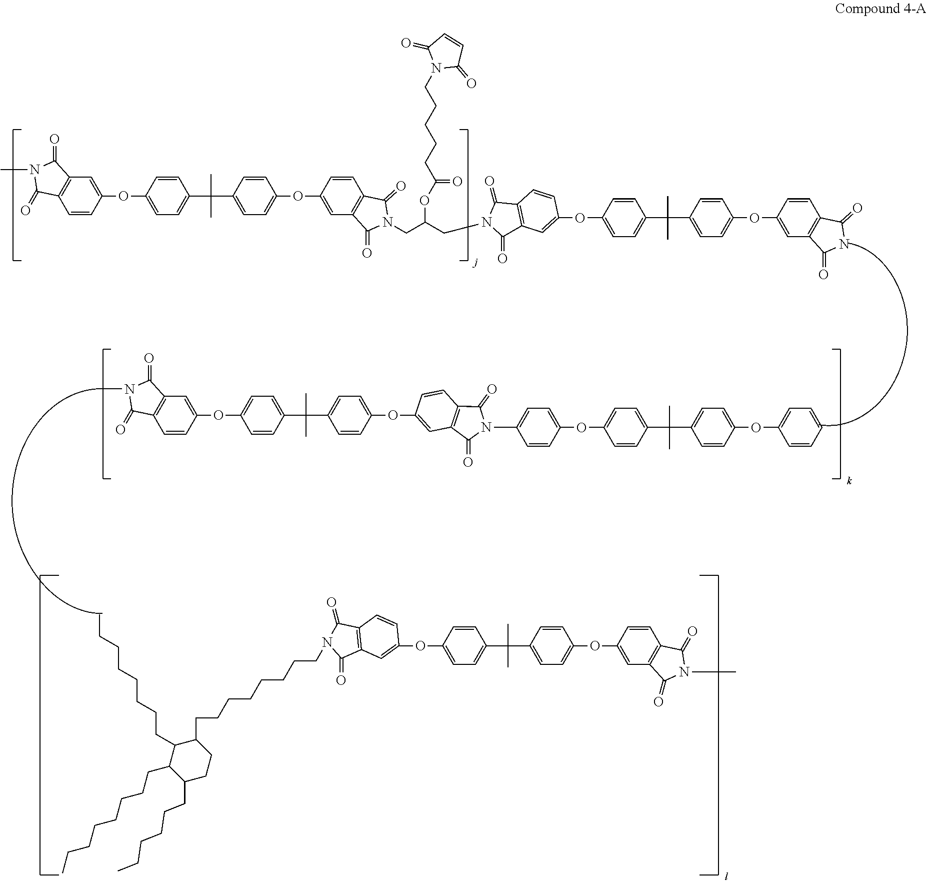

To a 1 L reactor was added 0.9 g (10.0 mmol) of 1,3-diamino-2-propanol; 4.11 g (10.0 mmol) of BAPPP, 43.9 g (80.0 mmol) of Priamine™ 1075, and 500 g of anisole. To the stirred solution was added 52.0 g (100.0 mmol) of BPADA. The mixture was heated to reflux for 1.5 hours to assure a complete reaction and form the alcohol pendent polyimide, with recovery of the 3.6 mL of the theoretical amount of water being produced. To the solution was added 2.10 g (10.0 mmol) of maleimidocaproic acid (Sigma, St. Louis, Mo.) and 2.0 g of Amberlyst® 36 acidic ion exchange resin. The mixture was heated to reflux for 1 hour to form an ester, and recovery of the 1.8 mL of theoretical amount of water. The Amberlyst® resin was filtered out of the solution.

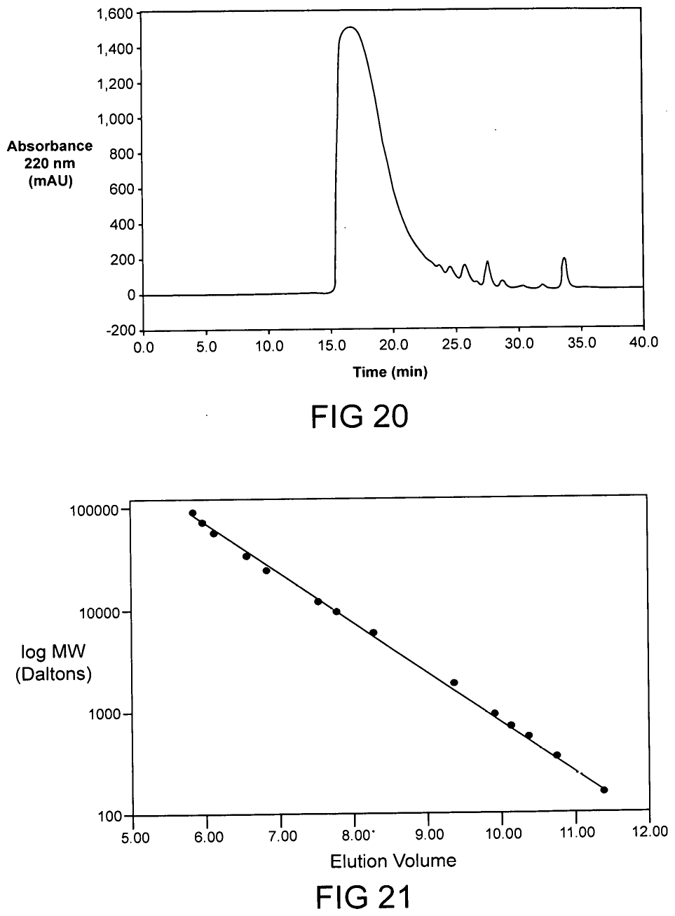

Molecular Weight was analyzed as described above by gel permeation chromatography. See FIG. 20. The estimated molecular weight of Compound 4-A was calculated to be ˜65,000 Daltons.

¹H NMR data were consistent with an aliphatic/aromatic polyimide. Infrared spectroscopy confirmed the presence of the maleimide group and the imide carbonyl group. The FTIR spectrum of the sample showed major bands at 1714, 1601, 1235, 839, and 744 wavenumbers.

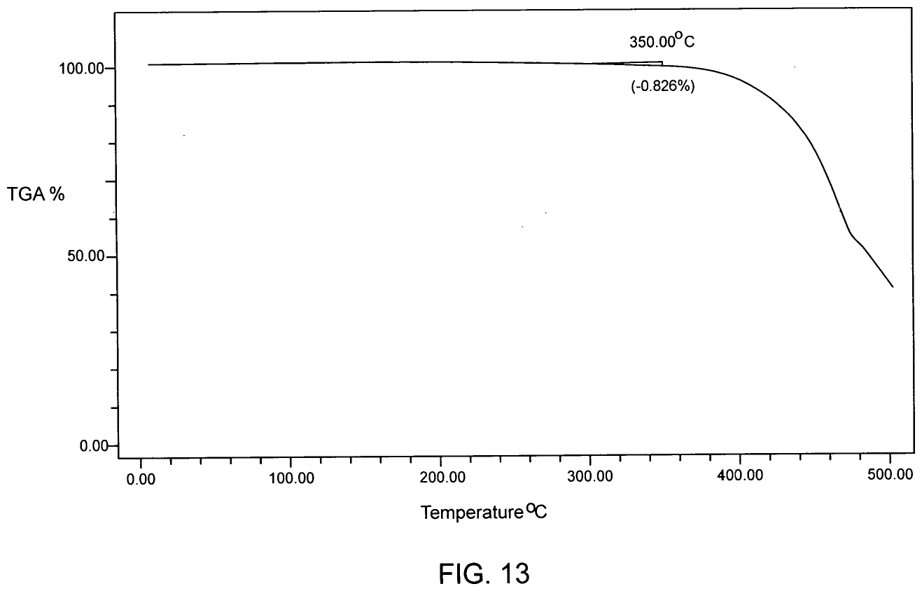

Thermal stability. The thermal stability of this compound was demonstrated by TGA analysis (performed as described above). The compound had less than 1% weight loss at 350° C. See FIG. 13.

### Formulations of Polyimides with Pendant Groups

### Example 15: Thermally Curable Formulations

The resins were mixed with representative co-reactant as indicated below in Table 1 plus 2% by weight dicumyl peroxide, degassed and cured in an oven at 175° C. for 1-hour. Various properties of the cured formulation were determined using the methods described above. The results are summarized in Table 1.

TABLE 1
Properties of Thermally Cured Formulations

| | | | | T_{g} | | |
|---|---|---|---|---|---|---|
| Sample | % | Co-Reactant | % | (DMA) | Dk | Df |
| 1-B | 65 | BMI-2500 | 35 | 55 | | — |
| 1-B | 50 | BMI-2500 | 50 | 77 | | — |
| 1-B | 35 | BMI-2500 | 65 | 96 | 2.54 | 0.002 |
| 1-D | 80 | SA-9000(PPE) | 20 | 69 | | — |
| 1-D | 70 | SA-9000(PPE) | 30 | 77 | | — |
| 1-D | 60 | SA-9000(PPE) | 40 | 86 | 2.78 | 0.003 |
| 1-H | 80 | SR-601 | 20 | 163 | | — |
| 1-H | 70 | SR-601 | 30 | 152 | | — |
| 1-H | 60 | SR-601 | 40 | 140 | | — |
| 1-I | 25 | BMI-1500 | 75 | 43 | | — |
| 1-I | 50 | BMI-1500 | 50 | 56 | | — |
| 1-J | 25 | BMI-689 | 75 | 52 | 2.42 | 0.002 |
| 1-J | 50 | BMI-689 | 50 | 73 | | — |
| 1-J | 75 | BMI-689 | 25 | 102 | | — |
| 1-K | 75 | SR-833S | 25 | 156 | | — |
| 1-K | 85 | SR-833S | 15 | 142 | | — |
| 2-A | 75 | TriallylIsocyanurate | 25 | 92 | | — |
| 2-A | 65 | TriallylIsocyanurate | 35 | 107 | | — |
| 3-A | 60 | Tris(2- | 40 | 151 | | — |
| | | acryloxyethyl)isocyanurate | | | | |
| 3-A | 50 | Tris(2- | 50 | 170 | | — |
| | | acryloxyethyl)isocyanurate | | | | |
| 4-A | 85 | BMI-70 | 15 | 77 | | — |
| 4-A | 75 | BMI-70 | 25 | 102 | | — |

SA-9000(PPE) = low molecular weight, bi-functional oligomer based on polyphenylene ether (PPE) with vinyl end-groups; SABIC Innovative Plastics, Riyadh, Saudi Arabia)

### Ultraviolet Light-Curable Formulations

### Example 16: 1-A UV-Curable Formulation

The following components were dissolved in 20 g of anisole with mixing:
56 wt % Resin 1-A
19 wt % BMI 2500 (Designer Molecule, Inc.)
19 wt % SR 454 (ethoxylated trimethylolpropane triacrylate; Sartomer Arkema Group, Exton, Pa.)
2 wt % 4 META
2 wt % Irgacure® 819
2 wt % Irgacure® 784

The solution was poured into a standard dogbone tensile test mold, degassed and placed in an oven to dry at 100° C. for 6 hours. Both sides of the film were exposed to ultraviolet light (365 nm) for 2 minutes per side, followed by heating to 175° C. for 1-hour to complete the cure.

The cured formulation was tested for tensile strength, elongation, T_{g}, CTE, Dk, and Df. The results of those tests are given below in Table 2.

### Example 17: 1-C UV-Curable Formulation

The following components were dissolved in 20 g of anisole with mixing:
63 wt % Resin 1-C
20 wt % BMI 2500
8 wt % SR833S (tricyclodecane dimethanol diacrylate; (Arkema Group), Exton, Pa.)
3 wt % Tris (2 acryloxyethyl)isocyanurate)
2 wt % 4 META
2 wt % Irgacure® 819
2 wt % Irgacure® 784

The solution was poured into standard dogbone tensile mold, degassed and placed in an oven to dry at 100° C. for about 6 hours. Both sides of the film were exposed to ultraviolet light (365 nm) for 2 minutes per side, followed by heating to 175° C. for 1-hour to complete the cure.

The cured formulation was tested for tensile strength, elongation, T_{g}, and CTE. The results of those tests are given below in Table 2.

### Example 18: 1-D UV-Curable Formulation

The following components were dissolved in 20 g of anisole with mixing:
75 wt % Resin 1-D
9 wt % Tris(2-acryloxyethyl)isocyanurate)
10 wt % SR833S
2 wt % 4-META 2-(Methacryloyloxy)ethyl 1,3-dioxo-1,3-dihydroisobenzofuran-5-carboxylate; Sigma-aldrich, St Louis, Mo.
2 wt % Irgacure® 819
2 wt % Irgacure® 784

The solution was poured into a standard dogbone tensile mold, degassed and placed in an oven to dry at 100° C. for 6 hours. Both sides of the film were exposed to ultraviolet light (365 nm) for 2 minutes per side, followed by heating to 175° C. for 1-hour to complete the cure.

The cured formulation was tested for tensile strength, elongation, T_{g} and CTE. The results of those tests are given below in Table 2.

### Example 19: 1-E UV-Curable Formulation

The following components were dissolved in 20 g of anisole with mixing:
25 wt % 1-E Resin
55 wt % BMI-2500 (Designer Molecules, Inc.)
14 wt % SR833S
2 wt % 4-META
2 wt % Irgacure® 819
2 wt % Irgacure® 784

The solution was poured into a standard dogbone tensile mold and placed in an oven to dry at 100° C. for 6 hours. Both sides of the film were exposed to ultraviolet light (365 nm) for 2 minutes per side, followed by heating to 175° C. for 1-hour to complete the cure.

The cured formulation was tested for tensile strength, elongation, T_{g}, and CTE. The results of those tests are given below in Table 2.

### Example 20: 1-F UV-Curable Formulation

The following components were dissolved in 20 g of anisole with mixing:
68 wt % 1-F Resin
18 wt % SR-833S
8 wt % Tris(2-acryloxyethyl)isocyanurate
2 wt % 4-META
2 wt % Irgacure® 819
2 wt % Irgacure® 784

The solution was poured into a standard dogbone tensile mold and placed in an oven to dry at 100° C. Both sides of the film were exposed to ultraviolet light (365 nm) for 2 minutes per side, followed by heating to 175° C. for 1-hour to complete the cure.

The cured formulation was tested for tensile strength, elongation, T_{g} and CTE. The results of those tests are given below in Table 2.

### Example 21: 1-G UV-Curable Formulation

46 wt % 1-G Resin
20 wt % DMI-4100 (Polyimide-BMI, Designer Molecules, Inc.)
15 wt % BMI-1550 (Designer Molecules, Inc.)
12 wt % SR833S
2 wt % 4-META
2 wt % Irgacure® 819 (Bis(2,4,6-trimethylbenzoyl)-phenylphosphineoxide; C; Ciba Specialty Chemicals, Basel, CH)
2 wt % Irgacure® 784 (cyclopenta-1,3-diene; 1-(2,4-difluorocyclohexa-2,3,5-trien-1-yl)pyrrole; titanium; Ciba Specialty Chemicals, Basel, CH)
1 wt % Ethyl(4-aminodimethyl)benzoate (Sigma-Aldrich, St. Louis Mo.)

The solution was poured into a standard dogbone tensile mold and placed in an oven to dry at 100° C. for 6 hours. Both sides of the film were exposed to ultraviolet light (365 nm) for 2 minutes per side, followed by heating to 175° C. for 1-hour to complete the cure.

The cured formulation was tested for tensile strength, elongation, T_{g}, CTE, Dk, and Df. The results of those tests are given below in Table 2.

TABLE 2
Properties of UV-Cured Formulations

| | Tensile | Percent | | | | |
|---|---|---|---|---|---|---|
| | Strength | Elongation | T_{g} | CTE | | |
| Formulation | (MPa) | at break | (TMA) | (α1) | Dk | Df |
| 1-A | 57 | 43 | 98 | 80 | 2.48 | 0.002 |
| 1-C | 48 | 100 | 80 | 87 | — | — |
| 1-D | 73 | 50 | 110 | 76 | — | — |
| 1-E | 85 | 32 | 105 | 78 | — | — |
| 1-F | 88 | 17 | 130 | 54 | — | — |
| 1-G | 75 | 78 | 145 | 53 | 2.7 | 0.003 |

### Example 22: Redistribution Layers Formulations

A formulation for use as RDL must not only have good physical properties, but also must UV-cure with less than 1000 mJ of UV light. The material must also develop using standard developing solutions such as cyclopentanone, be resistant to chemical stripper solutions, adhere well to copper surfaces, and effectively block the diffusion of copper oxide into the polymer matrix to prevent delamination.

The formulas presented in Table 2 are all suitable for use as RDL materials, however, the formulations also must contain proper coupling agents to make sure that adhesion to copper is met, especially after pressure cooker testing (PCT). The right coupling agents also help to prevent copper oxide migration.

The coupling agents that have been found to work best are 2-(3,4-epoxycylohexyl) ethyltrimethoxysilane (Gelest Inc., Morrisville, Pa.) and N-phenyl-3-aminopropyltrimethoxysilane (Gelest Inc. Morrisville, Pa.). 1-2% of each coupling agent is added to the formulations in Table 2 for RDL formulations.

### RDL Formulation

A solution was prepared by mixing the following materials:
10.0 g of tris(2-hydroxyethyl) isocyanurate triacrylate
12.0 g of dicyclopentadiene dimethanol diacrylate (Sartomer (Arkema Group))
2.0 g of 4-methacryloxyethyl trimellitic anhydride
76.0 g of the pendent vinyl ether functionalized polyimide (1-D Resin)
400.0 g of anisole

To the solution was added the following photoinitiator combination: 2.0 g of Irgacure® 819 (Bis(2,4,6-trimethylbenzoyl)-phenylphosphineoxide); 2.0 g of Irgacure® 784 (Bis(.eta.5-2,4-cylcopentadien-1-yl)-bis(2,6-difluoro-3-(1H-pyrrol-1-yl)-phenyl) titanium), followed by the addition of 1.0 g of ethyl-4-(dimethylamino)benzoate. These solids were mixed well in a double planetary mixer to ensure they were fully dissolved.

To the solution was added the following coupling agents: 2.0 g of N-phenyl-3-aminopropyl trimethoxysilane, and 1.0 g of 2-(3,4-epoxycyclohexyl)ethyl trimethoxysilane. The solution was stirred to completely dissolve everything.

The solution was filtered through a 1-micron filter to remove any trace particles that could interfere with making a perfect coating.

### Spin Coating Experiment

Silicon wafer was cleaned and dried and placed on a spin coating machine. The RDL solution was poured on the center of the copper wafer to make a puddle. The wafer was spun for 10 seconds at about 550 rpm, followed by 10 seconds at 1100 rpm. The wafer was dried in the oven for 10 minutes at 100° C. A photomask was applied to the wafer and placed in a UV chamber for 50 seconds to get approximately 500 mJ/cm² UV dosage.

The wafer was placed in a bath containing cyclopentanone to develop the pattern. After 1-minute the cleanly developed pattern was observed.

The wafer was placed in the oven at 125° C. for 30 minutes to make sure the coupling agents take affect and adhesion to the copper surface is maximized.

The copper wafers are placed in a pressure cooker for 96 hours to test the adhesion of the coating onto the surface. After the test they are dried and cross-cut with a razor blade, scotch tape was adhered onto the surface and pulled away to find any weakness in the adhesion. The test indicates that the material has very good adhesion, with no delamination visually observed under a microscope.

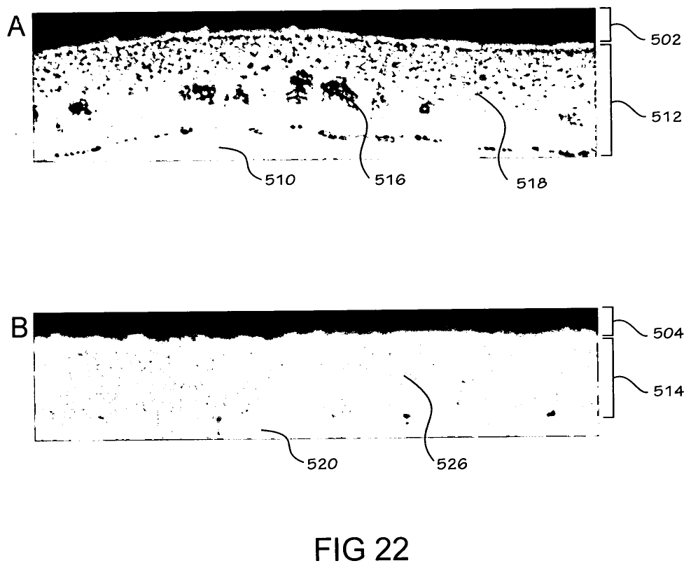

Copper oxide diffusion was tested by high temperature storage (HTS) at 175° C. for 200 hours in the oven. The cross-sectional analysis of the copper wafer using scanning electron microscopy is a good way to analyze for copper oxide diffusion. The presence of voids in the copper oxide layer and diffusion into the resin layer will ultimately cause delamination from the surface, and this is present in most RDL materials on the market. However, the invention formulations show no voids and no copper oxide diffusion, indicating that the combination of the resins in the formulation and the adhesion promoters and coupling agents have capped the copper oxide and prevented its diffusion into the resin layer (FIG. 22). Panel A shows a control which used an organic RDL solution and Panel B used the RDL solution described above. The figure shows the copper layer 512 and 514 in the control and invention RDL, respectively; 502 and 505 are the RDL layers. The plated copper is indicated 510 and 520; oxidized copper is above the plated (518, 526). In the control, voids are seen, but they are absent from the plated copper covered with the RDL formulation of the invention.

### Temporary Adhesive Compounds and Compositions

### Example 23: Temporary Adhesive Formulation

Temporary adhesives for high temperature applications require that the material be soft, so that during the lamination process at temperature the material can flow and fill all of the groves. The material must UV-cure and be stable with less than 5% weight loss at 350° C.

All of the resins described herein have less than 1% weight loss at 350° C. when made into a thin film and analyzed using TGA. The materials must be UV-cured, therefore a co-reactant that is low in viscosity and has little to no weight loss must be added to properly UV cure. Preferred co-reactants include, but are not limited to tri(2-acryloxyethyl)isocyanurate; BMI-689 (Designer Molecules, Inc.); 1,10-decane diol diacrylate; tricyclodecane dimethanol diacrylate; and trimethylolpropane triacrylate. The co-reactants are typically added in about 5-20% by weight to the formulation.

### Example 24: Temporary Adhesive for Backgrinding (Compound 5 Plus Tris[2-(acryloyloxy)ethyl] isocyanurate

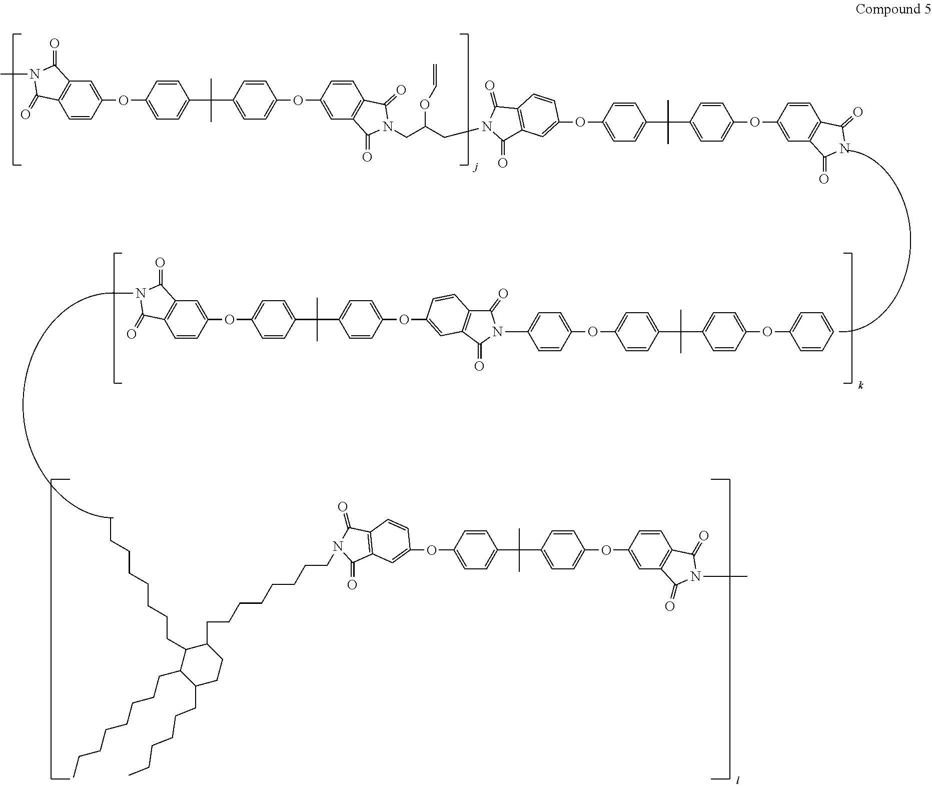

where j is approximately 0.2±0.01; k is approximately 0.05±0.01; and 1 is approximately 0.75±0.01.

### Synthesis of Pendent Vinyl Ether Polyimide:

A 3-L reactor was assembled and charged with 9.0 g (100 mmol) of 1,3-diamino-2-propanol, followed by the addition of 10.3 g (25 mmol) of 2,2-bis-[4-(4-aminophenoxy)phenyl]propane, and 205.9 g (375 mmol) of Priamine® 1075 (dimer diamine). To the reactor was added 1500 g of anisole, followed by stirring to form a homogeneous solution. To the reactor was added 262.5 g (505 mmol) of bisphenol-A-dianhydride. The mixture was stirred vigorously and heated slowly to about 155° C. to form the polyimide as the water from the reaction is azeotropically distilled into a Dean-Stark trap. The solution is refluxed for about 1-2 hours to assure complete polyimide formation.

The pendent alcohol functionalized polyimide is converted to a vinyl ether via transetherification reaction. Once the solution is cooled down to about 75° C. then a large excess, (500 mmol; 500 g) of butyl vinyl ether was added to the reactor along with 1 g of palladium acetate phenanthroline complex (Designer Molecules, San Diego, Calif.). The solution was stirred at 75° C. for about 6 hours, followed by room temperature stirring overnight. The excess butyl vinyl ether and some anisole were removed under reduced pressure to produce a 25% solids solution of polyimide in anisole.

The temporary adhesive formulation was a combination of the above polyimide (9.0 g, 90 wt %) with the following acrylic Tris[2-(acryloyloxy)ethyl] isocyanurate (1.0 g, 10 wt %). The materials were dissolved in 20 g of anisole, followed by the addition of 0.05 g of Irgacure-819 photoinitiator. The solution was spin coated onto a silicon wafer for 10 seconds at 550 rpm's followed by 10 seconds at 1150 rpm's. The wafer was placed in the oven to dry at 120° C. for 10 minutes, followed by allowing the material to cool down to ambient temperature over 30 minutes. The adhesion of the film on the wafer was tested by trying to remove the film using a razor blade. The material was on very well and had the feel of a very low modulus thermoplastic that was very difficult to remove from the surface.

The wafer was placed under the UV light at 365 nm and received 1000 mJ of UV exposure. The material was again tested for adhesion by trying to remove the material with a razor blade. After UV exposure the material peeled away very well, with no trace of polymer left on the surface of the wafer. The material felt much stiffer and that is what caused the much easier peeling of the surface. Not to be bound by any one theory, but since the material contains a large amount of greasy aliphatic groups it has low surface energy and with no coupling agents present it does not stick too well when the modulus is increased.

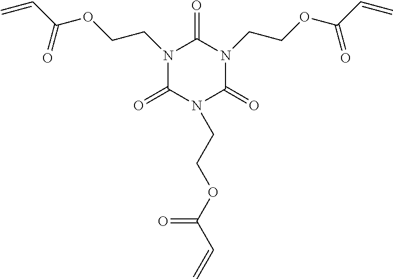 [SMILES: C=CC(=O)OCCn1c(=O)n(CCOC(=O)C=C)c(=O)n(CCOC(=O)C=C)c1=O]

The TGA analysis of the 50 micron thick film that was exposed to 1000 mJ of UV light (365 nm) shows 1.13% weight loss at 300° C., and 1.97% weight loss at 350° C. (FIG. 12).

FIG. 13, shows the TGA analysis of a maleimide-pendent polyimide of example 14. The TGA analysis shows about 0.826% weight loss at 350° C. after a similar 50 micron thick film was exposed to 1000 mJ of UV light.

### Example 25: Composites and Printed Wiring Boards

The curable pendent polyimides along with co-reactants described are suitable for making prepregs in combination with glass fabric. Glass fabric is dipped into a concentrated solution of the resin and dried, followed by lamination of multiple layers at up to 200° C. for 1-hour to form the composite. Additionally, adhesion promoters and flame retardants may be added to make a better product.

A solution of the following formulation was prepared by combining the following:
62 wt % Compound 1-C
19 wt % BMI-2500
10 wt % Tricyclodecanedimethanol diacrylate
2 wt % Tris[2-(acryloyloxy)ethyl] isocyanurate
2 wt % 4-methacryloxyethyl trimellitic anhydride
2.5 wt % Irgacure® 819
2.5 wt % Irgacure® 784

A thick film (600 microns) was cured using 365 nm UV light for 5 minutes on each side, followed by placing in the oven for 1 hour at 175° C.

### Example 26: Shape Memory Polyimide

All of the formulations described in Tables 1 and 2 were found to be possess shape memory properties. The approximately 500-micron thick materials after being cured were cut into 0.5 inch×6 inch strips and twisted into deformed shapes. The pieces were placed in the oven set to 180° C., and within a few seconds the materials would unwind and return to the original 0.5 inch×6 inch strips.

1-48. (canceled)

49. A curable, functionalized polyimide having a structure according to any one of Formulae IA, IB, IC and 1D: 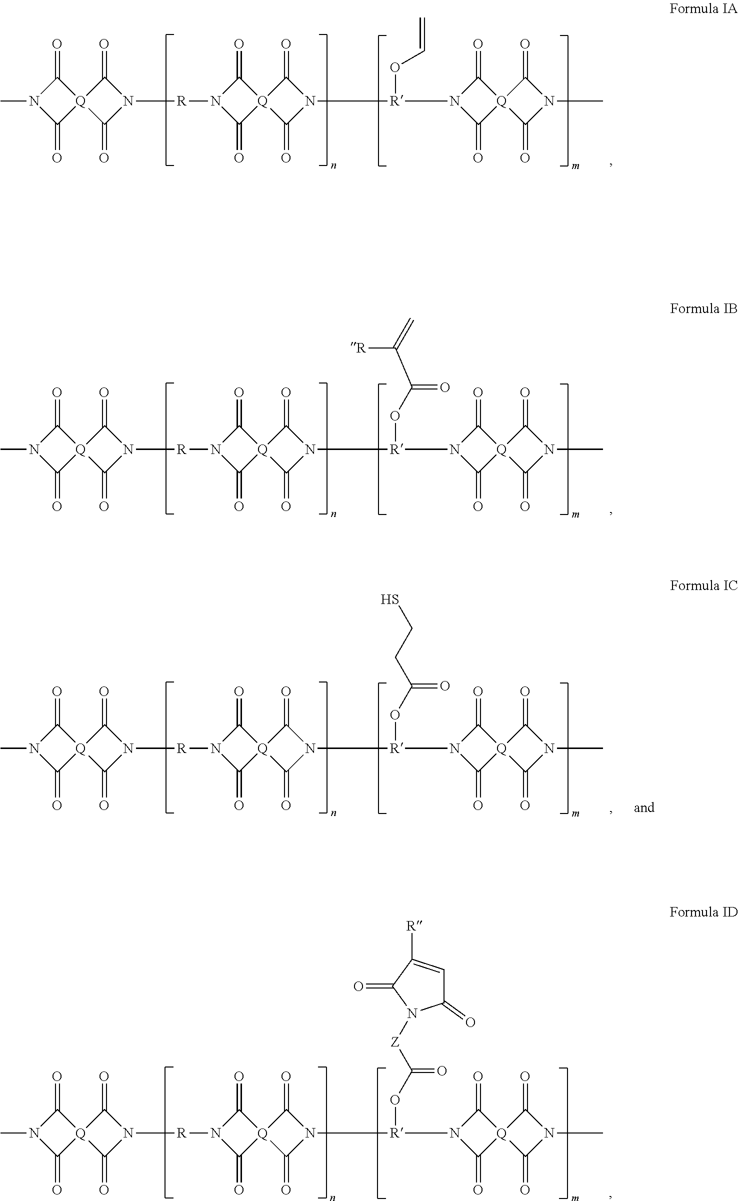
wherein:
R is independently a substituted or unsubstituted aliphatic, cycloaliphatic, alkenyl, polyether, polyester, polyamide, aromatic, heteroaromatic, or siloxane moieties; R′ is independently a diamine that contains a alcohol moiety;
each Q is independently a substituted or unsubstituted aliphatic, cycloaliphatic, alkenyl, polyether, polyester, polyamide, aromatic, heteroaromatic, or siloxane moiety;
each R″ is H or methyl;
z is independently a substituted or unsubstituted alkyl or aromatic; and
n and m are integers having a value from 10 to about 100, with the proviso the average molecular weight of curable polyimide is greater than 20,000 Daltons.

50. The curable, functionalized polyimide of claim 49, wherein the curable, functionalized polyimide is the product of a condensation of at least one diamine with at least one dianhydride resulting in formation of a pendant alcohol, followed by functionalizing the pendant alcohol group.

51. The curable, functionalized polyimide of claim 50, wherein the at least one diamine is selected from the group consisting of: dimer diamine; 1,10-diaminodecane; 1,12-diaminododecane; hydrogenated dimer diamine; 1,2-diamino-2-methylpropane; 1,2-diaminocyclohexane; 1,2-diaminopropane; 1,3-diaminopropane; 1,4-diaminobutane; 1,5-diaminopentane; 1,7-diaminoheptane; 1,8-diaminomenthane; 1,8-diaminooctane; 1,9-diaminononane; 3,3′-diamino-N-methyldipropylamine; diaminomaleonitrile; 1,3-diaminopentane; 9,10-diaminophenanthrene; 4,4′-diaminooctafluorobiphenyl; 3,5-diaminobenzoic acid; 3,7-diamino-2-methoxyfluorene; 4,4′-diaminobenzophenone; 3,4-diaminobenzophenone; 3,4-diaminotoluene; 2,6-diaminoanthroquinone; 2,6-diaminotoluene; 2,3-diaminotoluene; 1,8-diaminonaphthalene; 2,4-diaminotoluene; 2,5-diaminotoluene; 1,4-diaminoanthroquinone; 1,5-diaminoanthroquinone; 1,5-diaminonaphthalene; 1,2-diaminoanthroquinone; 2,4-cumenediamine; 1,3-bisaminomethylbenzene; 1,3-bisaminomethylcyclohexane; 2-chloro-1,4-diaminobenzene; 1,4-diamino-2,5-dichlorobenzene; 1,4-diamino-2,5-dimethylbenzene; 4,4-diamino-2,2-bistrifluoromethylbiphenyl; bis(amino-3-chlorophenyl)ethane; bis(4-amino-3,5-dimethylphenyl)methane; bis(4-amino-3,5-diisopropylphenyl)methane; bis(4-amino-3,5-methyl-isopropylphenyl)methane; bis(4-amino-3,5-diethylphenyl)methane; bis(4-amino-3-ethylphenyl)methane; diaminofluorene; 4,4-(9-Fluorenylidene)dianiline; diaminobenzoic acid; 2,3-diaminonaphthalene; 2,3-diaminophenol; bis(4-amino-3-methylphenyl)methane; bis(4-amino-3-ethylphenyl)methane; 4,4-diaminophenylsulfone; 3,3-diaminophenylsulfone; 2,2-bis(4,-(4-aminophenoxy)phenyl)sulfone; 2,2-bis(4-(3-aminophenoxy)phenyl)sulfone; 4,4-oxydianiline; 4,4-diaminodiphenyl sulfide; 3,4-oxydianiline; 2,2-bis(4-(4-aminophenoxy)phenyl)propane; 1,3-bis(4-aminophenoxy)benzene; 4,4-bis(4-aminophenoxy)biphenyl; 4,4-diamino-3,3-dihydroxybiphenyl; 4,4-diamino-3,3-dimethylbiphenyl; 4,4-diamino-3,3-dimethoxybiphenyl; Bisaniline M (4-[2-[3-[2-(4-aminophenyl)propan-2-yl]phenyl]propan-2-yl]aniline)]Bisaniline); Bisaniline P (4-[2-[4-[2-(4-aminophenyl)propan-2-yl]phenyl]propan-2-yl]aniline); 9,9-bis(4-aminophenyl)fluorene; o-tolidine sulfone; methylene bis(anthranilic acid); 1,3-bis(4-aminophenoxy)-2,2-dimethylpropane; 1,3-bis(4-aminophenoxy)propane; 1,4-bis(4-aminophenoxy)butane; 1,5-bis(4-aminophenoxy)butane; 2,3,5,6-tetramethyl-1,4-phenylenediamine; 3,3,5,5-tetramehylbenzidine; 4,4-diaminobenzanilide; 2,2-bis(4-aminophenyl)hexafluoropropane; polyoxyalkylenediamines; 1,3-cyclohexanebis(methylamine); m-xylylenediamine; p-xylylenediamine; bis(4-amino-3-methylcyclohexyl)methane; 1,2-bis(2-aminoethoxy)ethane; 3(4),8(9)-bis(aminomethyl)tricyclo(5.2.1.02,6)decane; 1,3-cyclohexanebis(methylamine); 1,3-diamino-2-propanol; 1,4-diaminobutane, 1,5-diaminopentane; 1,6-diaminohexane; 2,2-bis[4-(3-aminophenoxy)phenyl]propane; 2,3,5-tetramethylbenzidine; 2,3-diamononaphtalene; 3,5-diaminobenzyl alcohol; and polyalkylenediamines.

52. The curable, functionalized polyimide of claim 50, wherein the at least one dianhydride is selected from the group consisting of 4,4-Bisphenol A dianhydride; pyromellitic dianhydride; maleic anhydride, succinic anhydride; 1,2,3,4-cyclobutanetetracarboxylic dianhydride; 1,4,5,8-naphthalenetetracarboxylic dianhydride; 3,4,9,10-perylenentetracarboxylic dianhydride; bicyclo(2.2.2)oct-7-ene-2,3,5,6-tetracarboxylic dianhydride; diethylenetriaminepentaacetic dianhydride; ethylenediaminetetraacetic dianhydride; 3,3,4,4-benzophenone tetracarboxylic dianhydride; 3,3,4,4-biphenyl tetracarboxylic dianhydride; 4,4-oxydiphthalic anhydride; 3,3,4,4-diphenylsulfone tetracarboxylic dianhydride; 2,2-bis(3,4-dicarboxyphenyl)hexafluoropropane dianhydride; 4,4-bisphenol A diphthalic anhydride; 5-(2,5-dioxytetrahydro)-3-methyl-3-cyclohexene-1,2-dicarboxylic anhydride; ethylene glycol bis(trimellitic anhydride); and hydroquinone diphthalic anhydride, 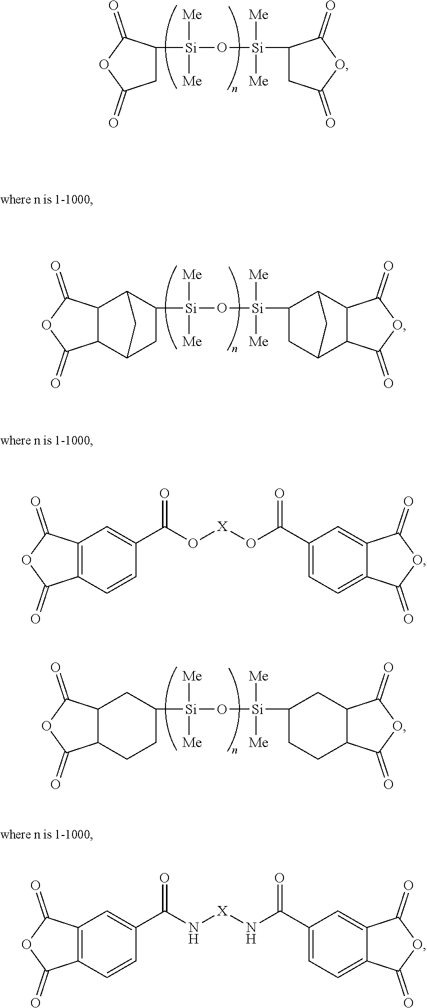
where X is saturated, unsaturated, strait or branched alkyl, polyester, polyamide, polyether, polysiloxane or polyurethane;

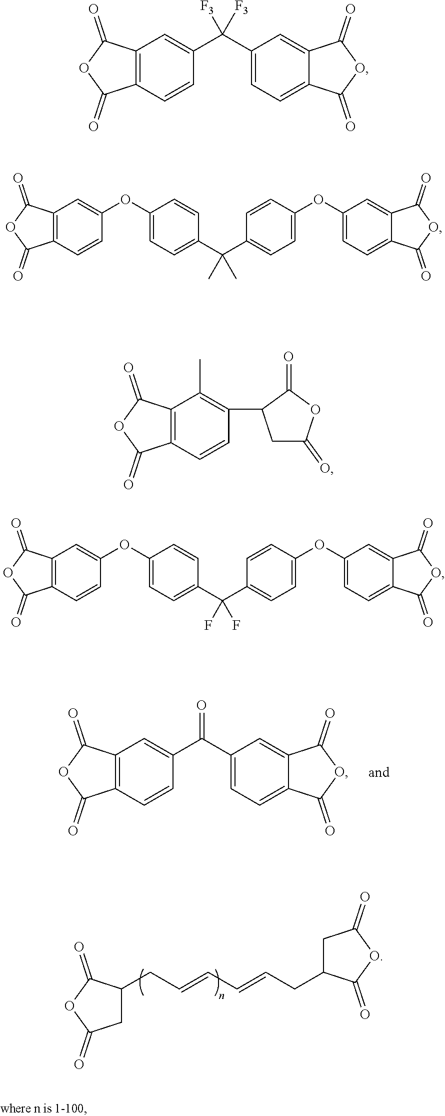

53. A method for synthesizing a curable, functionalized polyimide, comprising the steps of:
a) dissolving at least one diamine in a solvent at room temperature;
b) adding at least one dianhydride, wherein the total amount of the at least one anhydride amount is about one molar equivalent of the total amount of the at least one diamine;
c) slowly over 1 hour heating the mixture to reflux, thereby producing an imidized polymer and water; and
d) refluxing the mixture while removing the water, for about one to about two hours, or until all the water produced has been removed, wherein the average molecular weight of the polyimide is greater than 20,000 Daltons, thereby synthesizing a curable, functionalized polyimide.

54. The method of claim 53, wherein the solvent is an aromatic solvent, wherein the aromatic solvent is optionally anisole.

55. The method of claim 53, wherein the curable, functionalized polyimide comprises at least one pendant alcohol moiety, the method further comprising,
e) reacting the pendant alcohol to produce a functionalized polyimide with polymerizable pendant moieties.

56. The method of claim 55, wherein step e, reacting the pendant alcohol, comprises:
i) catalyzing the reaction of the alcohol groups with a polymer-bound acid catalyst, and
ii) removing the polymer-bound catalyst by filtration.

57. An adhesive formulation comprising a curable, functionalized polyimide of claim 49, wherein, optionally, the adhesive formulation is removable.

58. An article coated on at least a part of one surface with the adhesive formulation of claim 57, wherein optionally, the article is a thinned or unthinned wafer, a patterned or unpatterned chip or an electronics package.

59. A formulation comprising:
a) at least one curable, functionalized polyimide of claims 49;
b) at least one reactive diluent; and
c) a solvent in which the functionalized polyimide is soluble, and
d) optionally, at least one of: at least one adhesion promoter, at least one coupling agent, at least one UV initiator, at least one UV initiator, or a combination thereof.

60. The formulation of claim 59, wherein the formulation is a coating, a passivation layer, or a redistribution layer.

61. A redistribution layer, comprising metallization between two layers of the formulation of claim 59.

62. A prepreg comprising a fiber support impregnated with the formulation of claim 59.

63. A copper clad laminate comprising copper foil laminated to one surface or both surfaces of the prepreg of claim 62.

64. A printed wiring board comprising the copper-clad laminate of claim 63.

65. A method for removing the removable adhesive formulation of claim 57, comprising the steps of
a) applying an air jet to the temporary adhesive;
b) peeling the adhesive from the article; and
c) optionally, soaking the article in a chemical solvent that removes residual adhesive.

66. A UV curable composition comprising:
a) at least one curable, functionalized polyimide of claim 49; and
b) at least one reactive diluent.

67. A method for backgrinding a wafer, comprising the steps of:
a) applying the adhesive formulation of claim 57 to the top of a wafer;
b) contacting the adhesive formulation applied in step a) with a support;
c) grinding and polishing the bottom of the wafer;
d) removing the wafer from the support; and
e) removing the adhesive from the wafer.

68. A method for dicing a wafer, comprising the steps of:
a) applying the adhesive of claim 57 to the top or bottom side of a wafer;
b) adhering the top or bottom side of the wafer to which the composition was applied to a frame;
c) cutting the wafer to singulate individual die;
d) removing the die from the wafer; and
e) removing the adhesive from the die.
